(19) United States
(12) Patent Application Publication
(10) Pub. No.: US 2023/0284429 A1
(43) Pub. Date: Sep. 7, 2023

(54) SEMICONDUCTOR DEVICE

(71) Applicant: Semiconductor Energy Laboratory Co., Ltd., Atsugi-shi, Kanagawa-ken (JP)

(72) Inventors: Hiromichi GODO, Isehara (JP); Kazuki TSUDA, Atsugi (JP); Yoshiyuki KUROKAWA, Sagamihara (JP); Satoru OHSHITA, Toyooka (JP); Takuro KANEMURA, Sapporo (JP); Hidefumi RIKIMARU, Tama (JP)

(21) Appl. No.: 18/016,745

(22) PCT Filed: Jul. 19, 2021
(86) PCT No.: PCT/IB2021/056483

§ 371 Date: Jan. 18, 2023

(30) Foreign Application Priority Data
Jul. 31, 2020 (JP) 2020-129876
Feb. 5, 2021 (JP) 2021-017030
Jun. 29, 2021 (JP) 2021-107848

(51) Int. Cl. H10B 12/00; G11C 11/405; G11C 11/54

(52) U.S. Cl. CPC H10B 12/00; G11C 11/405; G11C 11/54

(57) ABSTRACT

Provided is a semiconductor device having a novel structure. A first transistor, a second transistor, a third transistor, and a capacitor are included. The first transistor has a function of retaining a first potential corresponding to first data supplied to a gate of the third transistor through the first transistor when being in an off state. The capacitor has a function of changing the first potential retained in the gate of the third transistor into a second potential in accordance with a change in potential corresponding to second data supplied to one electrode of the capacitor. The second transistor has a function of setting a potential of one of a source and a drain of the third transistor to a potential corresponding to a potential of a gate of the second transistor. The third transistor has a function of supplying output current corresponding to a potential of the gate of the third transistor to the other of the source and the drain of the third transistor. The output current is current flowing when the third transistor operates in a subthreshold region.

### TECHNICAL FIELD

In this specification, a semiconductor device and the like will be described.

Note that one embodiment of the present invention is not limited to the above technical field. Examples of the technical field of one embodiment of the present invention disclosed in this specification and the like include a semiconductor device, an imaging device, a display device, a light-emitting device, a power storage device, a storage device, a display system, an electronic device, a lighting device, an input device, an input/output device, a driving method thereof, and a manufacturing method thereof.

### BACKGROUND ART

Integrated circuits that imitate the mechanism of the human brain are currently under active development. The integrated circuits incorporate electronic circuits as the brain mechanism and include circuits corresponding to “neurons” and “synapses” of the human brain. Such integrated circuits may therefore be called “neuromorphic”, “brain-morphic”, or “brain-inspired” circuits. The integrated circuits have a non-von Neumann architecture and are expected to be able to perform parallel processing with extremely low power consumption as compared with a von Neumann architecture, in which power consumption increases with increasing processing speed.

An information processing model that imitates a biological neural network including “neurons” and “synapses” is called an artificial neural network (ANN). By using an artificial neural network, inference with an accuracy as high as or higher than that of a human can be carried out. In an artificial neural network, the main arithmetic is the weighted sum operation of outputs from neurons, i.e., the product-sum operation.

Non-Patent Document 1 proposes a product-sum operation circuit including a nonvolatile memory element. Each memory element of the product-sum operation circuit outputs current corresponding to a product of data corresponding to a multiplier stored in each memory element and input data corresponding to a multiplicand by using operation in a subthreshold region of a transistor containing silicon in its channel formation region. With the sum of currents output from the memory elements in each column, the product-sum operation circuit acquires data corresponding to product-sum operation. The product-sum operation circuit includes memory elements therein, and thus does not need to read and write data from and to an external memory when carrying out multiplication and addition. This can decrease the number of times of data transfer for reading, writing, and the like; thus, the power consumption should be reduced.

### REFERENCE

### Non-Patent Document

[Non-Patent Document 1] X. Guo et al., “Fast, Energy-Efficient, Robust, and Reproducible Mixed-Signal Neuromorphic Classifier Based on Embedded NOR Flash Memory Technology” IEDM2017, pp. 151-154.

### SUMMARY OF THE INVENTION

### Problems to be Solved by the Invention

In the case where the above-described product-sum operation circuit performs arithmetic using data stored in an external memory, a data signal or a potential is supplied to each wiring at the time of data writing and reading. In a transistor for performing arithmetic, voltage applied to a drain terminal changes between data writing and data reading. A change in voltage of the drain terminal causes a change in transistor characteristics, e.g., a change in threshold voltage, which might decrease the accuracy of data to be read.

In the case of performing product-sum operation by a digital circuit, an increase in shoot-through current due to miniaturization of transistors, for example, might increase power consumption. It is important that not only arithmetic processing speed but also arithmetic processing performance per unit electric power be improved in repetitive arithmetic processing such as product-sum operation.

An object of one embodiment of the present invention is to provide a semiconductor device in which the accuracy of data to be read is increased. An object of one embodiment of the present invention is to provide a semiconductor device with high arithmetic processing performance per unit electric power. An object of one embodiment of the present invention is to provide a semiconductor device that has a novel structure and is capable of performing product-sum operation.

One embodiment of the present invention does not necessarily achieve all the above objects and only needs to achieve at least one of the objects. The description of the above objects does not preclude the existence of other objects. Objects other than these objects will be apparent from the description of the specification, the claims, the drawings, and the like, and objects other than these objects can be derived from the description of the specification, the claims, the drawings, and the like.

### Means for Solving the Problems

One embodiment of the present invention is a semiconductor device including a first transistor, a second transistor, a third transistor, and a capacitor, in which the first transistor has a function of retaining a first potential corresponding to first data supplied to a gate of the third transistor through the first transistor when being in an off state, the capacitor has a function of changing the first potential retained in the gate of the third transistor into a second potential in accordance with a change in potential corresponding to second data supplied to one electrode of the capacitor, the second transistor has a function of setting a potential of one of a source and a drain of the third transistor to a potential corresponding to a potential of a gate of the second transistor, the third transistor has a function of supplying output current corresponding to a potential of the gate of the third transistor to the other of the source and the drain of the third transistor, and the output current is current flowing when the third transistor operates in a subthreshold region.

One embodiment of the present invention is a semiconductor device including a first transistor, a second transistor, a third transistor, and a capacitor, in which the first transistor has a function of retaining a first potential corresponding to first data supplied to a gate of the third transistor through the first transistor when being in an off state, the capacitor has a function of changing the first potential retained in the gate of the third transistor into a second potential in accordance with a change in potential corresponding to second data supplied to one electrode of the capacitor, the second transistor has a function of setting a potential of one of a source and a drain of the third transistor to a potential corresponding to a potential of a gate of the second transistor, the third transistor has a function of supplying output current corresponding to a potential of the gate of the third transistor to the other of the source and the drain of the third transistor, the output current is current flowing when the third transistor operates in a subthreshold region, the second transistor and the third transistor each have a back gate, and a potential supplied to the back gates is a potential of the other of the source and the drain of the third transistor.

One embodiment of the present invention is a semiconductor device including a first transistor, a second transistor, a third transistor, and a capacitor, in which the first transistor has a function of retaining a first potential corresponding to first data supplied to a gate of the third transistor through the first transistor when being in an off state, the capacitor has a function of changing the first potential retained in the gate of the third transistor into a second potential in accordance with a change in potential corresponding to second data supplied to one electrode of the capacitor, the second transistor has a function of setting a potential of one of a source and a drain of the third transistor to a potential corresponding to a potential of a gate of the second transistor, the third transistor has a function of supplying output current corresponding to a potential of the gate of the third transistor to the other of the source and the drain of the third transistor, the output current is current flowing when the third transistor operates in a subthreshold region, the second transistor and the third transistor each have a back gate, and a potential supplied to the back gates is lower than a potential of the other of the source and the drain of the third transistor.

In the semiconductor device of one embodiment of the present invention, the first transistor preferably includes a semiconductor layer containing a metal oxide in a channel formation region.

In the semiconductor device of one embodiment of the present invention, the metal oxide preferably contains In, Ga, and Zn.

In the semiconductor device of one embodiment of the present invention, the second transistor and the third transistor each preferably include a semiconductor layer containing silicon in a channel formation region.

One embodiment of the present invention is an electronic device including the above-described semiconductor device of one embodiment of the present invention and a housing, in which arithmetic of a neural network is performed by the semiconductor device.

Note that other embodiments of the present invention will be shown in the description of the following embodiments and the drawings.

### Effect of the Invention

One embodiment of the present invention can provide a semiconductor device in which the accuracy of data to be read is increased. One embodiment of the present invention can provide a semiconductor device with high arithmetic processing performance per unit electric power. One embodiment of the present invention can provide a semiconductor device that has a novel structure and is capable of performing product-sum operation.

The description of a plurality of effects does not preclude the existence of other effects. In addition, one embodiment of the present invention does not necessarily have all the effects described as examples. In one embodiment of the present invention, other objects, effects, and novel features are apparent from the description of this specification and the drawings.

### BRIEF DESCRIPTION OF THE DRAWINGS

FIG. 1 is a diagram illustrating a configuration example of a semiconductor device.

FIG. 2A and FIG. 2B are diagrams illustrating a configuration example of a semiconductor device.

FIG. 3A and FIG. 3B are diagrams illustrating a configuration example of a semiconductor device.

FIG. 4A, FIG. 4B, FIG. 4C, and FIG. 4D are diagrams illustrating configuration examples of semiconductor devices.

FIG. 5 is a diagram illustrating a configuration example of a semiconductor device.

FIG. 6A and FIG. 6B are diagrams illustrating a configuration example of a semiconductor device.

FIG. 7 is a diagram illustrating a configuration example of an arithmetic circuit.

FIG. 8A, FIG. 8B, and FIG. 8C are diagrams illustrating configuration examples of an arithmetic circuit.

FIG. 9A, FIG. 9B, FIG. 9C, and FIG. 9D are diagrams illustrating configuration examples of an arithmetic circuit.

FIG. 10A, FIG. 10B, and FIG. 10C are diagrams illustrating configuration examples of an arithmetic circuit.

FIG. 11 is a timing chart for showing a structure example of an arithmetic circuit.

FIG. 12A and FIG. 12B are diagrams illustrating a neural network.

FIG. 13 is a diagram illustrating a structure example of transistors.

FIG. 14A and FIG. 14B are diagrams illustrating a structure example of a transistor.

FIG. 15 is a diagram illustrating a structure example of an integrated circuit.

FIG. 16A and FIG. 16B are diagrams illustrating an application example of an integrated circuit.

FIG. 17A and FIG. 17B are diagrams illustrating an application example of an integrated circuit.

FIG. 18A, FIG. 18B, and FIG. 18C are diagrams illustrating application examples of an integrated circuit.

FIG. 19 is a diagram illustrating an application example of an integrated circuit.

FIG. 20A, FIG. 20B, and FIG. 20C are diagrams illustrating configuration examples of semiconductor devices.

FIG. 21A, FIG. 21B, and FIG. 21C are diagrams showing simulation results of semiconductor devices.

FIG. 22A, FIG. 22B, and FIG. 22C are diagrams showing simulation results of semiconductor devices.

FIG. 23 is a diagram illustrating an arithmetic device.

FIG. 24A and FIG. 24B are diagrams showing an arithmetic device.

FIG. 25 is a diagram showing an arithmetic device.

FIG. 26A and FIG. 26B are diagrams showing an arithmetic device.

FIG. 27A and FIG. 27B are diagrams showing an arithmetic device.

FIG. 28 is a diagram showing an arithmetic device.

FIG. 29 is a diagram showing an arithmetic device.

### MODE FOR CARRYING OUT THE INVENTION

Embodiments of the present invention will be described below. Note that one embodiment of the present invention is not limited to the following description, and it will be readily understood by those skilled in the art that modes and details of the present invention can be modified in various ways without departing from the spirit and scope of the present invention. One embodiment of the present invention therefore should not be construed as being limited to the following description of the embodiments.

Note that ordinal numbers such as “first”, “second”, and “third” in this specification and the like are used in order to avoid confusion among components. Thus, the terms do not limit the number of components. Furthermore, the terms do not limit the order of components. For example, a “first” component in one embodiment in this specification and the like can be referred to as a “second” component in other embodiments or the scope of claims. For another example, a “first” component in one embodiment in this specification and the like can be omitted in other embodiments or the scope of claims.

The same components, components having similar functions, components made of the same material, components formed at the same time, and the like in the drawings are denoted by the same reference numerals, and repeated description thereof is skipped in some cases.

In this specification, for example, a power supply potential VDD may be abbreviated to a potential VDD, VDD, or the like. The same applies to other components (e.g., a signal, a voltage, a circuit, an element, an electrode, and a wiring).

In the case where a plurality of components are denoted by the same reference numerals, and, particularly when they need to be distinguished from each other, an identification sign such as “_1”, “_2”, “_n”, or “_m,n” is sometimes added to the reference numerals. For example, a second wiring GL is referred to as a wiring GL_2.

### Embodiment 1

The structure, operation, and the like of a semiconductor device of one embodiment of the present invention will be described.

In this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be said that a display device (a liquid crystal display device, a light-emitting display device, and the like), a projection device, a lighting device, an electro-optical device, a power storage device, a storage device, a semiconductor circuit, an imaging device, an electronic device, and the like include a semiconductor device.

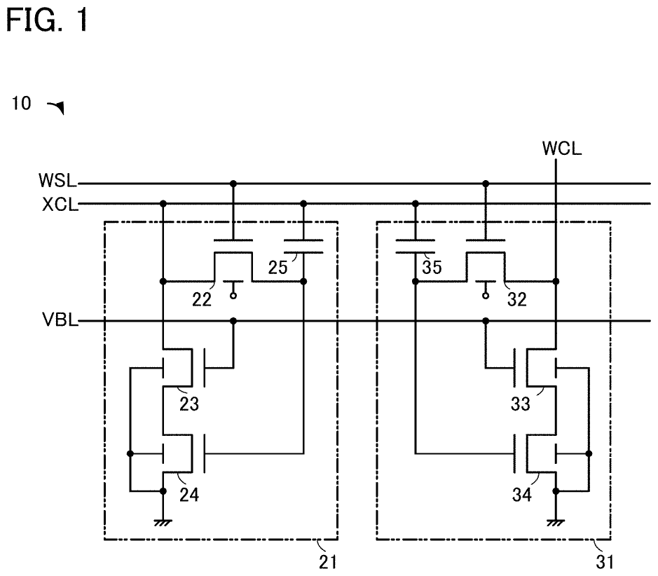

FIG. 1 is a diagram illustrating a semiconductor device 10 of one embodiment of the present invention.

The semiconductor device 10 includes a reference cell 21 and an arithmetic cell 31. The reference cell 21 includes a transistor 22, a transistor 23, a transistor 24, and a capacitor 25. The arithmetic cell 31 includes a transistor 32, a transistor 33, a transistor 34, and a capacitor 35. The transistors and the capacitors included in the reference cell 21 and the arithmetic cell 31 are connected to at least one of a wiring WSL, a wiring XCL, a wiring VBL, a wiring WCL, and a wiring supplying a ground potential, as illustrated in FIG. 1.

The reference cell 21 has a function of, when set current flows therein at the time of data writing and at the time of data reading, making the arithmetic cell 31 execute an arithmetic operation. Specifically, the reference cell 21 has a function of retaining reference voltage in the reference cell 21 when reference current flows therein at the time of data writing and controlling current flowing in the arithmetic cell 31 at the time of subsequent data reading by feeding current corresponding to input data (X) to be supplied to the arithmetic cell 31 to the reference cell 21. Note that the reference cell 21 is simply referred to as a cell in some cases.

Next, connection relations in the reference cell 21 will be described.

A gate of the transistor 22 is connected to the wiring WSL. One of a source and a drain of the transistor 22 is connected to one of a source and a drain of the transistor 23 and the wiring XCL. The other of the source and the drain of the transistor 22 is connected to a gate of the transistor 24 and one electrode of the capacitor 25. The transistor 22 is brought into an on state at the time of data writing so that reference voltage can be written to a retention node (the gate of the transistor 24) in the reference cell 21, and is brought into an off state so that the reference voltage can be retained in the reference cell 21.

A gate of the transistor 23 is connected to the wiring VBL. A back gate of the transistor 23 is connected to the other of a source and a drain of the transistor 24. The one of the source and the drain of the transistor 23 is connected to the one of the source and the drain of the transistor 22 and the wiring XCL. The other of the source and the drain of the transistor 23 is connected to one of the source and the drain of the transistor 24. The transistor 23 sets the potential of the one of the source and the drain of the transistor 24 to a potential corresponding to the potential of the gate of the transistor 23.

The gate of the transistor 24 is connected to the other of the source and the drain of the transistor 22 and the one electrode of the capacitor 25. Note that a node to which the gate of the transistor 24, the other of the source and the drain of the transistor 22, and the one electrode of the capacitor 25 are connected is also referred to as a retention node. The retention node can be made to have a potential corresponding to current flowing in the transistor 24. A back gate of the transistor 24 is connected to the other of the source and the drain of the transistor 24. The other of the source and the drain of the transistor 24 is connected to a wiring supplying a low power supply potential (e.g., a ground potential). The wiring supplying a ground potential functions as a wiring for supplying current between the source and the drain of the transistor 24. The other of the source and the drain of the transistor 24 is connected to the back gate of the transistor 23 and the back gate of the transistor 24. A fixed potential is supplied to the back gate of the transistor 23 and the back gate of the transistor 24; thus, transistor characteristics of the transistor 23 and the transistor 24 are stabilized. The transistor 24 feeds output current corresponding to the potential of the gate of the transistor 24 to the other of the source and the drain.

The one electrode of the capacitor 25 is connected to the other of the source and the drain of the transistor 22 and the gate of the transistor 24. The other electrode of the capacitor 25 is connected to the wiring XCL. The capacitor 25 changes the potential of its one electrode in accordance with a change in potential of the other electrode when the one electrode is in an electrically floating state.

The arithmetic cell 31 has a function of, by feeding current corresponding to weight data (W) to be retained in the arithmetic cell 31, retaining voltage corresponding to the current inside at the time of data writing. The arithmetic cell 31 also has a function of feeding current corresponding to arithmetic using the weight data and the input data at the time of data reading as a result of boosting of the voltage retained at the time of data writing in accordance with current flowing in the reference cell 21. The weight data is referred to as first data, and the input data is referred to as second data, in some cases. Note that the arithmetic cell 31 is simply referred to as a cell in some cases. Note that the weight data is data (weight data) that corresponds to a weight parameter used for product-sum operation of an artificial neural network, for example.

Next, connection relations in the arithmetic cell 31 will be described.

A gate of the transistor 32 is connected to the wiring WSL. One of a source and a drain of the transistor 32 is connected to one of a source and a drain of the transistor 33 and the wiring WCL. The other of the source and the drain of the transistor 32 is connected to a gate of the transistor 34 and one electrode of the capacitor 35. The transistor 32 is brought into an on state at the time of data writing so that voltage corresponding to the weight data can be written to the arithmetic cell 31, and is brought into an off state so that the voltage corresponding to the weight data can be retained in the arithmetic cell 31.

A gate of the transistor 33 is connected to the wiring VBL. A back gate of the transistor 33 is connected to the other of a source and a drain of the transistor 34. The one of the source and the drain of the transistor 33 is connected to the one of the source and the drain of the transistor 32 and the wiring WCL. The other of the source and the drain of the transistor 33 is connected to one of the source and the drain of the transistor 34. The transistor 33 sets the potential of the one of the source and the drain of the transistor 34 to a potential corresponding to the potential of the gate of the transistor 33.

The gate of the transistor 34 is connected to the other of the source and the drain of the transistor 32 and the one electrode of the capacitor 35. Note that a node to which the gate of the transistor 34, the other of the source and the drain of the transistor 32, and the one electrode of the capacitor 35 are connected is also referred to as a retention node. A back gate of the transistor 34 is connected to the other of the source and the drain of the transistor 34. The other of the source and the drain of the transistor 34 is connected to a wiring supplying a low power supply potential (e.g., a ground potential). The wiring supplying a ground potential functions as a wiring for supplying current between the source and the drain of the transistor 34. The other of the source and the drain of the transistor 34 is connected to the back gate of the transistor 33 and the back gate of the transistor 34. A fixed potential is supplied to the back gate of the transistor 33 and the back gate of the transistor 34; thus, transistor characteristics of the transistor 33 and the transistor 34 are stabilized. The transistor 34 feeds output current corresponding to the potential of the gate of the transistor 34 to the other of the source and the drain.

The one electrode of the capacitor 35 is connected to the other of the source and the drain of the transistor 32 and the gate of the transistor 34. The other electrode of the capacitor 35 is connected to the wiring XCL. The capacitor 35 changes the potential of its one electrode in accordance with a change in potential of the other electrode when the one electrode is in an electrically floating state.

Next, the transistors included in the reference cell 21 and the arithmetic cell 31 will be described.

The transistor 24 and the transistor 34 operate in a subthreshold region, unless otherwise specified. Drain current Id of a transistor that operates in a subthreshold region can be represented by Equation (1).

$$\begin{matrix}[ Formula 1 ] & \\ {I}_{d} = {I}_{0} exp ( \frac{q ( {V}_{g} - {V}_{t h} )}{η {k}_{B} T} ) & ( 1 )\end{matrix}$$

In Equation (1), I₀ represents drain current when V_{g}=Vₜₕ, q represents elementary charge, V_{g} represents gate voltage, Vₜₕ represents threshold voltage, η represents a coefficient determined by a device structure or the like, k_{B} represents the Boltzmann constant, and T represents temperature. As shown in Equation (1), the drain current Id of the transistor that operates in a subthreshold region does not depend on the drain voltage. Currents flowing in the transistor 24 and the transistor 34 are the amounts of currents flowing when the transistors operate in a subthreshold region. The currents in the transistor 24 and the transistor 34 in a subthreshold region can reduce the influence of variation in drain voltage. Accordingly, the accuracy of data obtained by arithmetic can be increased.

Note that in this specification and the like, a subthreshold region refers to a region where gate voltage is lower than threshold voltage in a graph showing gate voltage (Vg)-drain current (Id) characteristics of a transistor. Alternatively, the subthreshold region refers to a region where current flows due to carrier diffusion, which is out of gradual channel approximation (a model in which only drift current is considered). Alternatively, the subthreshold region refers to a region where drain current increases exponentially with respect to an increase in gate voltage. Alternatively, the subthreshold region includes a region that can be regarded as any region of the above description

Drain current when a transistor operates in the subthreshold region is referred to as subthreshold current. The subthreshold current increases exponentially with respect to gate voltage, regardless of drain voltage. The circuit operation using the subthreshold current can reduce the influence of variation in drain voltage.

The transistor 32 and the transistor 22 have functions of retaining the potentials of the gate of the transistor 24 and the gate of the transistor 34 by being brought into an off state. Specifically, the transistor 32 has functions of retaining a potential corresponding to data supplied to the gate of the transistor 34 through the transistor 32. It is preferred that the transistor 32 and the transistor 22 be OS transistors, for example. It is further preferred that channel formation regions of the transistor 32 and the transistor 22 be each an oxide containing at least one of indium, gallium, and zinc, for example. Instead of the oxide, an oxide containing at least one of indium, an element M (as the element M, for example, one kind or a plurality of kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like can be given), and zinc may be used.

An OS transistor has an extremely low current that flows between its source and drain in an off state, that is, leakage current. With the use of an OS transistor as the transistor 32 and/or the transistor 22, the leakage current of the transistor 32 and/or the transistor 22 can be suppressed, so that the power consumption of the semiconductor device 10 can be reduced. Specifically, a change in the potential retained in each of the gate of the transistor 24 and the gate of the transistor 34 can be extremely small, so that the frequency of refresh operations for the potential can be reduced. The reduction in the frequency of refresh operations can reduce the power consumption of the semiconductor device 10. An extremely low leakage current from the retention node to the wiring WCL or the wiring XCL allows the cell to retain the potential of the retention node for a long time.

Furthermore, an extremely low current, such as a current lower than 1×10⁻²⁰ A, lower than 1×10⁻²² A, or lower than 1×10⁻²⁴ A, can flow in an OS transistor as drain current per micrometer of channel width when the gate voltage is lower than the threshold voltage of the transistor. In addition, a drain current per micrometer of channel width of lower than or equal to 1.0×10⁻⁸ A, lower than or equal to 1.0×10⁻¹² A, or lower than or equal to 1.0×10⁻¹⁵ A can flow in an OS transistor when the gate voltage is equal to the threshold voltage of the transistor. Thus, subthreshold currents with different magnitudes can flow in an OS transistor in a range of the gate voltage in which the transistor operates in a subthreshold region. That is, an OS transistor can have a large range of the gate voltage in which the transistor operates in the subthreshold region. Specifically, when the threshold voltage of an OS transistor is Vₜₕ, a circuit operation using the gate voltage in the voltage range of (Vₜₕ−1.0 V) to Vₜₕ, inclusive, or (Vₜₕ−0.5 V) to Vₜₕ, inclusive, is possible in the subthreshold region.

Meanwhile, a Si transistor has a high off-state current and a narrow range of gate voltage in which the transistor operates in a subthreshold region. In the case of utilizing subthreshold current, an OS transistor can perform a circuit operation in a wider range of gate voltage than a Si transistor.

A metal oxide functioning as an oxide semiconductor has a bandgap of 2.5 eV or greater; thus, an OS transistor has an extremely low off-state current. For example, the off-state current per micrometer in channel width at a source-drain voltage of 3.5 V and at room temperature (25° C.) can be lower than 1×10⁻²⁰ A, lower than 1×10⁻²² A, or lower than 1×10⁻²⁴ A. Therefore, in an OS memory, the amount of electric charge that leaks from a retention node through the OS transistor is extremely small.

A metal oxide used for an OS transistor is a Zn oxide, a Zn—Sn oxide, a Ga—Sn oxide, an In—Ga oxide, an In—Zn oxide, an In-M-Zn oxide (M is Ti, Ga, Y, Zr, La, Ce, Nd, Sn, or Hf), or the like. The use of a metal oxide containing Ga as M for the OS transistor is particularly preferable because the electrical characteristics such as field-effect mobility of the transistor can be made excellent by adjusting a ratio of elements. In addition, an oxide containing indium and zinc may contain one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like.

In order to improve the reliability and electrical characteristics of the OS transistor, it is preferable that the metal oxide used in the semiconductor layer be a metal oxide having a crystal portion such as CAAC-OS, CAC-OS, or nc-OS. CAAC-OS is an abbreviation for c-axis-aligned crystalline oxide semiconductor. CAC-OS is an abbreviation for Cloud-Aligned Composite oxide semiconductor. In addition, nc-OS is an abbreviation for nanocrystalline oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The CAC-OS has a function of allowing electrons (or holes) serving as carriers to flow and a function of not allowing electrons serving as carriers to flow. The function of allowing electrons to flow and the function of not allowing electrons to flow are separated, whereby both functions can be maximized. In other words, when CAC-OS is used for a channel formation region of an OS transistor, a high on-state current and an extremely low off-state current can be both achieved.

An OS transistor is an accumulation transistor in which electrons are majority carriers. Therefore, DIBL (Drain-Induced Barrier Lowering), which is one of short-channel effects, affects an OS transistor less than an inversion transistor having a pn junction. In other words, an OS transistor has higher resistance against short-channel effects than a Si transistor.

The use of OS transistors also as the transistors 33 and 34 and the transistors 23 and 24 enables operation with a wide range of current in the subthreshold regions, leading to a reduction in the current consumption. With the use of OS transistors also as the transistors 33 and 34 and the transistors 23 and 24, the transistors can be manufactured concurrently with the transistor 22 and the transistor 32; thus, the manufacturing process of the arithmetic circuit can sometimes be shortened. Each of the transistors 33 and 34 and the transistors 23 and 24 can be, other than an OS transistor, a transistor containing silicon in its channel formation region (hereinafter, referred to as a Si transistor). As the silicon, amorphous silicon (sometimes referred to as hydrogenated amorphous silicon), microcrystalline silicon, polycrystalline silicon, single crystal silicon, or the like can be used, for example.

In the case where Si transistors are used as the transistors 33 and 34 and the transistors 23 and 24, a structure in which components functioning as back gates of the transistors, such as electrodes or body electrodes, are provided is preferably employed, and potentials supplied to the back gates are preferably the ground potentials supplied to the others of the sources and the drains of the transistors 34 and 24. Owing to the structure, the electrical characteristics of the transistors 33 and 34 and the transistors 23 and 24 can be stabilized.

The transistor 22 and the transistor 32 illustrated in FIG. 1 have back gates; however, the semiconductor device of one embodiment of the present invention is not limited thereto. For example, the transistor 22 and the transistor 32 illustrated in FIG. 1 may each be a transistor having a structure not including a back gate, i.e., a single-gate structure. Potentials or signals supplied to the back gates can be fixed potentials such as ground potentials, or signals that are supplied to the gates.

The transistors 32 to 34 and the transistors 22 to 24 illustrated in FIG. 1 are n-channel transistors; however, the semiconductor device of one embodiment of the present invention is not limited thereto. For example, some or all of the transistors 32 to 34 and the transistors 22 to 24 may be replaced with p-channel transistors. Note that in the case where some or all of the transistors 32 to 34 and the transistors 22 to 24 are replaced with p-channel transistors, voltage supplied from a wiring may be changed as necessary such that the transistors 32 to 34 and the transistors 22 to 24 perform the desired operation, for example.

Note that the above-described examples of changes in the structure and polarity of the transistor are applied not only to the transistors 32 to 34 and to the transistors 22 to 24. For example, the structure, the polarity, or the like of a transistor described in other parts of the specification or a transistor illustrated in other drawings may also be changed.

Next, the wiring WSL, the wiring XCL, the wiring VBL, and the wiring WCL connected to the reference cell 21 and the arithmetic cell 31 will be described.

A signal for controlling on/off of the transistor 22 and the transistor 32 functioning as switches is supplied to the wiring WSL. The wiring WSL functions as a write word line for writing data to the reference cell 21 and the arithmetic cell 31. By supply of current or voltage corresponding to data to be written to the wiring XCL or the wiring WCL, the data is written to the reference cell 21 and the arithmetic cell 31. The data is written when the transistor 22 and the transistor 32 are turned on. In this case, the wiring WCL is set to an H level (high level potential). When the transistor 22 and the transistor 32 in the reference cell 21 and the arithmetic cell 31 are controlled to be turned off, the data is retained in the reference cell 21 and the arithmetic cell 31. In this case, the wiring WCL is set to an L level (low level potential).

The wiring WCL has a function of supplying the amount of current (weight current or current I_{Wut}) corresponding to the weight data (also referred to as first data or first input data) to the arithmetic cell 31, or a function of supplying a constant potential Vd for supplying current in accordance with the potential retained in the arithmetic cell.

The wiring XCL has a function of supplying the amount of current (reference current or current I_{Xut}) corresponding to reference data or the amount of current (input current or current I_{X}) corresponding to the input data (also referred to as second data or second input data) to the reference cell 21 and the arithmetic cell 31.

The wiring VBL is a wiring from which a constant potential Vb is supplied. The constant potential Vb is a potential for fixing the potential of a drain terminal of each of the transistor 24 and the transistor 34 in the reference cell 21 and the arithmetic cell 31. When the constant potential Vb is supplied to the gates of the transistor 23 and the transistor 33, the transistor characteristics such as the threshold voltage of the transistor 24 and the transistor 34, which correspond to a change in the potential of the wiring WCL, can be stabilized.

In the case where the transistor 34 and the transistor 24 are short-channel transistors whose channel lengths are short, in particular, drain-induced barrier lowering (DIBL) reduces the threshold voltage; thus, the drain current Id depends on drain voltage Vd. Accordingly, a configuration in which the constant potential Vb is supplied to the gates of the transistor 23 and the transistor 33 to reduce a change in drain voltage of the transistor 24 and the transistor 34 is effective. This configuration can increase the accuracy of data obtained by arithmetic.

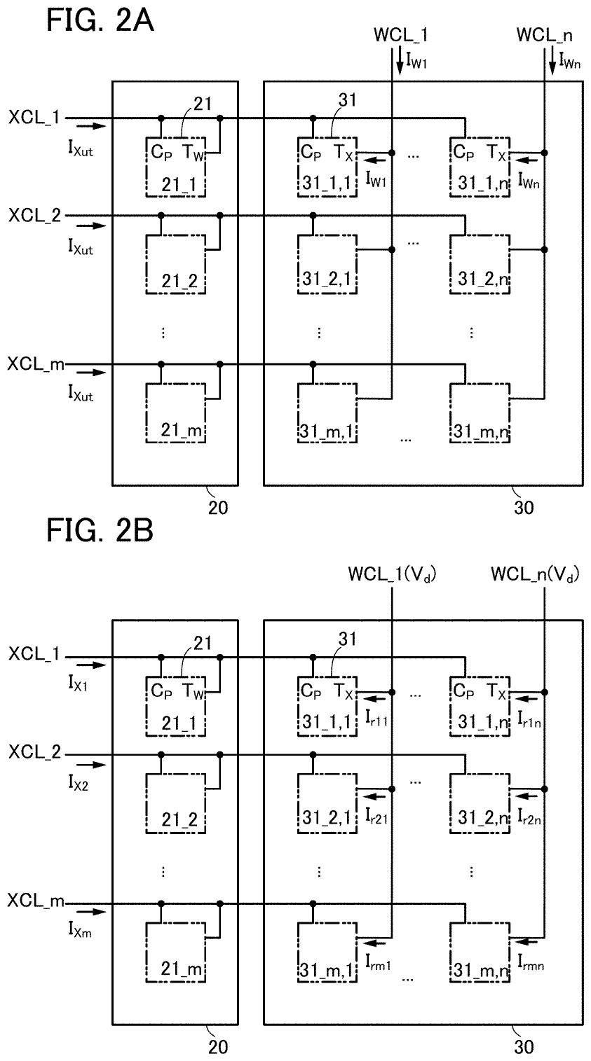

Next, a structure in which a plurality of the reference cells 21 and the arithmetic cells 31, each of which is in FIG. 1, will be described with reference to FIG. 2A and FIG. 2B. FIG. 2A illustrates a schematic operation at the time of data writing and FIG. 2B illustrates a schematic operation at the time of data reading.

In FIG. 2A and FIG. 2B, a reference cell portion 20 provided with a plurality of reference cells 21_1 to 21_m (each of which corresponds to the reference cell 21 in FIG. 1), and an arithmetic cell portion 30 provided with a plurality of arithmetic cells 31_1,1 to 31_m,n (each of which corresponds to the arithmetic cell 31 in FIG. 1) are provided. FIG. 2A and FIG. 2B illustrate a plurality of wirings XCL as wirings XCL_1 to XCL_m. Furthermore, FIG. 2A and FIG. 2B illustrate a plurality of wirings WCL as wirings WCL_1 to WCL_n. Note that m and n are each a natural number.

In FIG. 2A and FIG. 2B, the cells included in the reference cell portion 20 and the arithmetic cell portion 30 are arranged in a matrix including n+1 cells in the row direction and m cells in the column direction. Any structure is acceptable as long as the cells included in the reference cell portion 20 and the arithmetic cell portion 30 are arranged in a matrix including two or more cells in the row direction and one or more cells in the column direction.

FIG. 2A and FIG. 2B illustrate the reference cell 21 and the arithmetic cell 31 in a simplified manner for the description. Terminals C_{P} of the reference cells 21 in the reference cell portion 20 each correspond to the other electrode of the capacitor 25 in FIG. 1. Terminal Tw of the reference cells 21 in the reference cell portion 20 each correspond to a terminal to which the one of the source and the drain of the transistor 22 and the one of the source and the drain of the transistor 23 are connected in FIG. 1. The terminals C_{P} of the arithmetic cells 31 in the arithmetic cell portion 30 each correspond to the other electrode of the capacitor 35 in FIG. 1. Terminals T_{X} of the arithmetic cells 31 in the arithmetic cell portion 30 each correspond to a terminal to which the one of the source and the drain of the transistor 32 and the one of the source and the drain of the transistor 33 are connected in FIG. 1.

In a data writing operation illustrated in FIG. 2A, the current I_{Xut} is supplied to the reference cell 21 in each row. The current supplied to each row is the current I_{Xut} which is normalized, and is equivalent for each row. The current I_{Xut} corresponds to the amount of current (reference current) corresponding to the reference data. The current does not flow in the arithmetic cells 31 in each row because the arithmetic cells 31 are connected through the capacitors. The reference cell 21 operates such that voltage corresponding to the current flowing therein is retained.

Furthermore, in the data writing operation illustrated in FIG. 2A, currents I_{W1} to I_{Wn} (I_{W}) are supplied to arithmetic cells in the respective columns. Each of the currents supplied to the respective columns corresponds to the amount of current obtained by multiplying the current I_{Wut} which is normalized by weight data w (I_{W}=w×I_{Wut}). The currents I_{W1} to I_{Wn} may be different for each column.

In a data reading operation illustrated in FIG. 2B, currents I_{X1} to I_{Xm} (I_{X}) are supplied to the reference cell 21 in the respective rows. Each of the currents I_{X1} to I_{Xm} supplied to the respective rows corresponds to the amount of current obtained by multiplying the normalized current I_{Xut} by input data x (I_{X}=x×I_{Xut}). The currents I_{X1} to I_{Xm} may be different for each row. Note that the current I_{Xut} is preferably equivalent to the current I_{Wut}.

In the data reading operation illustrated in FIG. 2B, the voltages retained in the reference cells 21 are boosted by the currents I_{X1} to I_{Xm}. In accordance with the boosting, the voltages of the wirings XCL_1 to XCL_m are also boosted; thus, voltages retained in the arithmetic cells 31 are boosted by capacitive coupling of the capacitors 35. Then, the potentials of the wirings WCL_1 to WCL_n are set to the voltage Vd. At this time, the amount Iᵣ of current flowing in the transistor 34 corresponds to the product of the current value (I_{W}) retained in the arithmetic cell 31 at the time of data writing and the current value (I_{X}) supplied to the reference cell 21 at the time of data reading (currents Iᵣ₁₁ to Iᵣₘₙ). Estimation of the sum of the currents Iᵣ₁₁ to Iᵣₘ flowing in each column can result in output of data corresponding to the result of the product-sum operation of the input data and the weight data.

Note that the transistors 32 to 34 included in each of the cells in the arithmetic cell portion preferably have the same size (e.g., channel length, channel width, and transistor structure). Furthermore, the transistors 22 to 24 included in each of the cells in the reference cell portion 20 preferably have the same size. Furthermore, the transistor 22 and the transistor 32 preferably have the same size. Furthermore, the transistor 23 and the transistor 33 preferably have the same size. Furthermore, the transistor 24 and the transistor 34 preferably have the same size.

By making the transistors have the same size, the transistors can have substantially the same electrical characteristics. Thus, by making the transistors 32 included in the cell 31_1,1 to the cell 31_m,n have the same size, making the transistors 33 included in the cell 31_1,1 to the cell 31_m,n have the same size, and making the transistors 34 included in the cell 31_1,1 to the cell 31_m,n have the same size, the cell 31_1,1 to the cell 31_m,n can perform substantially the same operation when under the same conditions. The same conditions here mean, for example, input potentials to the source, the drain, the gate, and the like of the transistor 32, input potentials to the source, the drain, the gate, and the like of the transistor 33, input potentials to the source, the drain, the gate, and the like of the transistor 34, and voltage retained in each of the cell 31_1,1 to the cell 31_m,n. Furthermore, by making the transistors 22 included in the cell 21_1 to the cell 21_m have the same size, making the transistors 23 included in the cell 21_1 to the cell 21_m have the same size, and making the transistors 24 included in the cell 21_1 to the cell 21_m have the same size, for example, the cell 21_1 to the cell 21_m can perform substantially the same operation and can have substantially the same result of the operation. In the case of the same conditions, the cell 21_1 to the cell 21_m can perform substantially the same operation. The same conditions here mean, for example, input potentials to the source, the drain, the gate, and the like of the transistor 22, input potentials to the source, the drain, the gate, and the like of the transistor 23, input potentials to the source, the drain, the gate, and the like of the transistor 24, and voltage retained in each of the cell 21_1 to the cell 21_m.

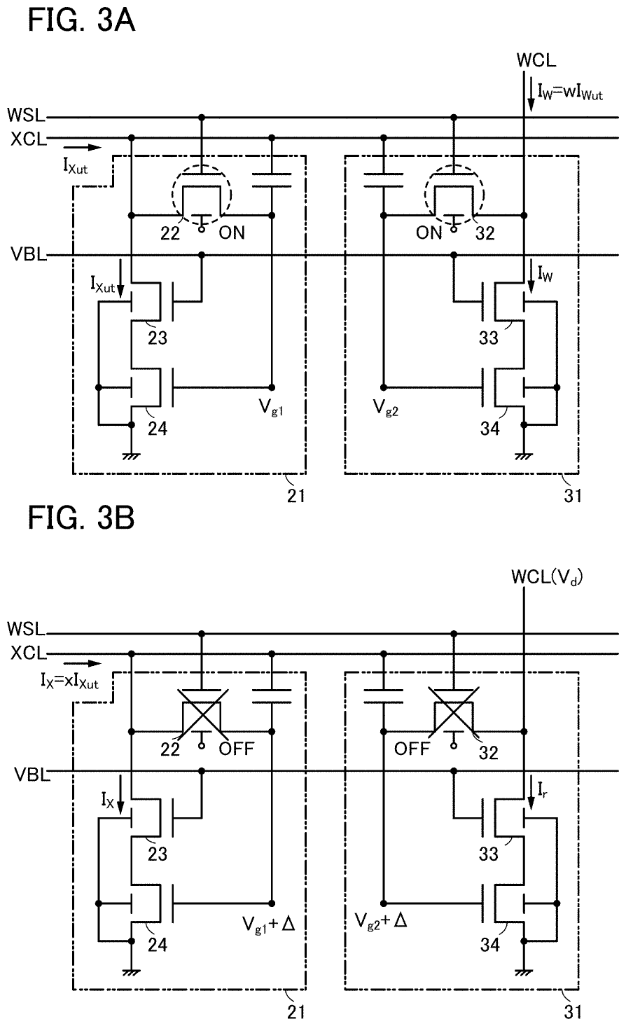

The operation of the reference cell 21 and the arithmetic cell 31 at the time of data writing will be described with reference to FIG. 3A.

The wiring WSL is set to an H level so that the transistor 22 and the transistor 32 are brought into an on state (ON). The current I_{Xut} that corresponds to the reference current is supplied to the wiring XCL. Furthermore, the current I_{W} is supplied to the wiring WCL. The current I_{W} corresponds to current obtained by multiplying the weight data w by the normalized current I_{Wut} (I_{W}=wI_{Wut} in the drawing).

In the reference cell 21, the transistor 22 is brought into an on state. The potential of the retention node, which is the gate of the transistor 24, becomes a potential V_{g1} at which the current I_{Xut} flows in the transistor 24. Accordingly, the transistor 24 enables the current of the current I_{Xut} to flow between the source and the drain of the transistor 24. In this specification and the like, such operation is rephrased as, for example, “setting (programming) the current flowing between the source and the drain of the transistor 24 in the reference cell 21 to I_{Xut}” in some cases.

In the arithmetic cell 31, the transistor 32 is brought into an on state. The potential of the retention node, which is the gate of the transistor 34, becomes a potential V_{g2} at which the current I_{W} flows in the transistor 34. Accordingly, current flowing between the source and the drain of the transistor 34 in the arithmetic cell 31 is set to I_{W}.

The current I_{Xut} supplied to the reference cell 21 through the wiring XCL at the time of data writing can be represented by Equation (2).

$$\begin{matrix}[ Formula 2 ] & \\ {I}_{Xut} = {I}_{0} exp ( \frac{( {V}_{g 1} - {V}_{th {1}^{′}} )}{η {k}_{B} T / q} ) & ( 2 )\end{matrix}$$

In Equation (2), V_{g1} is the potential of the retention node, which is the gate of the transistor 24. In Equation (2), Vₜₕ₁′ is the threshold voltage of the transistor 24.

The current I_{W} supplied to the arithmetic cell 31 through the wiring WCL at the time of data writing can be represented by Equation (3).

$$\begin{matrix}[ Formula 3 ] & \\ {I}_{W} = {I}_{0} exp ( \frac{( {V}_{g 2} - {V}_{th 1} )}{η {k}_{B} T / q} ) = {wI}_{Wut} & ( 3 )\end{matrix}$$

In Equation (3), V_{g2} is the potential of the retention node, which is the gate of the transistor 34. In Equation (3), Vₜₕ₁ is the threshold voltage of the transistor 34. The current I_{W} can be expressed as the product of the weight data w and the normalized current I_{Wut}.

The voltage Vb supplied to the wiring VBL satisfies, when Vₜₕ₂ is the threshold voltage of the transistor 33 and Vth2′ is the threshold voltage of the transistor 23, Vb>Vth2′ and Vb>Vth2. Owing to the structure, the drain voltage of the transistor 24 can be (Vb−Vth2). Thus, the drain voltage of the transistor 34 can be (Vb−Vth2′). In other words, the drain voltages of the transistor 24 and the transistor 34 can be set to potentials which do not depend on the potentials of the wiring WCL and the wiring XCL. Thus, a reduction in the threshold voltage of each of the transistor 34 and the transistor 24 due to DIBL is inhibited, which enables an increase in the accuracy of data obtained by arithmetic.

The operation of the reference cell 21 and the arithmetic cell 31 at the time of data reading is described with reference to FIG. 3B. Note that a period in which the set current is retained can be provided in a period between data writing and data reading. In the period in which the set current is retained, the transistor 22 and the transistor 32 are brought into an off state (OFF). When OS transistors are used as the transistor 22 and the transistor 32, each of them can keep retaining the potential of the retention node corresponding to the set current.

In the reference cell 21, the wiring WSL is set to an L level so that the transistor 22 is brought into an off state (OFF). The current I_{X} that corresponds to the input current is supplied to the wiring XCL. The current I_{X} corresponds to current obtained by multiplying the input data x by the normalized current I_{Xut} (I_{X}=xI_{Xut} in the drawing). The potential of the retention node, which is the gate of the transistor 24, changes as denoted by V_{g1}+Δ when the current I_{X} flows in the transistor 24, and the potential of the wiring XCL also changes accordingly.

In the arithmetic cell 31, the wiring WSL is set to an L level so that the transistor 32 is brought into an off state (OFF). Accordingly, the retention node in the arithmetic cell 31 is in an electrically floating state (floating). By capacitive coupling of the capacitor 35 due to the change in the potential of the wiring XCL by the operation of the reference cell 21, the potential V_{g2} of the retention node in the arithmetic cell 31 changes to V_{g1}+Δ. When the potential of the retention node in the arithmetic cell 31 changes to V_{g2}+Δ, the current Iᵣ flows in the transistor 34 in the arithmetic cell 31.

The current I_{X} supplied to the reference cell 21 through the wiring WSL at the time of data reading can be represented by Equation (4). V_{g1}+Δ is a change in the potential of the retention node in the reference cell 21 caused when the current I_{X} is supplied to the reference cell 21.

$$\begin{matrix}[ Formula 4 ] & \\ {I}_{X} = {I}_{0} exp ( \frac{( {V}_{g 1} + Δ - {V}_{th {1}^{′}} )}{η {k}_{B} T / q} ) = {xI}_{Xut} & ( 4 )\end{matrix}$$

In Equation (4), Δ can be expressed using the input data x shown in Equation (5).

$$\begin{matrix}[ Formula 5 ] & \\ x = exp ( \frac{Δ}{η {k}_{B} T / q} ) & ( 5 )\end{matrix}$$

From Equation (4) and Equation (5), the current I_{X} can be expressed as the product of the input data x and the normalized current I_{Xut}.

The wiring WCL is set to the voltage V_{d} at the time of data reading so that currents flow in the arithmetic cells 31 in each row. Then, the potential of the retention node in each of the arithmetic cells 31 changes to V_{g2}+Δ, whereby the current Iᵣ flowing in the transistor 34 in each of the arithmetic cells 31 can be represented by Equation (6).

$$\begin{matrix}[ Formula 6 ] & \\ {I}_{r} = {I}_{0} exp ( \frac{( {V}_{g 2} + Δ - {V}_{th 1} )}{η {k}_{B} T / q} ) = {wxI}_{Wut} & ( 6 )\end{matrix}$$

From Equation (3) and Equation (5), Iᵣ in Equation (6) can be estimated as current corresponding to the product of the weight data w and the input data x. Since currents flowing in the arithmetic cells 31 in each row can be added, a signal corresponding to the arithmetic result obtained by product-sum operation processing of the weight data w and the input data x can be output when current flowing through the wiring WCL is output to the outside.

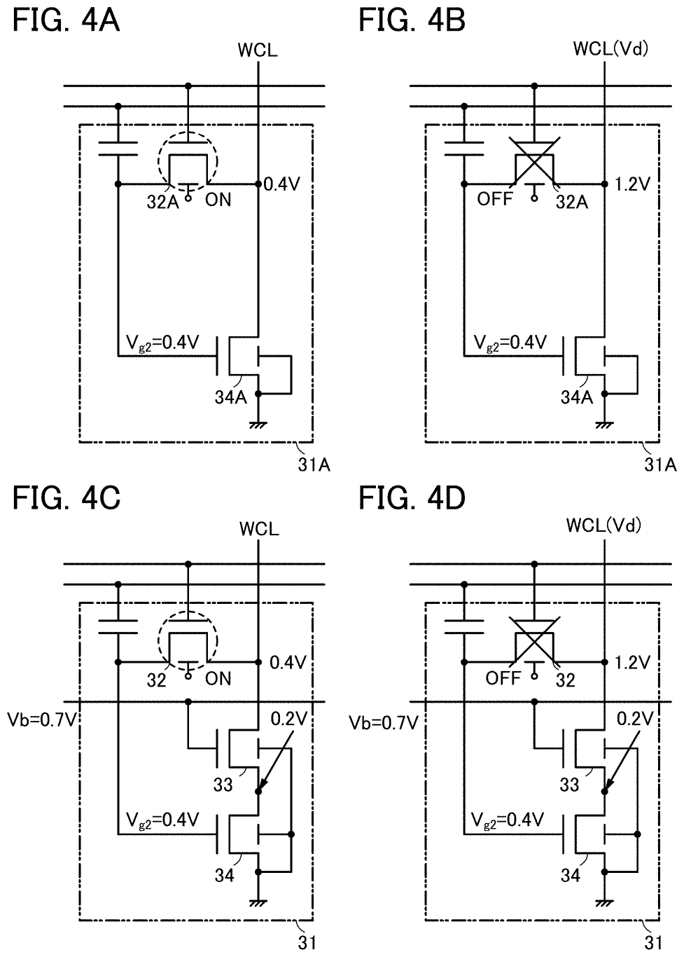

An arithmetic cell 31A illustrated in FIG. 4A and FIG. 4B is a circuit diagram illustrating a comparative example not including the transistor 22 and the transistor 33 of the semiconductor device 10 in FIG. 1. Note that the threshold value of a transistor 34A included in the arithmetic cell 31A is 0.5 V in FIG. 4A and FIG. 4B for the description of a specific operation example. The potential Vb is 0.7 V.

In a data writing operation illustrated in FIG. 4A, when a transistor 32A is turned on, a voltage of 0.4 V for feeding the current I_{W} is written as the above-described V_{g2} to a retention node, which is a gate of the transistor 34A.

In a data reading operation illustrated in FIG. 4B, the transistor 32A is turned off and V_{d}, which corresponds to the potential of the wiring WCL, is set to 1.2 V. Since the current Iᵣ needs to be fed in arithmetic cells in each row, V_{d} needs to be set slightly higher in the data reading operation.

In the arithmetic cell 31A in a semiconductor device 10B illustrated in FIG. 4A and FIG. 4B, the drain voltages of the transistor 34A in the data writing operation and in the data reading operation are 0.4 V and 1.2 V, respectively, leading to a large voltage difference. As a result, the current Iᵣ flowing in the arithmetic cell 31A greatly varies.

The semiconductor device 10 of one embodiment of the present invention is described with reference to FIG. 4C and FIG. 4D. For comparison, FIG. 4C and FIG. 4D illustrate the cases where operations similar to those in FIG. 4A and FIG. 4B are performed.

FIG. 4C and FIG. 4D each illustrate the components of the arithmetic cell 31. In FIG. 4C and FIG. 4D, the threshold voltage of each of the transistor 33 and the transistor 34 is 0.5 V. The potential Vb is 0.7 V.

In a data writing operation illustrated in FIG. 4C, when the transistor 32 is turned on, a voltage of 0.4 V for feeding the current I_{W} is written as the above-described V_{g2} to the retention node, which is the gate of the transistor 34. In FIG. 4C, the drain voltage of the transistor 34 is 0.2 V, which is voltage decreased from the voltage Vb by the threshold voltage of the transistor 33.

In a data reading operation illustrated in FIG. 4D, the transistor 32 is turned off and V_{d}, which corresponds to the voltage of the wiring WCL, is set to 1.2 V. Since the current Iᵣ needs to be fed in arithmetic cells in each row, V_{d} needs to be set slightly higher in the data reading operation. In FIG. 4D, the drain voltage of the transistor 34 is 0.2 V, which is voltage decreased from the voltage Vb by the threshold voltage of the transistor 33, as in FIG. 4C.

In the arithmetic cell 31 illustrated in FIG. 4C and FIG. 4D, the drain voltage of the transistor 34A is 0.2 V in both the data writing operation and the data reading operation, leading to a small voltage difference. As a result, variation in the current Iᵣ flowing in the arithmetic cell 31 can be small.

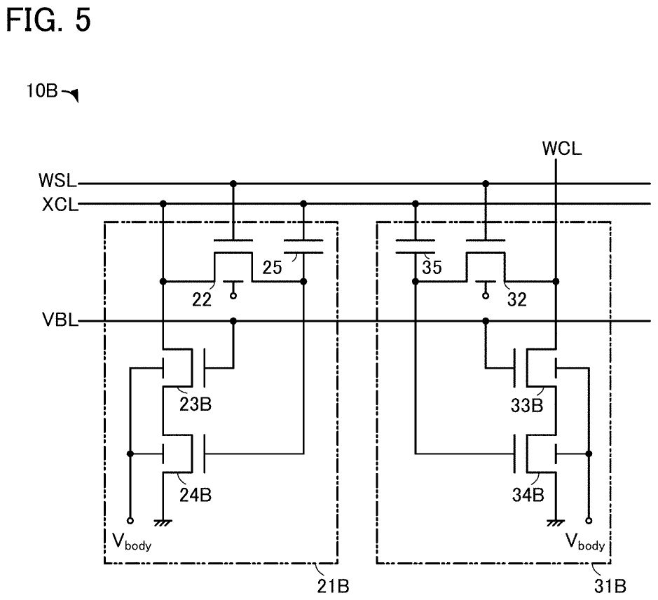

A modification example of the semiconductor device 10 illustrated in FIG. 1 will be described with reference to the semiconductor device 10B illustrated in FIG. 5. In the description of FIG. 5, points different from those of FIG. 1 are described and description of the same components is omitted.

The semiconductor device 10B illustrated in FIG. 5 includes a reference cell 21B and an arithmetic cell 31B. The reference cell 21B includes the transistor 22, a transistor 23B, a transistor 24B, and the capacitor 25. The arithmetic cell 31B includes the transistor 32, a transistor 33B, a transistor 34B, and the capacitor 35.

Voltage V_{body} is applied to back gates of the transistor 23B and the transistor 24B. The voltage V_{body} is voltage lower than the ground potential. The transistor characteristics of the transistor 23B and the transistor 24B are stabilized.

Similarly, the voltage V_{body} is applied to back gates of the transistor 33B and the transistor 34B. The transistor characteristics of the transistor 33B and the transistor 34B are stabilized.

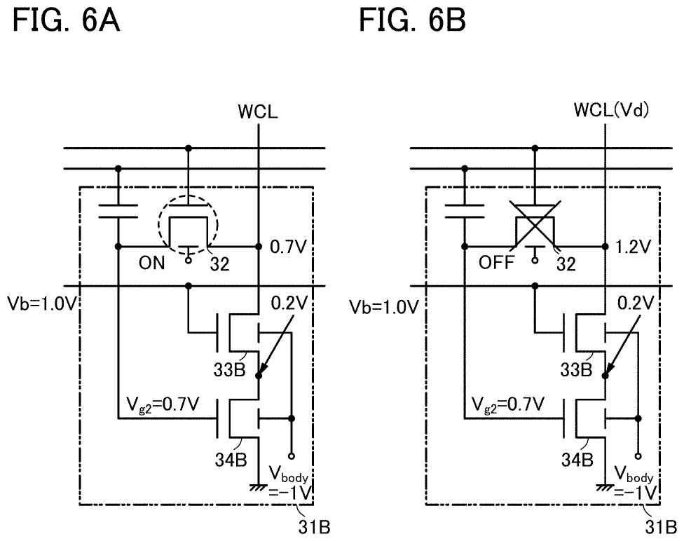

Description of the semiconductor device 10B in FIG. 5, which is similar to the description of FIG. 4A and FIG. 4B and the description of FIG. 4C and FIG. 4D, will be made with reference to FIG. 6A and FIG. 6B.

FIG. 6A and FIG. 6B each illustrate the components of the arithmetic cell 31B. In FIG. 6A and FIG. 6B, the threshold voltage of each of the transistor 33B and the transistor 34B is 0.8 V. The voltage Vb is 1.0 V. The threshold voltage of each of the transistor 33B and the transistor 34B is described as voltage shifted in a positive direction from 0.5 V to 0.8 V, for example, by a voltage V_{body} of −1 V, for example.

In a data writing operation illustrated in FIG. 6A, when the transistor 32 is turned on, a voltage of 0.7 V for feeding the current I_{W} is written as the above-described V_{g2} to a retention node, which is a gate of the transistor 34B. In FIG. 6A, the drain voltage of the transistor 34B is 0.2 V, which is voltage decreased from the voltage Vb by the threshold voltage of the transistor 33B.

In a data reading operation illustrated in FIG. 6B, the transistor 32 is turned off and V_{d}, which corresponds to the voltage of the wiring WCL, is set to 1.2 V. Since the current Iᵣ needs to be fed in arithmetic cells in each row, V_{d} needs to be set slightly higher in the data reading operation. In FIG. 4D, the drain voltage of the transistor 34B is 0.2 V, which is voltage decreased from the voltage Vb by the threshold voltage of the transistor 33B, as in FIG. 6A.

In the arithmetic cell 31B illustrated in FIG. 6A and FIG. 6B, the drain voltage of the transistor 34B is 0.2 V in both the data writing operation and the data reading operation, leading to a small voltage difference. As a result, variation in the current Iᵣ of the arithmetic cell subjected to reading can be small.

In addition, in the arithmetic cell 31B illustrated in FIG. 6A and FIG. 6B, a change in the drain voltage of the transistor 33B can be made small by the voltage V_{body}. For example, the difference of the drain voltage of the transistor 33B between the data writing operation and the data reading operation is 0.5 V (difference between 1.2 V and 0.7 V) in FIG. 6A and FIG. 6B. Meanwhile, in FIG. 4C and FIG. 4D in which the ground potential is used as the voltage V_{body}, the difference of the drain voltage of the transistor 33B between the data writing operation and the data reading operation is 0.8 V (difference between 1.2 V and 0.4 V).

From the above, the semiconductor device 10B in FIG. 5 can inhibit variation in the transistor characteristics due to the change in drain voltage and can make variation in the current Iᵣ in the data reading operation small.

As described above, one embodiment of the present invention can provide a semiconductor device in which the accuracy of data to be read is increased.

### Embodiment 2

In this embodiment, an example of an arithmetic device, which is a device to which the semiconductor device of one embodiment of the present invention can be applied, will be described. The arithmetic device includes a circuit capable of performing product-sum operation. The arithmetic device is referred to as an arithmetic circuit in some cases.

### Configuration Example of Arithmetic Device

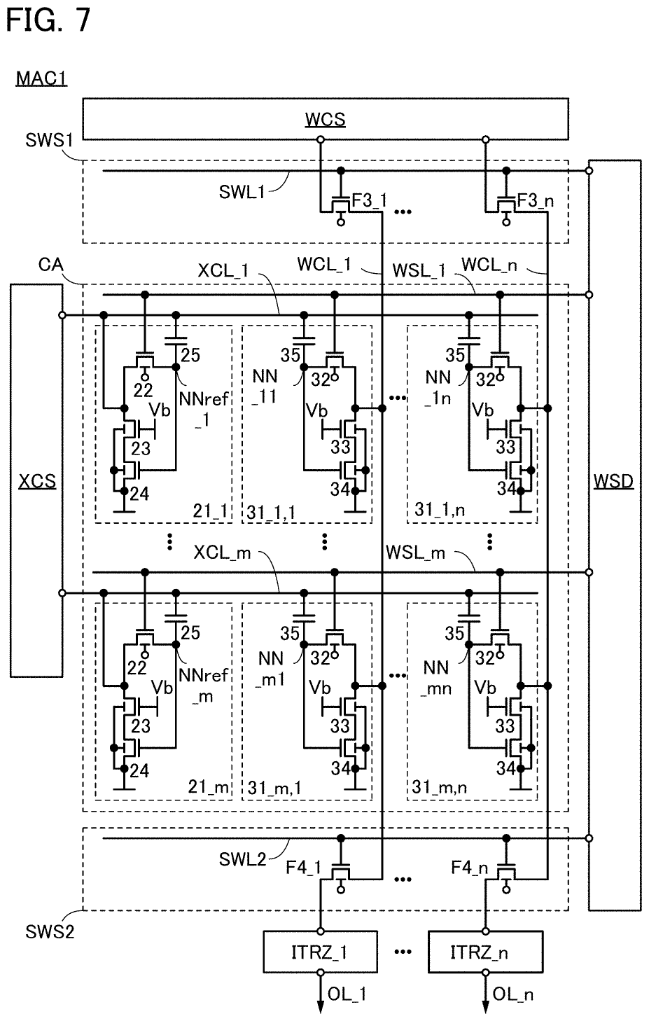

FIG. 7 illustrates a configuration example of an arithmetic device that performs product-sum operation of first data and second data. An arithmetic device MAC1 illustrated in FIG. 7 is a circuit that performs product-sum operation of the first data (weight data) corresponding to a potential retained in each cell and the input second data (input data), and performs arithmetic of an activation function with the use of the product-sum operation result. Note that the first data and the second data can be analog data or multilevel data (discrete data), for example.

The arithmetic device MAC1 includes a circuit WCS, a circuit XCS, a circuit WSD, a circuit SWS1, a circuit SWS2, a cell array CA, and a converter circuit ITRZ_1 to a converter circuit ITRZ_n.

The cell array CA includes the cell 31_1,1 to the cell 31_m,n and the cell 21_1 to the cell 21_m. Each of the cell 31_1,1 to the cell 31_m,n includes, for example, the transistor 32, the transistor 33, the transistor 34, and the capacitor 35 like the arithmetic cell 31 described in the above embodiment. Each of the cell 21_1 to the cell 21_m includes, for example, the transistor 22, the transistor 23, the transistor 24, and the capacitor 25 like the reference cell 21 described in the above embodiment. Note that in the following description, “one of a source and a drain” and “the other of the source and the drain” described in Embodiment 1 above are described as “first terminal” and “second terminal, respectively, in some cases. Furthermore, in the following description, “one electrode” and “the other electrode” of a capacitor are described as “first terminal” and “second terminal”, respectively, in some cases.

In FIG. 7, a connection portion of a first terminal of the transistor 32, the gate of the transistor 34, and a first terminal of the capacitor 35 in the cell 31_1,1 is a node NN_11. Similarly, similar connection portions in the cell 31_1, n, the cell 31_m,l, and the cell 31_m,n in FIG. 7 are a node NN_1n, a node NN_m1, and a node NN_mn. Similarly, similar connection portions in the cell 21_1 and the cell 21_m in FIG. 7 are a node NN_ref1 and a node NNref_m. Note that the node NN_11 to the node NN_mn and a node NNref_1 to the node NNref_m function as retention nodes in their respective cells.

The circuit SWS1 includes a transistor F3_1 to a transistor F3_n, for example. A first terminal of the transistor F3_1 is electrically connected to a wiring WCL_1, a second terminal of the transistor F3_1 is electrically connected to the circuit WCS, and a gate of the transistor F3_1 is electrically connected to a wiring SWL1. A first terminal of the transistor F3_n is electrically connected to a wiring WCL_n, a second terminal of the transistor F3_n is electrically connected to the circuit WCS, and a gate of the transistor F3_n is electrically connected to the wiring SWL1.

A transistor that can be used as any of the transistors included in the cell array CA can be used as each of the transistor F3_1 to the transistor F3_n, for example. It is particularly preferable to use an OS transistor as each of the transistor F3_1 to the transistor F3_n.

The circuit SW functions as a circuit that makes the conduction state or the non-conduction state between the circuit WCS and each of the wiring WCL_1 to the wiring WCL_n.

The circuit SWS2 includes a transistor F4_1 to a transistor F4_n, for example. A first terminal of the transistor F4_1 is electrically connected to the wiring WCL_1, a second terminal of the transistor F4_1 is electrically connected to an input terminal of the converter circuit ITRZ_1, and a gate of the transistor F4_1 is electrically connected to a wiring SWL2. A first terminal of the transistor F4_n is electrically connected to the wiring WCL_n, a second terminal of the transistor F4_n is electrically connected to an input terminal of the converter circuit ITRZ_n, and a gate of the transistor F4_n is electrically connected to the wiring SWL2.

A transistor that can be used as any of the transistors included in the cell array CA can be used as each of the transistor F4_1 to the transistor F4_n, for example. It is particularly preferable to use an OS transistor as each of the transistor F4_1 to the transistor F4_n.

The circuit SWS2 has a function of making the conduction state or the non-conduction state between the wiring WCL_1 and the converter circuit ITRZ_1 and between the wiring WCL_n and the converter circuit ITRZ_n.

The circuit WCS has a function of supplying data that is to be stored in each cell of the cell array CA.

The circuit XCS is electrically connected to a wiring XCL_1 to a wiring XCL_m. The circuit XCS has a function of feeding current with the amount corresponding to reference data described later or current with the amount corresponding to the second data to each of the cell 21_1 and the cell 21_m included in the cell array CA.

The circuit WSD is electrically connected to a wiring WSL_1 to a wiring WSL_m. The circuit WSD has a function of selecting a row of the cell array CA to which the first data is written, by supplying a predetermined signal to the wiring WSL_1 to the wiring WSL_m at the time of writing the first data to the cell 31_1,1 to the cell 31_m,n. That is, the wiring WSL_1 to the wiring WSL_m function as write word lines.

The circuit WSD is electrically connected to the wiring SWL1 and the wiring SWL2, for example. The circuit WSD has a function of establishing or breaking electrical continuity between the circuit WCS and the cell array CA by supplying a predetermined signal to the wiring SWL1, and a function of establishing or breaking electrical continuity between the cell array CA and each of the converter circuit ITRZ_1 to the converter circuit ITRZ_n by supplying a predetermined signal to the wiring SWL2.

The converter circuit ITRZ_1 to the converter circuit ITRZ_n each include an input terminal and an output terminal, for example. An output terminal of the converter circuit ITRZ_1 is electrically connected to a wiring OL_1, and an output terminal of the converter circuit ITRZ_n is electrically connected to a wiring OL_n, for example.

The converter circuit ITRZ_1 to the converter circuit ITRZ_n each have a function of converting current into voltage according to the amount of the current when the current is input to the input terminal and outputting the voltage from the output terminal. The voltage can be, for example, an analog voltage, a digital voltage, and the like. The converter circuit ITRZ_1 to the converter circuit ITRZ_n may each include an arithmetic circuit of a function system. In that case, for example, the arithmetic circuit may perform arithmetic of a function with the use of the converted voltage and may output the arithmetic results to the wiring OL_1 to the wiring OL_n.

In particular, in the case of performing arithmetic of the hierarchical neural network, a sigmoid function, a tanh function, a softmax function, a ReLU function, a threshold function, or the like can be used as the above-described function.

### <<Circuit WCS and Circuit XCS>>

Here, specific examples of the circuit WCS and the circuit XCS will be described.

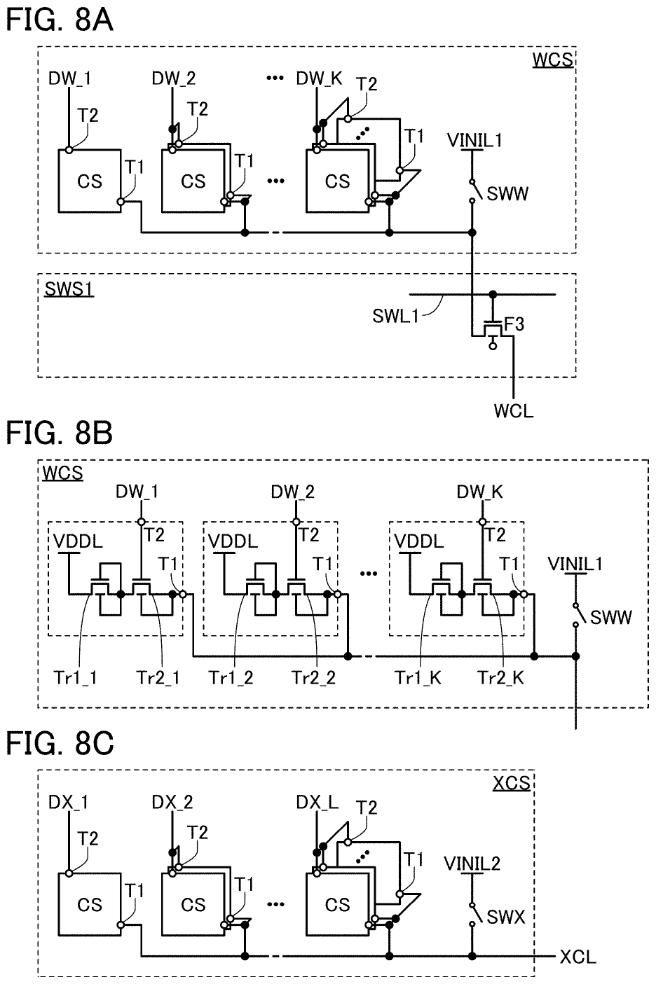

First, the circuit WCS is described. FIG. 8A is a block diagram illustrating an example of the circuit WCS. In FIG. 8A, to illustrate the electrical connection between the circuit WCS and its peripheral circuits, the circuit SWS1, a transistor F3, the wiring SWL1, and the wiring WCL are also illustrated. The transistor F3 is any one of the transistor F3_1 to the transistor F3_n included in the arithmetic device MAC1 in FIG. 7, and the wiring WCL is any one of the wiring WCL_1 to the wiring WCL_n included in the arithmetic device MAC1 in FIG. 7.

The circuit WCS illustrated in FIG. 8A includes a switch SWW, for example. A first terminal of the switch SWW is electrically connected to the second terminal of the transistor F3, and a second terminal of the switch SWW is electrically connected to a wiring VINIL1. The wiring VINIL1 functions as a wiring for supplying an initialization potential to the wiring WCL, and the initialization potential can be set to a ground potential (GND), a low-level potential, a high-level potential, or the like. The switch SWW is in an on state only when the initialization potential is supplied to the wiring WCL; otherwise, the switch is in an off state.

As the switch SWW, an electrical switch such as an analog switch or a transistor can be used, for example. Note that in the case where a transistor is used as the switch SWW, for example, the transistor can be a transistor that can be used as any of the transistors included in the cell array CA, for example. Other than the electrical switch, a mechanical switch may be used.

The circuit WCS in FIG. 8A includes a plurality of current sources CS, for example. Specifically, the circuit WCS has a function of outputting K-bit first data (2K values) (K is an integer greater than or equal to 1) as current; in this case, the circuit WCS includes 2K−1 current sources CS. The circuit WCS includes one current source CS that outputs information corresponding to the first bit value as current, two current sources CS that output information corresponding to the second bit value as current, and the 2K−1 current sources CS that output information corresponding to the K-th bit value as current.

Each of the current sources CS in FIG. 8A includes a terminal T1 and a terminal T2. The terminal T1 of each of the current sources CS is electrically connected to the second terminal of the transistor F3 included in the circuit SWS1. The terminal T2 of the one current source CS is electrically connected to a wiring DW_1, the terminals T2 of the two current sources CS are electrically connected to a wiring DW_2, and the terminals T2 of the 2^{K-1} current sources CS are electrically connected to a wiring DW_K.

The plurality of current sources CS included in the circuit WCS have a function of outputting the same constant current I_{Wut} from the terminals T1. The constant current I_{Wut} corresponds to the normalized current I_{Wut} described in Embodiment 1. In practice, at the manufacturing stage of the arithmetic device MAC1, transistors included in the current sources CS may have different electrical characteristics; this may yield an error. The error in the constant current I_{Wut} output from each of the terminals T1 of the plurality of current sources CS is thus preferably within 10%, further preferably within 5%, still further preferably within 1%. In this embodiment, the description is made on the assumption that there is no error in the constant current I_{Wut} output from each of the terminals T1 of the plurality of current sources CS included in the circuit WCS.

The wiring DW_1 to the wiring DW_K function as wirings for transmitting control signals to make the current sources CS, which are electrically connected to the wiring DW_1 to the wiring DW_K, output the constant currents I_{Wut}. Specifically, for example, when a high-level potential is supplied to the wiring DW_1, the current source CS electrically connected to the wiring DW_1 supplies I_{Wut} as a constant current to the second terminal of the transistor F3, and when a low-level potential is supplied to the wiring DW_1, the current source CS electrically connected to the wiring DW_1 does not output I_{Wut}.

The current flowing from the one current source CS electrically connected to the wiring DW_1 corresponds to the value of the first bit, the current flowing from the two current sources CS electrically connected to the wiring DW_2 corresponds to the value of the second bit, and the current flowing from the K current sources CS electrically connected to the wiring DW_K corresponds to the value of the K-th bit.

FIG. 8A illustrates the circuit WCS with K of an integer greater than or equal to 3; when K is 1, a configuration in which the current sources CS electrically connected to the wiring DW_2 to the wiring DW_K are not provided in the circuit WCS in FIG. 8A can be employed. When K is 2, a configuration in which the current sources CS electrically connected to the wiring DW_3 to the wiring DW_K are not provided in the circuit WCS in FIG. 8A can be employed.

Next, a specific configuration example of the current source CS is described.

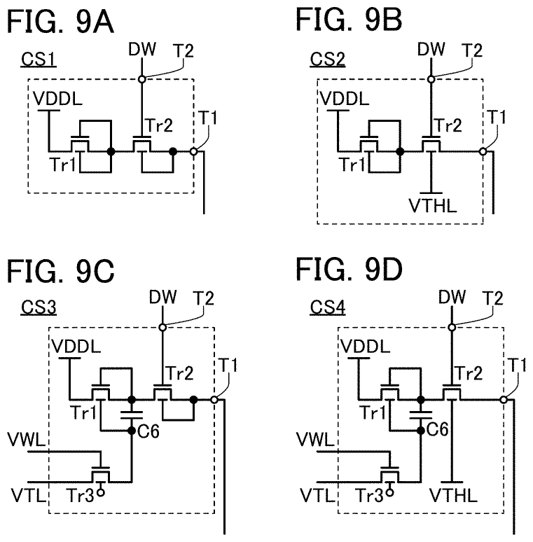

A current source CS1 illustrated in FIG. 9A is a circuit that can be used as the current source CS included in the circuit WCS in FIG. 8A, and the current source CS1 includes a transistor Tr1 and a transistor Tr2.

A first terminal of the transistor Tr1 is electrically connected to a wiring VDDL, and a second terminal of the transistor Tr1 is electrically connected to a gate of the transistor Tr1, a back gate of the transistor Tr1, and a first terminal of the transistor Tr2. A second terminal of the transistor Tr2 is electrically connected to the terminal T1, and a gate of the transistor Tr2 is electrically connected to the terminal T2. The terminal T2 is electrically connected to the wiring DW.

The wiring DW is any one of the wiring DW_1 to the wiring DW_n in FIG. 8A.

The wiring VDDL functions as a wiring for supplying a constant voltage. The constant voltage can be a high-level potential, for example.

When a constant voltage supplied from the wiring VDDL is set at a high-level potential, a high-level potential is input to the first terminal of the transistor Tr1. The potential of the second terminal of the transistor Tr1 is lower than the high-level potential. At this time, the first terminal of the transistor Tr1 functions as a drain, and the second terminal of the transistor Tr1 functions as a source. Since the gate of the transistor Tr1 is electrically connected to the second terminal of the transistor Tr1, the gate-source voltage of the transistor Tr1 is 0 V. When the threshold voltage of the transistor Tr1 is within an appropriate range, current in the current range of the subthreshold region (drain current) flows between the first terminal and the second terminal of the transistor Tr1. The amount of the current is preferably smaller than or equal to 1.0×10⁻⁸ A, further preferably smaller than or equal to 1.0×10⁻¹² A, still further preferably smaller than or equal to 1.0×10⁻¹⁵ A, for example, when the transistor Tr1 is an OS transistor. For example, the current is further preferably within a range where the current exponentially increases with respect to the gate-source voltage. That is, the transistor Tr1 functions as a current source for supplying current within a current range of the transistor Tr1 operating in the subthreshold region. The current corresponds to I_{Wut} described above or I_{Xut} described later.

The transistor Tr2 functions as a switching element. When the potential of the first terminal of the transistor Tr2 is higher than the potential of the second terminal of the transistor Tr2, the first terminal of the transistor Tr2 functions as a drain and the second terminal of the transistor Tr2 functions as a source. Since a back gate of the transistor Tr2 and the second terminal of the transistor Tr2 are electrically connected to each other, a back gate-source voltage becomes 0 V. Thus, when the threshold voltage of the transistor Tr2 is within an appropriate range and a high-level potential is input to the gate of the transistor Tr2, the transistor Tr2 is brought into an on state; when a low-level potential is input to the gate of the transistor Tr2, the transistor Tr2 is brought into an off state. Specifically, when the transistor Tr2 is in an on state, current within the current range of the subthreshold region flows from the second terminal of the transistor Tr1 to the terminal T1, and when the transistor Tr2 is in an off state, the current does not flow from the second terminal of the transistor Tr1 to the terminal T1.

The circuit that can be used as the current source CS included in the circuit WCS in FIG. 8A is not limited to the current source CS1 in FIG. 9A. For example, the current source CS1 has a configuration in which the back gate of the transistor Tr2 and the second terminal of the transistor Tr2 are electrically connected to each other; however, a configuration in which the back gate of the transistor Tr2 is electrically connected to another wiring may be employed. Such a configuration example is illustrated in FIG. 9B. In a current source CS2 illustrated in FIG. 9B, the back gate of the transistor Tr2 is electrically connected to a wiring VTHL. When the wiring VTHL of the current source CS2 is electrically connected to an external circuit or the like, the external circuit or the like supplies a predetermined potential to the wiring VTHL and the back gate of the transistor Tr2 can be supplied with the predetermined potential. This can change the threshold voltage of the transistor Tr2. In particular, the off-state current of the transistor Tr2 can be reduced by an increase in the threshold voltage of the transistor Tr2.

For example, the current source CS1 has a configuration in which the back gate of the transistor Tr1 and the second terminal of the transistor Tr1 are electrically connected to each other; however, a configuration in which the voltage between the back gate and the second terminal of the transistor Tr2 is retained with a capacitor may be employed. Such a configuration example is illustrated in FIG. 9C. A current source CS3 illustrated in FIG. 9C includes a transistor Tr3 and a capacitor C6 in addition to the transistor Tr1 and the transistor Tr2. The current source CS3 is different from the current source CS1 in that the second terminal of the transistor Tr1 and the back gate of the transistor Tr1 are electrically connected to each other through the capacitor C6, and the back gate of the transistor Tr1 and a first terminal of the transistor Tr3 are electrically connected to each other. In the current source CS3, a second terminal of the transistor Tr3 is electrically connected to a wiring VTL, and a gate of the transistor Tr3 is electrically connected to a wiring VWL. In the current source CS3, the wiring VWL is supplied with a high-level potential to bring the transistor Tr3 into an on state, so that electrical continuity can be established between the wiring VTL and the back gate of the transistor Tr1. In this case, a predetermined potential can be input to the back gate of the transistor Tr1 from the wiring VTL. The wiring VWL is supplied with a low-level potential to bring the transistor Tr3 into an off state, so that voltage between the second terminal of the transistor Tr1 and the back gate of the transistor Tr1 can be retained with the capacitor C6. The threshold voltage of the transistor Tr1 can be changed when the voltage supplied to the back gate of the transistor Tr1 is determined by the wiring VTL, and the threshold voltage of the transistor Tr1 can be fixed with the transistor Tr3 and the capacitor C6.

For example, as the circuit that can be used as the current source CS included in the circuit WCS in FIG. 8A, a current source CS4 illustrated in FIG. 9D may be used. The current source CS4 is different from the current source CS3 in FIG. 9C in that the back gate of the transistor Tr2 is electrically connected not to the second terminal of the transistor Tr2 but to the wiring VTHL. That is, the current source CS4 can change the threshold voltage of the transistor Tr2 with the potential supplied from the wiring VTHL, as in the current source CS2 in FIG. 9B.

When a high current flows between the first terminal and the second terminal of the transistor Tr1 in the current source CS4, the on-state current of the transistor Tr2 needs to be increased to supply the current from the terminal T1 to the outside of the current source CS4. In this case, in the current source CS4, the wiring VTHL is supplied with a high-level potential to decrease the threshold voltage of the transistor Tr2 and increase the on-state current of the transistor Tr2, whereby a high current flowing between the first terminal and the second terminal of the transistor Tr1 can be supplied from the terminal T1 to the outside of the current source CS4.

The use of the current source CS1 to the current source CS4 illustrated in FIG. 9A to FIG. 9D as the current sources CS included in the circuit WCS in FIG. 8A enables the circuit WCS to output current corresponding to the K-bit first data. The amount of the current can be current flowing between the first terminal and the second terminal of the transistor 34 in the range where the transistor 34 operates in the subthreshold region.

As the circuit WCS in FIG. 8A, the circuit WCS illustrated in FIG. 8B can be used. In the circuit WCS in FIG. 8B, one current source CS in FIG. 9A is connected to each of the wiring DW_1 to the wiring DW_K. When the channel width of a transistor Tr1_1 is w_1, the channel width of a transistor Tr1_2 is w_2, and the channel width of a transistor Tr1_K is w_K, the ratio of the channel widths is w_1:w_2:w_K=1:2:2K−1. Since current flowing between a source and a drain of a transistor that operates in the subthreshold region is proportional to the channel width, the circuit WCS illustrated in FIG. 8B can output current corresponding to the K-bit first data like the circuit WCS in FIG. 8A.

As the transistor Tr1 (including the transistor Tr1_1 to a transistor Tr2_K), the transistor Tr2 (including the transistor Tr2_1 to the transistor Tr2_K), and the transistor Tr3, a transistor that can be used as any of the transistors included in the cell array CA can be used, for example. In particular, as the transistor Tr1 (including the transistor Tr1_1 to the transistor Tr2_K), the transistor Tr2 (including the transistor Tr2_1 to the transistor Tr2_K), and the transistor Tr3, OS transistors are preferably used.

Next, a specific example of the circuit XCS will be described.

FIG. 8C is a block diagram illustrating an example of the circuit XCS. FIG. 8C also illustrates the wiring XCL to show the electrical connection between the circuit WCS and its peripheral circuits. The wiring XCL is any one of the wiring XCL_1 to the wiring XCL_m included in the arithmetic device MAC1 in FIG. 7.

The circuit XCS illustrated in FIG. 8C includes a switch SWX, for example. A first terminal of the switch SWX is electrically connected to the wiring XCL and a plurality of the current sources CS, and a second terminal of the switch SWX is electrically connected to a wiring VINIL2. The wiring VINIL2 functions as a wiring for supplying an initialization potential to the wiring XCL, and the initialization potential can be set to a ground potential (GND), a low-level potential, a high-level potential, or the like. The initialization potential supplied from the wiring VINIL2 can be the same as the potential supplied from the wiring VINIL1. The switch SWX is in an on state only when the initialization potential is supplied to the wiring XCL; otherwise, the switch is in an off state.

As the switch SWX, a switch that can be used as the switch SWW can be used, for example.

The circuit XCS in FIG. 8C can have almost the same circuit configuration as that of the circuit WCS in FIG. 8A. Specifically, the circuit XCS has a function of outputting reference data as current, and a function of outputting L-bit second data (2^{L} values) (L is an integer greater than or equal to 1) as current; in this case, the circuit XCS includes 2^{L}−1 current sources CS. The circuit XCS includes one current source CS that outputs information corresponding to the first bit value as current, two current sources CS that output information corresponding to the second bit value as current, and 2^{L-1} current sources CS that output information corresponding to the L-th bit value as current.

The reference data output from the circuit XCS as current can be information in which the first bit value is “1” and the second and subsequent bit values are “0”, for example.

In FIG. 8C, the terminal T2 of the one current source CS is electrically connected to a wiring DX_1, the terminals T2 of the two current sources CS are electrically connected to a wiring DX_2, and the terminals T2 of the 2^{L-1} current sources CS are electrically connected to a wiring DX_L.

The plurality of current sources CS included in the circuit XCS has a function of outputting the same constant currents I_{Xut} from the terminals T1. The wiring DX_1 to the wiring DX_L electrically connected to the current sources CS function as wirings for transmitting control signals to make the current sources CS output I_{Xut}. In other words, the circuit XCS has a function of supplying current corresponding to the L-bit data transmitted from the wiring DX_1 to the wiring DX_L to the wiring XCL.

When the transistors in the current sources CS included in the circuit XCS have different electrical characteristics and this yields errors, the errors in the constant currents I_{Xut} output from the terminals T1 of the plurality of current sources CS are preferably within 10%, further preferably within 5%, still further preferably within 1%. In this embodiment, the description is made on the assumption that there is no error in the constant currents I_{Xut} output from the terminals T1 of the plurality of current sources CS included in the circuit XCS.

As the current source CS of the circuit XCS, any of the current source CS1 to the current source CS4 in FIG. 9A to FIG. 9D can be used as the current source CS of the circuit WCS. In that case, the wiring DW illustrated in FIG. 9A to FIG. 9D is replaced with the wiring DX. This allows the circuit XCS to make current within the current range of the subthreshold region flow through the wiring XCL as the reference data or the L-bit second data.

The circuit XCS in FIG. 8C can have a circuit configuration similar to that of the circuit WCS illustrated in FIG. 8B. In this case, the circuit WCS illustrated in FIG. 8B is replaced with the circuit XCS, the wiring DW_1 is replaced with the wiring DX_1, the wiring DW_2 is replaced with the wiring DX_2, the wiring DW_K is replaced with the wiring DX_L, the switch SWW is replaced with the switch SWX, and the wiring VINIL1 is replaced with the wiring VINIL2.

### <<Converter Circuit ITRZ_1 to Converter Circuit ITRZ_n>>

Here, a specific example of a circuit that can be used as the converter circuit ITRZ_1 to the converter circuit ITRZ_n included in the arithmetic device MAC1 in FIG. 7 will be described.

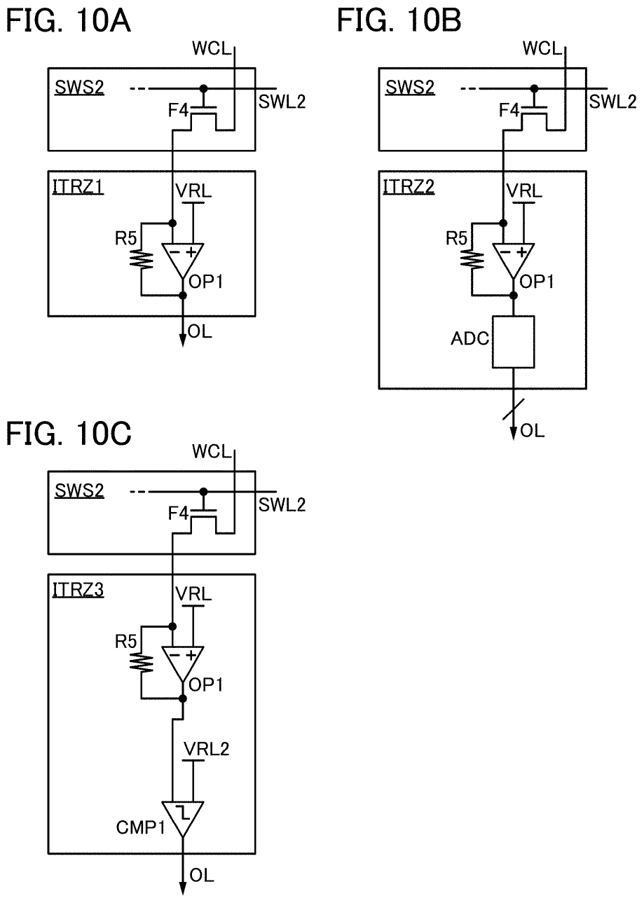

A converter circuit ITRZ1 illustrated in FIG. 10A is an example of a circuit that can be used as the converter circuit ITRZ_1 to the converter circuit ITRZ_n in FIG. 7. FIG. 10A also illustrates the circuit SWS2, the wiring WCL, the wiring SWL2, and the transistor F4 to show the electrical connection between the converter circuit ITRZ1 and its peripheral circuits. The wiring WCL is any one of the wiring WCL_1 to the wiring WCL_n included in the arithmetic device MAC1 in FIG. 7, and the transistor F4 is any one of the transistor F4_1 to the transistor F4_n included in the arithmetic device MAC1 in FIG. 7.

The converter circuit ITRZ1 in FIG. 10A is electrically connected to the wiring WCL through the transistor F4. The converter circuit ITRZ1 is electrically connected to the wiring OL. The converter circuit ITRZ1 has a function of converting current flowing from the converter circuit ITRZ1 to the wiring WCL, or current flowing from the wiring WCL to the converter circuit ITRZ1 into an analog voltage and outputting the analog voltage to the wiring OL. That is, the converter circuit ITRZ1 includes a current-voltage converter circuit.

The converter circuit ITRZ1 in FIG. 10A includes a resistor R5 and an operational amplifier OP1, for example.

An inverting input terminal of the operational amplifier OP1 is electrically connected to a first terminal of the resistor R5 and a second terminal of the transistor F4. A non-inverting input terminal of the operational amplifier OP1 is electrically connected to a wiring VRL. An output terminal of the operational amplifier OP1 is electrically connected to a second terminal of the resistor R5 and the wiring OL.

The wiring VRL functions as a wiring for supplying a constant voltage. The constant voltage can be a ground potential (GND), a low-level potential, or the like, for example.

The converter circuit ITRZ1 with the configuration in FIG. 10A can convert current flowing from the wiring WCL to the converter circuit ITRZ1 through the transistor F4 or current flowing from the converter circuit ITRZ1 to the wiring WCL through the transistor F4 into an analog voltage to output it to the wiring OL.

In particular, by setting the constant voltage applied from the wiring VRL to a ground potential (GND), the inverting input terminal of the operational amplifier OP1 is virtually grounded, and the analog voltage output to the wiring OL can be voltage with reference to the ground potential (GND).

The converter circuit ITRZ1 in FIG. 10A outputs an analog voltage; however, a circuit configuration that can be used for the converter circuit ITRZ_1 to the converter circuit ITRZ_n in FIG. 7 is not limited thereto. For example, the converter circuit ITRZ1 may include an analog-digital converter circuit ADC as illustrated in FIG. 10B. Specifically, in a converter circuit ITRZ2 in FIG. 10B, an input terminal of the analog-digital converter circuit ADC is electrically connected to an output terminal of the operational amplifier OP1 and the second terminal of the resistor R5, and an output terminal of the analog-digital converter circuit ADC is electrically connected to the wiring OL. With such a configuration, the converter circuit ITRZ2 in FIG. 10B can output a digital signal to the wiring OL.

When the digital signal output to the wiring OL is 1 bit (binary) in the converter circuit ITRZ2, the converter circuit ITRZ2 may be replaced with a converter circuit ITRZ3 illustrated in FIG. 10C. The converter circuit ITRZ3 in FIG. 10C has a configuration in which a comparator CMP1 is provided in the converter circuit ITRZ1 in FIG. 10A. Specifically, the converter circuit ITRZ3 has a configuration in which a first input terminal of the comparator CMP1 is electrically connected to the output terminal of the operational amplifier OP1 and the second terminal of the resistor R5, a second input terminal of the comparator CMP1 is electrically connected to a wiring VRL2, and an output terminal of the comparator CMP1 is electrically connected to the wiring OL. The wiring VRL2 functions as a wiring for supplying a potential to be compared with the potential of the first terminal of the comparator CMP1. With such a configuration, the converter circuit ITRZ3 in FIG. 10C can output a low-level potential or a high-level potential (a binary digital signal) to the wiring OL in accordance with the magnitude relationship between the voltage converted with the current-voltage converter circuit from current flowing between the source and the drain of the transistor F4 and the voltage supplied from the wiring VRL2.

The converter circuit ITRZ_1 to the converter circuit ITRZ_n that can be used for the arithmetic device MAC1 in FIG. 7 are not limited to the converter circuit ITRZ1 to the converter circuit ITRZ3 illustrated in FIG. 10A to FIG. 10C. When the arithmetic device MAC1 is used for arithmetic of the hierarchical neural network, for example, the converter circuit ITRZ1 to the converter circuit ITRZ3 preferably have arithmetic devices of a function system. As an arithmetic device of a function system, an arithmetic device with a sigmoid function, a tanh function, a softmax function, a ReLU function, a threshold function, or the like can be used.

### Operation Example of Arithmetic Device

Next, an operation example of the arithmetic device MAC1 will be described.

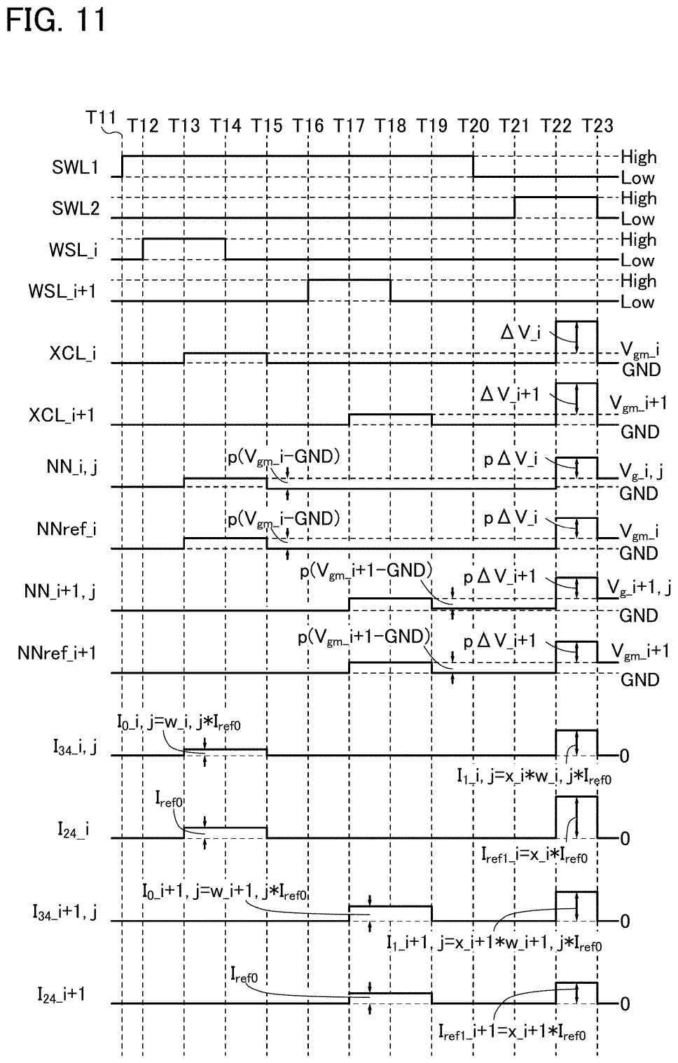

FIG. 11 is a timing chart showing an operation example of the arithmetic device MAC1. The timing chart in FIG. 11 shows changes in the potentials of the wiring SWL1, the wiring SWL2, the wiring WSL_i (i is an integer greater than or equal to 1 and less than or equal to m−1), the wiring WSL_i+1, the wiring XCL_i, the wiring XCL_i+1, the node NN_i,j (j is an integer greater than or equal to 1 and less than or equal to n−1), the node NN_i+1,j, the node NNref_i, and the node NNref_i+1 in the period from Time T11 to Time T23 and the vicinity thereof. The timing chart in FIG. 11 also shows changes in current I₃₄_i,j flowing between the first terminal and the second terminal of each of the transistors 33 and 34 included in the cell 31_i,j; current I₂₄_i flowing between the first terminal and the second terminal of each of the transistors 23 and 24 included in the cell 21_i; current I₃₄_i+1,j flowing between the first terminal and the second terminal of each of the transistors 33 and 34 included in the cell 31_i+1,j; and current I₂₄_i+1 flowing between the first terminal and the second terminal of each of the transistors 23 and 24 included in the cell 21_i+1.

The circuit WCS in FIG. 8A is used as the circuit WCS of the arithmetic device MAC1, and the circuit XCS in FIG. 8C is used as the circuit XCS of the arithmetic device MAC1.

Note that in this operation example, the source potentials of the transistor 24 and the transistor 34 are set to a ground potential GND. Before Time T11, each potential of the node NN_i,j, the node NN_i+1,j, the node NNref_i, and the node NNref_i+1 is the ground potential GND. Specifically, for example, the initialization potential of the wiring VINIL1 in FIG. 8A is set to the ground potential GND, and the switch SWW, the transistor F3, and the transistor 32 included in each of the cell 31_i,j and the cell 31_i+1,j are brought into an on state, whereby the potentials of the node NN_i,j and the node NN_i+1,j can be set to the ground potential GND. For example, the initialization potential of the wiring VINIL2 in FIG. 8C is set to the ground potential GND, and the switch SWX and the transistor 22 included in each of the cell 31_i,j and the cell 31_i+1,j are brought into an on state, whereby the potentials of the node NNref_i,j and the node NNref_i+1,j can be set to the ground potential GND.

Note that in this operation example, the gate potentials of the transistor 23 and the transistor 33 are each the constant potential Vb. When the gate potentials of the transistor 23 and the transistor 33 are each the constant potential Vb, the first terminals of the transistor 23 and the transistor 33 can each have a voltage Vb-Vth, which is lower than the constant potential Vb by the threshold voltage. Accordingly, an increase at the second terminals (on the drain side) of the transistors 24 and 34 can be inhibited.

### <<From Time T11 to Time T12>>

In the period from Time T11 to Time T12, a high-level potential (shown as High in FIG. 11) is applied to the wiring SWL1, and a low-level potential (shown as Low in FIG. 11) is applied to the wiring SWL2. Accordingly, the high-level potential is applied to each of the gates of the transistor F3_1 to the transistor F3_n so that each of the transistor F3_1 to the transistor F3_n is brought into an on state, and the low-level potential is applied to each of the gates of the transistor F4_1 to the transistor F4_n so that each of the transistor F4_1 to the transistor F4_n is brought into an off state.

In the period from Time T11 to Time T12, a low-level potential is applied to the wiring WSL_i and the wiring WSL_i+1. Accordingly, in the i-th row of the cell array CA, a low-level potential is applied to the gates of the transistors 32 included in the cell 31_i,1 to the cell 31_i,n and the gate of the transistor 22 included in the cell 21_i so that each of the transistors 32 and the transistor 22 is brought into an off state. In addition, in the i+1-th row of the cell array CA, a low-level potential is applied to the gates of the transistors 32 included in the cell 31_i+1,1 to the cell 31_i+1,n and the gate of the transistor 22 included in the cell 21_i+1 so that each of the transistors 32 and the transistor 22 is brought into an off state.

In the period from Time T11 to Time T12, the ground potential GND is applied to the wiring XCL_i and the wiring XCL_i+1. Specifically, for example, when the wiring XCL illustrated in FIG. 8C is the wiring XCL_i and the wiring XCL_i+1, the initialization potential of the wiring VINIL2 is set to the ground potential GND, and the switch SWX is brought into an on state, the potentials of the wiring XCL_i and the wiring XCL_i+1 can be set to the ground potential GND.

In the period from Time T11 to Time T12, when the wiring WCL illustrated in FIG. 8A is each of the wiring WCL_1 to the wiring WCL_K, the first data is not input to the wiring DW_1 to the wiring DW_K. When the wiring XCL in FIG. 8C is each of the wiring XCL_1 to the wiring XCL K, the second data is not input to the wiring DX_1 to the wiring DX_L. Here, it is assumed that a low-level potential is input to each of the wiring DW_1 to the wiring DW_K in the circuit WCS in FIG. 8A and a low-level potential is input to each of the wiring DX_1 to the wiring DX_L in the circuit XCS in FIG. 8C.

In the period from Time T11 to Time T12, current does not flow through a wiring WCL_j, the wiring XCL_i, and the wiring XCL_i+1. Therefore, I₃₄_i,j, I₂₄_i, I₃₄_i+1,j, and I₂₄_i+1 are each 0.

### <<From Time T12 to Time T13>>

In the period from Time T12 to Time T13, a high-level potential is applied to the wiring WSL_i. Accordingly, in the i-th row of the cell array CA, a high-level potential is applied to the gates of the transistors 32 included in the cell 31_i,1 to the cell 31_i,n and the gate of the transistor 22 included in the cell 21_i so that each of the transistors 32 and the transistor 22 is brought into an on state. Furthermore, in the period from Time T12 to Time T13, a low-level potential is applied to the wiring WSL_1 to the wiring WSL_m other than the wiring WSL_i, and in the cell array CA, the transistors 32 included in the cell 31_1,1 to the cell 31_m,n in the rows other than the i-th row and the transistors 22 included in the cell 21_1 to the cell 21_m in the rows other than the i-th row are in an off state.

The ground potentials GND have been continuously applied to the wiring XCL_1 to the wiring XCL_m since before Time T12.

### <<From Time T13 to Time T14>>

In the period from Time T13 to Time T14, current I₀_i,j flows as the first data from the circuit WCS to the cell array CA through the transistor F3_j. Specifically, when the wiring WCL illustrated in FIG. 8A is the wiring WCL_j, signals corresponding to the first data are input to the wiring DW_1 to the wiring DW_K, whereby the current I₀_i,j flows from the circuit WCS to the second terminal of the transistor F3_j. That is, when the value of the K-bit signal input as the first data is α_i,j (α_i,j is an integer greater than or equal to 0 and less than or equal to 2^{K}−1), I₀_i,j=α_i,j×I_{Wut} is satisfied (“x” is shown as “*” in the drawing).

Since I₀_i,j=0 is satisfied when α_i,j is 0, current does not flow from the circuit WCS to the cell array CA through the transistor F3_j in a strict sense, but in this specification and the like, the expression such as “current with I₀_i,j=0 flows” is sometimes used.

In the period from Time T13 to Time T14, electrical continuity is established between the wiring WCL_j and the first terminal of the transistor 32 included in the cell 31_i,j in the i-th row of the cell array CA, and electrical continuity is not established between the wiring WCL_j and the first terminals of the transistors 32 included in the cell 31_1,j to the cell 31_m,j in the rows other than the i-th row of the cell array CA; accordingly, the current amount I₀_i,j flows from the wiring WCL_j to the cell 31_i,j.

By the way, the transistor 32 included in the cell 31_i,j is brought into an on state. In the transistor 34, the gate-source voltage becomes V_{g}_i,j-GND, and the current I₀_i,j is set as current flowing between the first terminal and the second terminal of the transistor 34.

In the period from Time T13 to Time T14, current I_{ref0} flows as the reference data from the circuit XCS to the wiring XCL_i. Specifically, when the wiring XCL illustrated in FIG. 8C is the wiring XCL_i, a high-level potential is input to the wiring DX_1, a low-level potential is input to the wiring DX_2 to the wiring DX_K, and the current I_{ref0} flows from the circuit XCS to the wiring XCL_i. In other words, I_{ref0}=I_{Xut} is satisfied.

In the period from Time T13 to Time T14, since electrical continuity is established between the first terminal of the transistor 22 included in the cell 21_i and the wiring XCL_i, the current I_{ref0} flows from the wiring XCL_i to the cell 21_i.

As in the cell 31_i,j, the transistor 22 included in the cell 21_i is brought into an on state. In the transistor 24, the gate-source voltage becomes V_{gm}_i−GND, and the current I_{ref0} is set as current flowing between the first terminal and the second terminal of the transistor 24.

<<From Time T14 to Time T15>>

In the period from Time T14 to Time T15, a low-level potential is applied to the wiring WSL_i. Accordingly, in the i-th row of the cell array CA, a low-level potential is applied to the gates of the transistors 32 included in the cell 31_i,1 to the cell 31_i,n and the gate of the transistor 22 included in the cell 21_i so that each of the transistors 32 and the transistor 22 is brought into an off state.

When the transistor 32 included in the cell 31_i,j is brought into an off state, V_{g}_i,j−V_{gm}_i, which is a difference between the potential of the gate of the transistor 34 (the node NN_i,j) and the potential of the wiring XCL_i, is retained in the capacitor 35. When the transistor 32 included in the cell 21_i is brought into an off state, 0, which is a difference between the potential of the gate of the transistor 24 (the node NNref_i) and the potential of the wiring XCL_i, is retained in the capacitor 25.

### <<From Time T15 to Time T16>>

In the period from Time T15 to Time T16, GND is applied to the wiring XCL_i. Specifically, for example, when the wiring XCL illustrated in FIG. 8C is the wiring XCL_i, the initialization potential of the wiring VINIL2 is set to the ground potential GND, and the switch SWX is brought into an on state, the potential of the wiring XCL_i can be set to the ground potential GND.

Thus, the potentials of the node NN_i,1 to the node NN_i,n change because of capacitive coupling of the capacitors 35 included in the cell 31_i,1 to the cell 31_i,n in the i-th row, and the potential of the node NNref_i changes because of capacitive coupling of the capacitor 25 included in the cell 21_i.

The amount of change in the potentials of the node NN_i,1 to the node NN_i,n is a potential obtained by multiplying the amount of change in the potential of the wiring XCL_i by a capacitive coupling coefficient determined by the structures of the cell 31_i,1 to the cell 31_i,n included in the cell array CA. The capacitive coupling coefficient is calculated using the capacitance of the capacitor 35, the gate capacitance of the transistor 34, the parasitic capacitance, and the like. When the capacitive coupling coefficient due to the capacitor 35 is p in each of the cell 31_i,1 to the cell 31_i,n, the potential of the node NN_i,j in the cell 31_i,j decreases by p(V_{gm}_i−GND) from the potential of the period from Time T14 to Time T15.

Similarly, when the potential of the wiring XCL_i changes, the potential of the node NNref_i also changes because of capacitive coupling of the capacitor 25 included in the cell 21_i. In the case where the capacitive coupling coefficient due to the capacitor 25 is p as with the capacitor 35, the potential of the node NNref_i in the cell 21_i decreases by p(V_{gm}_i−GND) from the potential of the period from Time T14 to Time T15. In the timing chart in FIG. 11, p=1, for example. Thus, the potential of the node NNref_i is GND in the period from Time T15 to Time T16.

Accordingly, the potential of the node NN_i,j of the cell 31_i,j decreases, so that the transistor 34 is brought into an off state; similarly, the potential of the node NNref_i of the cell 21_i decreases, so that the transistor 24 is also brought into an off state. Therefore, I₃₄_i,j and I₂₄_i are each 0 in the period from Time T15 to Time T16.

### <<From Time T16 to Time T17>>

In the period from Time T16 to Time T17, a high-level potential is applied to the wiring WSL_i+1. Accordingly, in the i+1-th row of the cell array CA, a high-level potential is applied to the gates of the transistors 32 included in the cell 31_i+1,1 to the cell 31_i+1,n and the gate of the transistor 22 included in the cell 21_i+1 so that each of the transistors 32 and the transistor 22 is brought into an on state. Furthermore, in the period from Time T16 to Time T17, a low-level potential is applied to the wiring WSL_1 to the wiring WSL_m other than the wiring WSL_i+1, and in the cell array CA, the transistors 32 included in the cell 31_1,1 to the cell 31_m,n in the rows other than the i+1-th row and the transistors 22 included in the cell 21_1 to the cell 21_m in the rows other than the i+1-th row are in an off state.

The ground potential GND has been continuously applied to the wiring XCL_1 to the wiring XCL_m since before Time T16.

### <<From Time T17 to Time T18>>

In the period from Time T17 to Time T18, current I₀_i+1,j flows as the first data from the circuit WCS to the cell array CA through the transistor F3_j. Specifically, when the wiring WCL illustrated in FIG. 8A is the wiring WCL_j+1, signals corresponding to the first data are input to the wiring DW_1 to the wiring DW_K, whereby the current I₀_i+1,j flows from the wiring WCS to the second terminal of the transistor F3_j. That is, when the value of the K-bit signal input as the first data is α_i+1,j (α_i+1,j is an integer greater than or equal to 0 and less than or equal to 2^{K}−1), I₀_i+1,j=α_i+1,j×I_{Wut} is satisfied (“x” is shown as “*” in the drawing).

Since I₀_i+1,j=0 is satisfied when α_i+1,j is 0, current does not flow from the circuit WCS to the cell array CA through the transistor F3_j in a strict sense, but in this specification and the like, the expression such as “current with I₀_i+1,j=0 flows” is sometimes used, as in the case of I₀_i,j=0.

At this time, electrical continuity is established between the wiring WCL_j and the first terminal of the transistor 32 included in the cell 31_i+1,j in the i+1-th row of the cell array CA, and electrical continuity is not established between the wiring WCL_j and the first terminals of the transistors 32 included in the cell 31_1,j to the cell 31_m,j in the rows other than the i+1-th row of the cell array CA; accordingly, the current I₀_i+1,j flows from the wiring WCL_j to the cell 31_i+1,j.

By the way, the transistor 32 included in the cell 31_i+1,j is brought into an on state. In the transistor 34, the gate-source voltage becomes V_{g}_i+1,j−GND, and the current I₀_i+1,j is set as current flowing between the first terminal and the second terminal of the transistor 34.

In the period from Time T17 to Time T18, the current I_{ref0} flows as the reference data from the circuit XCS to the wiring XCL_i+1. Specifically, as in the period from Time T13 to Time T14, when the wiring XCL illustrated in FIG. 8C is the wiring XCL_i+1, a high-level potential is input to the wiring DX_1, a low-level potential is input to the wiring DX_2 to the wiring DX_K, and the current I_{ref0}=I_{Xut} flows from the circuit XCS to the wiring XCL_i+1.

In the period from Time T17 to Time T18, since electrical continuity is established between the first terminal of the transistor 22 included in the cell 21_i+1 and the wiring XCL_i+1, the current I_{ref0} flows from the wiring XCL_i+1 to the cell 21_i+1.

As in the cell 31_i+1,j the transistor 22 included in the cell 21_i+1 is brought into an on state. In the transistor 24, the gate-source voltage becomes V_{gm}_i+1−GND, and the current I_{ref0} is set as current flowing between the first terminal and the second terminal of the transistor 24.

### <<From Time T18 to Time T19>>

In the period from Time T18 to Time T19, a low-level potential is applied to the wiring WSL_i+1. Accordingly, in the i+1-th row of the cell array CA, a low-level potential is applied to the gates of the transistors 32 included in the cell 31_i+1,1 to the cell 31_i+1,n and the gate of the transistor 22 included in the cell 21_i+1 so that each of the transistors 32 and the transistor 22 is brought into an off state.

When the transistor 32 included in the cell 31_i+1,j is brought into an off state, V_{g}_i+1,j−V_{gm}_i+1, which is a difference between the potential of the gate of the transistor 34 (the node NN_i+1,j) and the potential of the wiring XCL_i+1, is retained in the capacitor 35. When the transistor 32 included in the cell 21_i+1 is brought into an off state, 0, which is a difference between the potential of the gate of the transistor 24 (the node NNref_i+1) and the potential of the wiring XCL_i+1, is retained in the capacitor 25. In the operation from Time T18 to Time T19, the voltage retained in the capacitor 25 might be voltage that is not 0 (for example, Vas here) depending on the transistor characteristics and the like of the transistor 22 and the transistor 24. In this case, the potential of the node NNref_i+1 is regarded as a potential obtained by adding Vas to the potential of the wiring XCL_i+1.

### <<From Time T19 to Time T20>>

In the period from Time T19 to Time T20, the ground potential GND is applied to the wiring XCL_i+1. Specifically, for example, when the wiring XCL illustrated in FIG. 8C is the wiring XCL_i+1, the potential of the wiring XCL_i+1 can be set to the ground potential GND by setting the initialization potential of the wiring VINIL2 to the ground potential GND and bringing the switch SWX into an on state.

Thus, the potentials of the node NN_i,1 to the node NN_i+1,n change because of capacitive coupling of the capacitors 35 included in the cell 31_i+1,1 to the cell 31_i+1,n in the i+1-th row, and the potential of the node NNref_i+1 changes because of capacitive coupling of the capacitor 25 included in the cell 21_i+1.

The amount of change in the potentials of the node NN_i+1,1 to the node NN_i+1,n is a potential obtained by multiplying the amount of change in the potential of the wiring XCL_i+1 by a capacitive coupling coefficient determined by the structures of the cell 31_i+1,1 to the cell 31_i+1,n included in the cell array CA. The capacitive coupling coefficient is calculated using the capacitance of the capacitor 35, the gate capacitance of the transistor 34, the parasitic capacitance, and the like. In the case where the capacitive coupling coefficient due to the capacitor 35 in each of the cell 31_i+1,1 to the cell 31_i+1,n is p, which is the same as the capacitive coupling coefficient due to the capacitor 35 in each of the cell 31_i,1 to the cell 31_i,n, the potential of the node NN_i+1,j in the cell 31_i+1,j decreases by p(V_{gm}_i+1−GND) from the potential of the period from Time T18 to Time T19.

Similarly, when the potential of the wiring XCL_i+1 changes, the potential of the node NNref_i+1 also changes because of capacitive coupling of the capacitor 25 included in the cell 21_i+1. In the case where the capacitive coupling coefficient due to the capacitor 25 is p as with the capacitor 35, the potential of the node NNref_i+1 in the cell 21_i+1 decreases by p(V_{gm}_i+1−GND) from the potential of the period from Time T18 to Time T19. In the timing chart in FIG. 11, p=1, for example. Thus, the potential of the node NNref_i+1 is GND in the period from Time T20 to Time T21.

Accordingly, the potential of the node NN_i+1,j of the cell 31_i+1,j decreases, so that the transistor 34 is brought into an off state; similarly, the potential of the node NNref_i+1 of the cell 21_i+1 decreases, so that the transistor 24 is also brought into an off state. Therefore, I₃₄_i+1,j and I₂₄_i+1 are each 0 in the period from Time T19 to Time T20.

### <<From Time T20 to Time T21>>

In the period from Time T20 to Time T21, a low-level potential is applied to the wiring SWL1. Accordingly, a low-level potential is applied to each of the gates of the transistor F3_1 to the transistor F3_n, whereby each of the transistor F3_1 to the transistor F3_n is brought into an off state.

### <<From Time T21 to Time T22>>

In the period from Time T21 to Time T22, a high-level potential is applied to the wiring SWL2. Accordingly, a high-level potential is applied to each of the gates of the transistor F4_1 to the transistor F4_n, whereby each of the transistor F4_1 to the transistor F4_n is brought into an on state.

### <<From Time T22 to Time T23>>

In the period from Time T22 to Time T23, current x_iI_{ref0}, which is x_i times as high as the current I_{ref0}, flows as the second data from the circuit XCS to the wiring XCL_i. Specifically, for example, when the wiring XCL illustrated in FIG. 8C is the wiring XCL_i, a high-level potential or a low-level potential is input to the wiring DX_1 to the wiring DX_K in accordance with the value of x_i, and the current x_iI_{ref0}=x_iI_{Xut} flows from the circuit XCS to the wiring XCL_i. In this operation example, x_i corresponds to the value of the second data. At this time, the potential of the wiring XCL_i changes from 0 to V_{gm}_i+ΔV_i.

When the potential of the wiring XCL_i changes, the potentials of the node NN_i,1 to the node NN_i,n also change because of the capacitive coupling of the capacitors 35 included in the cell 31_i,1 to the cell 31_i,n in the i-th row of the cell array CA. Thus, the potential of the node NN_i,j in the cell 31_i,j becomes V_{g}_i,j+pΔV_i.

Similarly, when the potential of the wiring XCL_i changes, the potential of the node NNref_i also changes because of capacitive coupling of the capacitor 25 included in the cell 21_i. Thus, the potential of the node NNref_i in the cell 21_i becomes V_{gm}_i+pΔV_i.

Thus, current flowing between the first terminal and the second terminal of the transistor 34 included in the cell 31_i,j is proportional to the product of first data w_i,j and second data x_i, as described in Embodiment 1.

In the period from Time T22 to Time T23, current x_i+1I_{ref0}, which is x_i+1 times as high as the current I_{ref0}, flows as the second data from the circuit XCS to the wiring XCL_i+1. Specifically, for example, when the wiring XCL illustrated in FIG. 8C is the wiring XCL_i+1, a high-level potential or a low-level potential is input to the wiring DX_1 to the wiring DX_K in accordance with the value of x_i+1, and the current x_i+1I_{ref0}=x_i+1I_{Xut} flows from the circuit XCS to the wiring XCL_i+1. In this operation example, x_i+1 corresponds to the value of the second data. At this time, the potential of the wiring XCL_i+1 changes from 0 to V_{gm}_i+1+ΔV_i+1.

When the potential of the wiring XCL_i+1 changes, the potentials of the node NN_i+1,1 to the node NN_i+1,n also change because of the capacitive coupling of the capacitors 35 included in the cell 31_i+1,1 to the cell 31_i+1,n in the i+1-th row of the cell array CA. Thus, the potential of the node NN_i+1,j in the cell 31_i+1,j becomes V_{g}_i+1,j+pΔV_i+1.

Similarly, when the potential of the wiring XCL_i+1 changes, the potential of the node NNref_i+1 also changes because of capacitive coupling of the capacitor 25 included in the cell 21_i+1. Thus, the potential of the node NNref_i+1 in the cell 21_i+1 becomes V_{gm}_i+1+pΔV_i−1.

Thus, current flowing between the first terminal and the second terminal of the transistor 34 included in the cell 31_i+1,j is proportional to the product of first data w_i+1,j and second data x_i+1, as described in Embodiment 1.

Thus, current output from the converter circuit ITRZ_j is current proportional to the sum of products of the weight coefficients w_i,j and w_i+1,j that are the first data and the values x_i and x_i+1 of the signals of the neurons that are the second data.

Thus, even in the case of the arithmetic device MAC1 including the cell array CA with three or more rows and two or more columns, product-sum operation can be performed in the above-described manner. In the arithmetic device MAC1 of such a case, cells in one of the plurality of columns are used for retaining I_{ref0} and xI_{ref0} as current, whereby product-sum operations, the number of which corresponds to the number of rest of the columns among the plurality of columns, can be executed concurrently. That is, when the number of columns in a memory cell array increases, a semiconductor device that achieves high-speed product-sum operation can be provided. Accordingly, an arithmetic device with high arithmetic processing performance per unit electric power can be provided.

Although this embodiment describes the case where the transistors included in the arithmetic device MAC1 are OS transistors or Si transistors, one embodiment of the present invention is not limited thereto. The transistor included in the arithmetic device MAC1 can be, for example, a transistor including Ge or the like in a channel formation region, a transistor including a compound semiconductor such as ZnSe, CdS, GaAs, InP, GaN, or SiGe in a channel formation region, a transistor including a carbon nanotube in a channel formation region, or a transistor including an organic semiconductor in a channel formation region.

Note that this embodiment can be combined with any of the other embodiments described in this specification as appropriate.

### Embodiment 3

A hierarchical artificial neural network (hereinafter, referred to as a neural network) will be described in this embodiment. Note that arithmetic of a hierarchical neural network can be performed using the semiconductor device and the arithmetic device described in the above embodiments.

In a neural network, the connection strength between synapses can be changed by providing the neural network with existing information. The processing for determining a connection strength by providing a neural network with existing information in such a manner is called “learning” in some cases.

Furthermore, when a neural network in which “learning” has been performed (the connection strength has been determined) is provided with some type of information, new information can be output on the basis of the connection strength. The processing for outputting new information on the basis of provided information and the connection strength in a neural network in such a manner is called “inference” or “recognition” in some cases. A signal input from a neuron in one layer to a neuron in the subsequent layer corresponds to the connection strength (hereinafter, referred to as a weight coefficient) of the synapse that connects the neurons to each other, and the weight coefficient corresponds to the weight data described in the above embodiment.

Examples of the model of a neural network include a Hopfield type and a hierarchical type. In particular, a neural network with a multilayer structure is called a “deep neural network” (DNN), and machine learning using a deep neural network is called “deep learning” in some cases.

### <Hierarchical Neural Network>

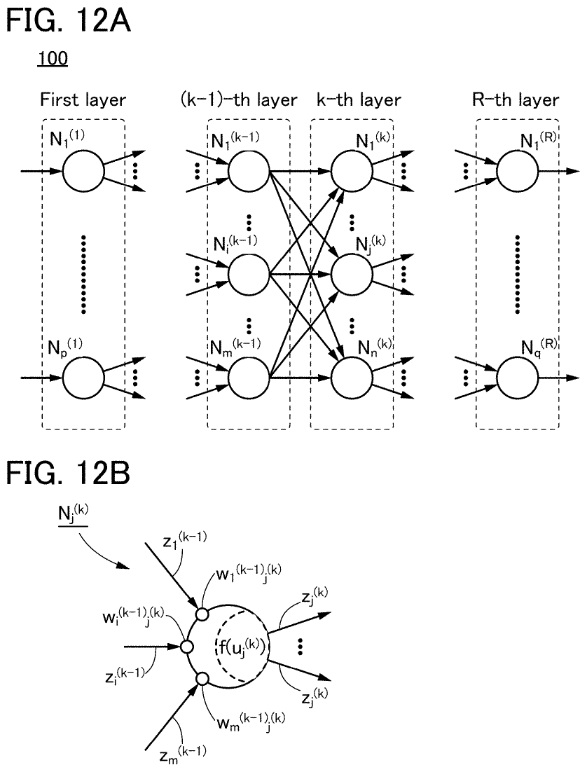

A hierarchical neural network includes one input layer, one or a plurality of intermediate layers (hidden layers), and one output layer, for example, and is configured with a total of at least three layers. A hierarchical neural network 100 illustrated in FIG. 12A is one example, and the neural network 100 includes a first layer to an R-th layer (here, R can be an integer greater than or equal to 4). Specifically, the first layer corresponds to the input layer, the R-th layer corresponds to the output layer, and the other layers correspond to the intermediate layers. Note that FIG. 12A illustrates the (k−1)-th layer and the k-th layer (here, k is an integer greater than or equal to 3 and less than or equal to R−1) as the intermediate layers, and does not illustrate the other intermediate layers.

Each of the layers of the neural network 100 includes one or a plurality of neurons. In FIG. 12A, the first layer includes a neuron N₁⁽¹⁾ to a neuron Nₚ⁽¹⁾ (here, p is an integer greater than or equal to 1); the (k−1)-th layer includes a neuron N₁^{(k-1)} to a neuron Nₘ^{(k-1)} (here, m is an integer greater than or equal to 1); the k-th layer includes a neuron N₁^{(k)} to a neuron Nₙ^{(k)} (here, n is an integer greater than or equal to 1); and the R-th layer includes a neuron N₁^{(R)} to a neuron N_{q}^{(R)} (here, q is an integer greater than or equal to 1).

FIG. 12A illustrates a neuron Nᵢ^{(k-1)} (here, i is an integer greater than or equal to 1 and less than or equal to m) in the (k−1)-th layer and a neuron Nⱼ^{(k)} (here, j is an integer greater than or equal to 1 and less than or equal to n) in the k-th layer, in addition to the neuron N₁⁽¹⁾, the neuron Nₚ⁽¹⁾, the neuron N₁^{(k-1)}, the neuron Nₘ^{(k-1)}, the neuron N₁^{(k)}, the neuron Nₙ^{(k)}, the neuron N₁^{(R)}, and the neuron N_{q}^{(R)}; the other neurons are not illustrated.

Next, signal transmission from a neuron in one layer to a neuron in the subsequent layer and signals input to and output from the neurons are described. Note that description here is made focusing on the neuron Nⱼ^{(k)} in the k-th layer.

FIG. 12B illustrates the neuron Nⱼ^{(k)} in the k-th layer, signals input to the neuron Nⱼ^{(k)}, and a signal output from the neuron Nⱼ^{(k)}.

Specifically, z₁^{(k-1)} to zₘ^{(k-1)} that are output signals from the neuron N₁^{(k-1)} to the neuron Nₘ^{(k-1)} in the (k−1)-th layer are output to the neuron Nⱼ^{(k)}. Then, the neuron Nⱼ^{(k)} generates zⱼ^{(k)} in accordance with z₁^{(k-1)} to zₘ^{(k-1)}, and outputs zⱼ^{(k)} as the output signal to the neurons in the (k+1)-th layer (not illustrated).

The efficiency of transmitting a signal input from a neuron in one layer to a neuron in the subsequent layer depends on the connection strength (hereinafter, referred to as a weight coefficient) of the synapse that connects the neurons to each other. In the neural network 100, a signal output from a neuron in one layer is multiplied by the corresponding weight coefficient and then is input to a neuron in the subsequent layer. When i is an integer greater than or equal to 1 and less than or equal to m and the weight coefficient of the synapse between the neuron Nᵢ^{(k-1)} in the (k−1)-th layer and the neuron Nⱼ^{(k)} in the k-th layer is wᵢ^{(k-1)}ⱼ^{(k)}, a signal input to the neuron Nⱼ^{(k)} in the k-th layer can be expressed by Formula (7).

[Formula 7]

wᵢ^{(k-1)}ⱼ^{(k)}·zᵢ^{(k-1)} (7)

That is, when the signals are transmitted from the neuron N₁^{(k-1)} to the neuron Nₘ^{(k-1)} in the (k−1)-th layer to the neuron Nⱼ^{(k)} in the k-th layer, the signals z₁^{(k-1)} to zₘ^{(k-1)} are multiplied by the respective weight coefficients (w₁^{(k-1)}ⱼ^{(k)} to wₘ^{(k-1)}ⱼ^{(k)}). Then, w₁^{(k-1)}ⱼ^{(k)}·z₁^{(k-1)} to wₘ^{(k-1)}ⱼ^{(k)}·zₘ^{(k-1)} are input to the neuron Nⱼ^{(k)} in the k-th layer. At this time, the total sum uⱼ^{(k)} of the signals input to the neuron Nⱼ^{(k)} in the k-th layer is expressed by Formula (8).

$$\begin{matrix}[ Formula 8 ] & \\ {u}_{j}^{( k )} = {{\sum }_{i = 1}}^{m} {{w}_{i}^{( k - 1 )}}_{j}^{( k )} \cdot {z}_{i}^{( k - 1 )} & ( 8 )\end{matrix}$$

In addition, a bias may be added to the product-sum result of the weight coefficients w₁^{(k-1)}ⱼ^{(k)} to wₘ^{(k-1)}ⱼ^{(k)} and the signals z₁^{(k-1)} to zₘ^{(k-1)} of the neurons. When the bias is denoted by b, Formula (8) can be rewritten to the following Formula (9).

$$\begin{matrix}[ Formula 9 ] & \\ {u}_{j}^{( k )} = {{\sum }_{i = 1}}^{m} {{w}_{i}^{( k - 1 )}}_{j}^{( k )} \cdot {z}_{i}^{( k - 1 )} + b & ( 9 )\end{matrix}$$

The neuron Nⱼ^{(k)} generates the output signal zⱼ^{(k)} in accordance with uⱼ^{(k)}. Here, the output signal zⱼ^{(k)} from the neuron Nⱼ^{(k)} is defined by the following Formula (10).

[Formula 10]

Zⱼ^{(k)}=ƒ(uⱼ^{(k)}) (10)

A function ƒ(uⱼ^{(k)}) is an activation function in a hierarchical neural network, and a step function, a linear ramp function, a sigmoid function, or the like can be used. Note that the activation function may be the same or different among all neurons. In addition, the neuron activation function may be the same or different between the layers.

Signals output from the neurons in the layers, the weight coefficients w, or the bias b may be an analog value or a digital value. For example, a binary or ternary digital value may be used. A value having a larger number of bits may be used. In the case of an analog value, for example, a linear ramp function or a sigmoid function is used as the activation function. In the case of a binary digital value, for example, a step function with an output of −1 or 1 or an output of 0 or 1 is used. Alternatively, the neurons in the layers may each output a ternary or higher-level signal; in this case, a step function with an output of three or more values, for example, an output of −1, 0, or 1 or an output of 0, 1, or 2 is used as an activation function. Furthermore, as an activation function for outputting five values, a step function with an output of −2, −1, 0, 1, or 2 may be used, for example. Using a digital value as at least one of the signals output from the neurons in the layers, the weight coefficients w, and the bias b enables a reduction in the circuit scale, a reduction in power consumption, or an increase in operation speed, for example. Furthermore, the use of an analog value as at least one of the signals output from the neurons in the layers, the weight coefficients w, and the bias b can improve the arithmetic accuracy.

The neural network 100 performs operation in which by input of an input signal to the first layer (the input layer), output signals are sequentially generated in the layers from the first layer (the input layer) to the last layer (the output layer) according to Formula (7), Formula (8) (or Formula (9)), and Formula (10) on the basis of the signals input from the previous layers, and the output signals are output to the subsequent layers. The signal output from the last layer (the output layer) corresponds to the calculation results of the neural network 100.

In the case where the arithmetic device MAC1 described in Embodiment 2 is used as the above-described hidden layer, the weight coefficient w_{s[k-1]}^{(k-1)}_{s_K}^{(k)}(s[k−1] is an integer greater than or equal to 1 and less than or equal to m, and s_K is an integer greater than or equal to 1 and less than or equal to n) is used as the first data, current corresponding to the first data is stored in the cells IM in the same column sequentially, the output signal z_{s[k-1]}^{(k-1)} from the neuron N_{s[k-1]}^{(k-1)} in the (k−1)-th layer is used as the second data, and current corresponding to the second data is fed from the circuit XCS to the wiring XCL in each row, so that the product-sum of the first data and the second data can be obtained from current Is input to the converter circuit ITRZ. In addition, the value of the activation function is obtained using the value of the sum of products, so that the value of the activation function can be the output signal z_{s_K}^{(k)} of the neuron N_{s_K}^{(k)} in the k-th layer.

In the case where the arithmetic device MAC1 described in Embodiment 2 is used as the above-described output layer, the weight coefficient w_{s[R-1]}^{(R-1)}_{s[R]}^{(R)} (s[R−1] is an integer greater than or equal to 1, and s[R] is an integer greater than or equal to 1 and less than or equal to q) is used as the first data, the current corresponding to the first data is stored in the cells IM in the same column sequentially, the output signal z_{s[R-1]}^{(R-1)} from the neuron N_{s[R-1}]^{(R-1)} in the (R−1)-th layer is used as the second data, and the current corresponding to the second data is fed from the circuit XCS to the wiring XCL in each row, so that the sum of products of the first data and the second data can be obtained from the current Is input to the converter circuit ITRZ. In addition, the value of the activation function is obtained using the value of the sum of products, so that the value of the activation function can be the output signal z_{s[R]}^{(R)} of the neuron N_{s[R]}^{(R)} in the R-th layer.

Note that the input layer described in this embodiment may function as a buffer circuit that outputs an input signal to the second layer.

Note that this embodiment can be combined with any of the other embodiments described in this specification as appropriate.

### Embodiment 4

In this embodiment, a structure example of transistors that can be used in the semiconductor device 10 and the arithmetic device MAC1 described in the above embodiment will be described. As an example, a structure in which transistors having different electrical characteristics are stacked is described. With the structure, the flexibility in design of the semiconductor device can be increased. Stacking transistors having different electrical characteristics can increase the degree of integration of the semiconductor device.

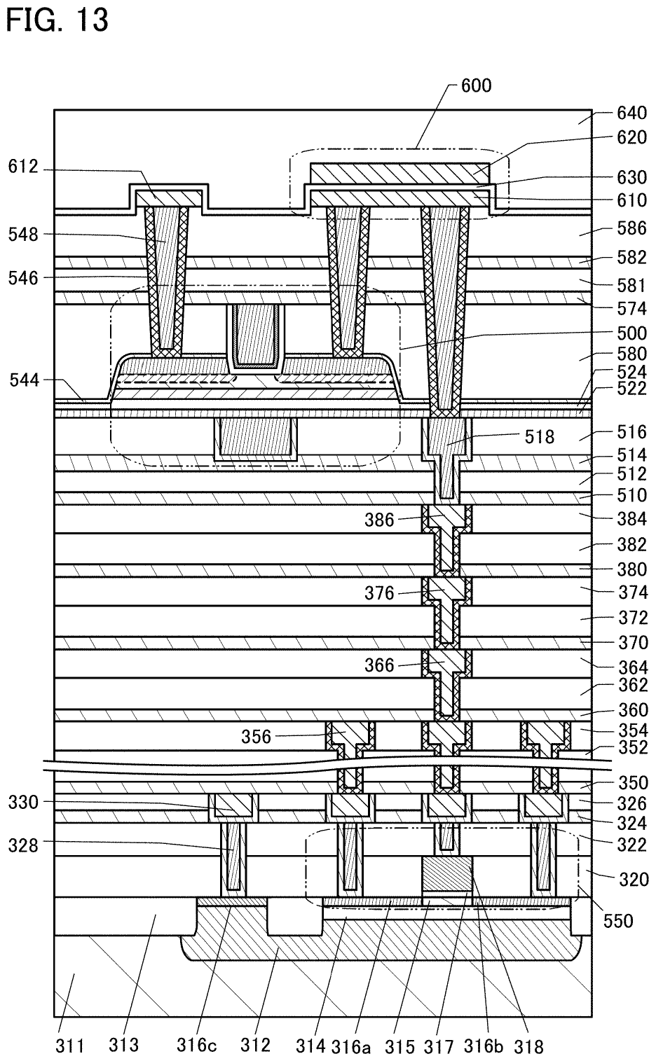

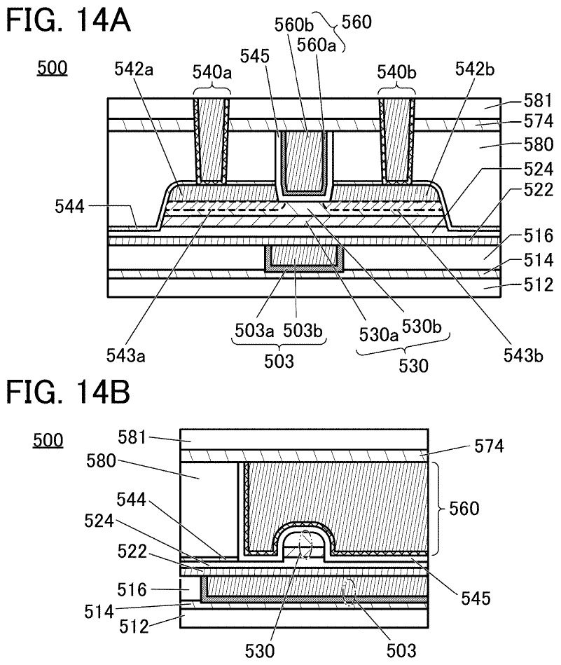

FIG. 13 illustrates part of a cross-sectional structure of a semiconductor device. The semiconductor device illustrated in FIG. 13 includes a transistor 550, a transistor 500, and a capacitor 600. FIG. 14A is a cross-sectional view of the transistor 500 in a channel length direction, and FIG. 14B is a cross-sectional view of the transistor 500 in a channel width direction. For example, the transistor 500 corresponds to each of the OS transistors, i.e., transistors containing oxide semiconductors in their channel formation regions, included in the reference cell 21 and the arithmetic cell 31 described in the above embodiment. The transistor 550 corresponds to each of the Si transistors, i.e., transistors containing silicon in their channel formation regions, included in the reference cell 21 and the arithmetic cell 31 described in the above embodiment. The capacitor 600 corresponds to each of the capacitors included in the reference cell 21 and the arithmetic cell 31.

In FIG. 13, the transistor 500 is provided above the transistor 550, and the capacitor 600 is provided above the transistor 550 and the transistor 500.

The transistor 550 is provided on a substrate 311. The substrate 311 is a p-type silicon substrate, for example. The substrate 311 may be an n-type silicon substrate. An oxide layer 314 is preferably an insulating layer formed with an oxide buried (Burried oxide) into the substrate 311 (the insulating layer is also referred to as a BOX layer), e.g., silicon oxide. The transistor 550 is formed using single crystal silicon provided over the substrate 311 with the oxide layer 314 sandwiched therebetween; that is, the transistor 550 is provided on an SOI (Silicon On Insulator) substrate.

The substrate 311 included in the SOI substrate is provided with an insulator 313 serving as an element isolation layer. The substrate 311 includes a well region 312. The well region 312 is a region to which n-type or p-type conductivity is imparted in accordance with the conductivity of the transistor 550. The single crystal silicon in the SOI substrate is provided with a semiconductor region 315 and a low-resistance region 316a and a low-resistance region 316b functioning as a source region and a drain region. A low-resistant region 316c is provided over the well region 312.

The transistor 550 can be provided to overlap with the well region 312 to which an impurity element imparting conductivity is added. The well region 312 can function as a bottom gate electrode of the transistor 550 by independently changing the potential through the low-resistance region 316c. Thus, the threshold voltage of the transistor 550 can be controlled. In particular, when a negative potential is applied to the well region 312, the threshold voltage of the transistor 550 can be further increased, and the off-state current can be reduced. Thus, a negative potential is applied to the well region 312, so that a drain current when a potential applied to a gate electrode of the Si transistor is 0 V can be reduced. As a result, power consumption of the semiconductor device 10, the arithmetic device MAC1, and the like each including the transistor 550 can be reduced, and the arithmetic efficiency can be improved.

The transistor 550 preferably has a structure in which the top surface and the side surface in the channel width direction of the semiconductor layer are covered with a conductor 318 with an insulator 317 therebetween, that is, a Fin-type structure. Such a Fin-type transistor 550 can have an increased effective channel width, and thus have improved on-state characteristics. In addition, since contribution of an electric field of a gate electrode can be increased, the off-state characteristics of the transistor 550 can be improved.

Note that the transistor 550 can be either a p-channel transistor or an n-channel transistor.

The conductor 318 sometimes functions as a first gate (also referred to as top gate) electrode. In addition, the well region 312 sometimes functions as a second gate (also referred to as bottom gate) electrode. In that case, a potential applied to the well region 312 can be controlled through the low-resistance region 316c.

A region of the semiconductor region 315 where a channel is formed, a region in the vicinity thereof, the low-resistance region 316a and the low-resistance region 316b functioning as a source region and a drain region, the low-resistance region 316c connected to an electrode controlling the potential of the well region 312, and the like preferably contain a semiconductor such as a silicon-based semiconductor, and preferably contain single crystal silicon. Alternatively, the regions may be formed using a material containing Ge (germanium), SiGe (silicon germanium), GaAs (gallium arsenide), GaAlAs (gallium aluminum arsenide), or the like. A structure may be employed in which silicon whose effective mass is controlled by applying stress to the crystal lattice and changing the lattice spacing is used. Alternatively, the transistor 550 may be a HEMT (High Electron Mobility Transistor) with use of GaAs and GaAlAs, or the like.

The well region 312, the low-resistance region 316a, the low-resistance region 316b, and the low-resistance region 316c contain an element that imparts n-type conductivity, such as arsenic or phosphorus, or an element that imparts p-type conductivity, such as boron, in addition to the semiconductor material used for the semiconductor region 315.

For the conductor 318 functioning as a gate electrode, a semiconductor material such as silicon containing the element that imparts n-type conductivity, such as arsenic or phosphorus, or the element that imparts p-type conductivity, such as boron, or a conductive material such as a metal material, an alloy material, or a metal oxide material can be used. Alternatively, silicide such as nickel silicide may be used for the conductor 318.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

To form each of the low-resistance region 316a, the low-resistance region 316b, and the low-resistance region 316c, another conductor, for example, silicide such as nickel silicide may be stacked. With this structure, the conductivity of the region functioning as an electrode can be increased. At this time, an insulator functioning as a sidewall spacer (also referred to as a sidewall insulating layer) may be provided at the side surface of the conductor 318 functioning as a gate electrode and the side surface of the insulator functioning as a gate insulating film. This structure can prevent electrical continuity from being established between the conductor 318 and each of the low-resistance region 316a and the low-resistance region 316b.

An insulator 320, an insulator 322, an insulator 324, and an insulator 326 are provided to be stacked in this order to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like may be used, for example.

Note that in this specification, silicon oxynitride refers to a material that contains oxygen at a higher proportion than nitrogen in its composition, and silicon nitride oxide refers to a material that contains nitrogen at a higher proportion than oxygen in its composition. Furthermore, in this specification, aluminum oxynitride refers to a material that contains oxygen at a higher proportion than nitrogen in its composition, and aluminum nitride oxide refers to a material that contains nitrogen at a higher proportion than oxygen in its composition.

The insulator 322 may have a function of a planarization film for eliminating a level difference caused by the transistor 550 or the like provided below the insulator 322. For example, a top surface of the insulator 322 may be planarized by planarization treatment using a chemical mechanical polishing (CMP) method or the like to improve planarity.

In addition, for the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550. The film that inhibits hydrogen diffusion is specifically a film from which a small amount of hydrogen is released.

The amount of released hydrogen can be analyzed by thermal desorption spectroscopy (TDS) or the like, for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm², in the TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. When a material with a low permittivity is used for an interlayer film, parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each have a function of a plug or a wiring. Furthermore, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

A wiring layer may be provided over the insulator 326 and the conductor 330. For example, in FIG. 13, an insulator 350, an insulator 352, and an insulator 354 are provided to be stacked in this order. Furthermore, a conductor 356 is formed in the insulator 350, the insulator 352, and the insulator 354. The conductor 356 has a function of a plug or a wiring that is connected to the transistor 550. Note that the conductor 356 can be provided using a material similar to those for the conductor 328 and the conductor 330.

Note that for example, like the insulator 324, the insulator 350 is preferably formed using an insulator having a barrier property against hydrogen. Furthermore, the conductor 356 preferably contains a conductor having a barrier property against hydrogen. In particular, the conductor having a barrier property against hydrogen is formed in an opening portion of the insulator 350 having a barrier property against hydrogen. With this structure, the transistor 550 and the transistor 500 can be separated by a barrier layer, so that diffusion of hydrogen from the transistor 550 into the transistor 500 can be inhibited.

Note that for the conductor having a barrier property against hydrogen, tantalum nitride is preferably used, for example. In addition, by stacking tantalum nitride and tungsten, which has high conductivity, the diffusion of hydrogen from the transistor 550 can be inhibited while the conductivity as a wiring is kept. In that case, a structure in which a tantalum nitride layer having a barrier property against hydrogen is in contact with the insulator 350 having a barrier property against hydrogen is preferable.

A wiring layer may be provided over the insulator 354 and the conductor 356. For example, in FIG. 13, an insulator 360, an insulator 362, and an insulator 364 are provided to be stacked in this order. Furthermore, a conductor 366 is formed in the insulator 360, the insulator 362, and the insulator 364. The conductor 366 has a function of a plug or a wiring. Note that the conductor 366 can be provided using a material similar to those for the conductor 328 and the conductor 330.

Note that for example, like the insulator 324, the insulator 360 is preferably formed using an insulator having a barrier property against hydrogen. Furthermore, the conductor 366 preferably contains a conductor having a barrier property against hydrogen. In particular, the conductor having a barrier property against hydrogen is formed in an opening portion of the insulator 360 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 364 and the conductor 366. For example, in FIG. 13, an insulator 370, an insulator 372, and an insulator 374 are provided to be stacked in this order. Furthermore, a conductor 376 is formed in the insulator 370, the insulator 372, and the insulator 374. The conductor 376 has a function of a plug or a wiring. Note that the conductor 376 can be provided using a material similar to those for the conductor 328 and the conductor 330.

Note that for example, like the insulator 324, the insulator 370 is preferably formed using an insulator having a barrier property against hydrogen. Furthermore, the conductor 376 preferably contains a conductor having a barrier property against hydrogen. In particular, the conductor having a barrier property against hydrogen is formed in an opening portion of the insulator 370 having a barrier property against hydrogen. With this structure, the transistor 550 and the transistor 500 can be separated by a barrier layer, so that diffusion of hydrogen from the transistor 550 into the transistor 500 can be inhibited.

A wiring layer may be provided over the insulator 374 and the conductor 376. For example, in FIG. 13, an insulator 380, an insulator 382, and an insulator 384 are provided to be stacked in this order. Furthermore, a conductor 386 is formed in the insulator 380, the insulator 382, and the insulator 384. The conductor 386 has a function of a plug or a wiring. Note that the conductor 386 can be provided using a material similar to those for the conductor 328 and the conductor 330.

Note that for example, like the insulator 324, the insulator 380 is preferably formed using an insulator having a barrier property against hydrogen. Furthermore, the conductor 386 preferably contains a conductor having a barrier property against hydrogen. In particular, the conductor having a barrier property against hydrogen is formed in an opening portion of the insulator 380 having a barrier property against hydrogen. With this structure, the transistor 550 and the transistor 500 can be separated by a barrier layer, so that diffusion of hydrogen from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. Three or less wiring layers that are similar to the wiring layer including the conductor 356 may be provided, or five or more wiring layers that are similar to the wiring layer including the conductor 356 may be provided.

An insulator 510, an insulator 512, an insulator 514, and an insulator 516 are provided to be stacked in this order over the insulator 384. A substance having a barrier property against oxygen or hydrogen is preferably used for any of the insulator 510, the insulator 512, the insulator 514, and the insulator 516.

For example, for the insulator 510 and the insulator 514, it is preferable to use a film having a barrier property against hydrogen or impurities diffused from the substrate 311, a region where the transistor 550 is provided, or the like into the region where the transistor 500 is provided. Therefore, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Therefore, a film that inhibits hydrogen diffusion is preferably provided between the transistor 500 and the transistor 550.

In addition, for the film having a barrier property against hydrogen, a metal oxide such as aluminum oxide, hafnium oxide, or tantalum oxide is preferably used for the insulator 510 and the insulator 514, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent entry of impurities such as hydrogen and moisture into the transistor 500 in the manufacturing process and after the manufacture of the transistor. In addition, release of oxygen from the oxide included in the transistor 500 can be inhibited. Therefore, aluminum oxide is suitably used for a protective film of the transistor 500.

In addition, for the insulator 512 and the insulator 516, a material similar to that for the insulator 320 can be used, for example. Furthermore, when a material with a comparatively low permittivity is used for these insulators, parasitic capacitance generated between wirings can be reduced. A silicon oxide film, a silicon oxynitride film, or the like can be used for the insulator 512 and the insulator 516, for example.

Furthermore, a conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring that is connected to the capacitor 600 or the transistor 550. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 550 and the transistor 500 can be separated by a layer having a barrier property against oxygen, hydrogen, and water; thus, diffusion of hydrogen from the transistor 550 into the transistor 500 can be inhibited.

The transistor 500 is provided above the insulator 516.

As illustrated in FIG. 14A and FIG. 14B, the transistor 500 includes the conductor 503 positioned to be embedded in the insulator 514 and the insulator 516; an insulator 522 positioned over the insulator 516 and the conductor 503; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap with a region between the conductor 542a and the conductor 542b; an insulator 545 positioned on a bottom surface and a side surface of an opening; and a conductor 560 positioned over a formation surface of the insulator 545.

In addition, as illustrated in FIG. 14A and FIG. 14B, an insulator 544 is preferably placed between the insulator 580 and the oxide 530a, the oxide 530b, the conductor 542a, and the conductor 542b. Furthermore, as illustrated in FIG. 14A and FIG. 14B, the conductor 560 preferably includes a conductor 560a provided inside the insulator 545 and a conductor 560b provided to be embedded inside the conductor 560a. Moreover, as illustrated in FIG. 14A and FIG. 14B, an insulator 574 is preferably placed over the insulator 580, the conductor 560, and the insulator 545.

Note that in this specification and the like, the oxide 530a and the oxide 530b are sometimes collectively referred to as an oxide 530.

Note that although a structure of the transistor 500 in which two layers of the oxide 530a and the oxide 530b are stacked in a region where a channel is formed and its vicinity is illustrated, the present invention is not limited thereto. For example, it is possible to employ a structure in which a single layer of the oxide 530b or a stacked-layer structure of three or more layers is provided.

Furthermore, although the conductor 560 is illustrated to have a stacked-layer structure of two layers in the transistor 500, the present invention is not limited thereto. For example, the conductor 560 may have a single-layer structure or a stacked-layer structure of three or more layers. Note that the structure of the transistor 500 illustrated in FIG. 13, FIG. 14A, and FIG. 14B is a non-limiting example and an appropriate transistor can be used in accordance with a circuit structure, a driving method, or the like.

Here, the conductor 560 functions as a gate electrode of the transistor, and the conductor 542a and the conductor 542b function as a source electrode and a drain electrode. As described above, the conductor 560 is formed to be embedded in the opening of the insulator 580 and the region between the conductor 542a and the conductor 542b. The positions of the conductor 560, the conductor 542a, and the conductor 542b are selected in a self-aligned manner in the opening of the insulator 580. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the switching speed of the transistor 500 can be improved, and the transistor 500 can have high frequency characteristics.

The conductor 560 sometimes functions as a first gate (also referred to as top gate) electrode. In addition, the conductor 503 sometimes functions as a second gate (also referred to as bottom gate) electrode. In that case, the threshold voltage of the transistor 500 can be controlled by changing a potential applied to the conductor 503 not in synchronization with but independently of a potential applied to the conductor 560. In particular, when a negative potential is applied to the conductor 503, the threshold voltage of the transistor 500 can be further increased, and the off-state current can be reduced. Thus, a drain current at the time when a potential applied to the conductor 560 is 0 V can be lower in the case where a negative potential is applied to the conductor 503 than in the case where a negative potential is not applied.

The conductor 503 is placed to overlap with the oxide 530 and the conductor 560. Thus, in the case where potentials are applied to the conductor 560 and the conductor 503, an electric field generated from the conductor 560 and an electric field generated from the conductor 503 are connected, so that a channel formation region formed in the oxide 530 can be covered.

In this specification and the like, a transistor structure in which a channel formation region is electrically surrounded by electric fields of a pair of gate electrodes (a first gate electrode and a second gate electrode) is referred to as a surrounded channel (S-channel) structure. The S-channel structure disclosed in this specification and the like is different from a Fin-type structure and a planar structure. With the S-channel structure, resistance to a short-channel effect can be enhanced, that is, a transistor in which a short-channel effect is unlikely to occur can be provided.

In addition, the conductor 503 has a structure similar to that of the conductor 518; a conductor 503a is formed in contact with an inner wall of an opening in the insulator 514 and the insulator 516, and a conductor 503b is formed on the inner side. Note that although the transistor 500 having a structure in which the conductor 503a and the conductor 503b are stacked is illustrated, the present invention is not limited thereto. For example, the conductor 503 may be provided as a single layer or a stacked-layer structure of three or more layers.

Here, for the conductor 503a, a conductive material having a function of inhibiting diffusion of impurities such as a hydrogen atom, a hydrogen molecule, a water molecule, and a copper atom (through which the impurities are less likely to pass) is preferably used. Alternatively, it is preferable to use a conductive material that has a function of inhibiting diffusion of oxygen (e.g., at least one of an oxygen atom, an oxygen molecule, and the like) (through which oxygen is less likely to pass). Note that in this specification, the function of inhibiting diffusion of impurities or oxygen means a function of inhibiting diffusion of any one or a plurality of the impurities and oxygen.

For example, when the conductor 503a has a function of inhibiting diffusion of oxygen, a reduction in conductivity of the conductor 503b due to oxidation can be inhibited.

In addition, in the case where the conductor 503 also functions as a wiring, a conductive material with high conductivity that contains tungsten, copper, or aluminum as its main component is preferably used for the conductor 503b. Note that although the conductor 503 is illustrated to have a stacked layer of the conductor 503a and the conductor 503b in this embodiment, the conductor 503 may have a single-layer structure.

The insulator 522 and the insulator 524 have a function of a second gate insulating film.

Here, as the insulator 524 that is in contact with the oxide 530, an insulator that contains oxygen more than oxygen in the stoichiometric composition is preferably used. Such oxygen is easily released from the insulator by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (Vo) in the oxide 530 can be reduced and the reliability of the transistor 500 can be improved. When hydrogen enters the oxygen vacancies in the oxide 530, such defects (hereinafter, referred to as VoH in some cases) serve as donors and generate electrons serving as carriers in some cases. In other cases, bonding of part of hydrogen to oxygen bonded to a metal atom generates electrons serving as carriers. Thus, a transistor using an oxide semiconductor that contains a large amount of hydrogen is likely to have normally-on characteristics. Moreover, hydrogen in an oxide semiconductor is easily transferred by a stress such as heat or an electric field; thus, a large amount of hydrogen contained in an oxide semiconductor might reduce the reliability of the transistor. In one embodiment of the present invention, VoH in the oxide 530 is preferably reduced as much as possible so that the oxide 530 becomes a highly purified intrinsic or substantially highly purified intrinsic oxide. It is important to remove impurities such as moisture and hydrogen in an oxide semiconductor (sometimes described as “dehydration” or “dehydrogenation treatment”) and to compensate for oxygen vacancies by supplying oxygen to the oxide semiconductor (sometimes described as “oxygen adding treatment”) in order to obtain an oxide semiconductor whose VoH is sufficiently reduced. When an oxide semiconductor with sufficiently reduced impurities such as VoH is used for a channel formation region of a transistor, stable electrical characteristics can be given.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis preferably falls within the range of 100° C. to 700° C., or 100° C. to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen to be H₂O, and removed from the oxide 530 or an insulator in the vicinity of the oxide 530 in some cases. Part of hydrogen may be gettered into the conductor 542 in some cases.

For the microwave treatment, for example, an apparatus including a power source that generates high-density plasma or an apparatus including a power source that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate (O₂/(O₂+Ar)) is lower than or equal to 50%, preferably higher than or equal to 10% and lower than or equal to 30%.

In a manufacturing process of the transistor 500, heat treatment is preferably performed with the surface of the oxide 530 exposed. The heat treatment is performed at higher than or equal to 100° C. and lower than or equal to 450° C., preferably higher than or equal to 350° C. and lower than or equal to 400° C., for example. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (Vo). The heat treatment may be performed under reduced pressure. Alternatively, heat treatment may be performed in an atmosphere containing an oxidizing gas at 10 ppm or more, 1% or more, or 10% or more in order to compensate for released oxygen after heat treatment in a nitrogen gas or inert gas atmosphere. Alternatively, heat treatment may be performed in a nitrogen gas or inert gas atmosphere successively after heat treatment in an atmosphere containing an oxidizing gas at 10 ppm or more, 1% or more, or 10% or more.

Note that the oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, it is preferable that the insulator 522 have a function of inhibiting diffusion of oxygen (e.g., an oxygen atom and an oxygen molecule) (or that the above oxygen be less likely to pass through the insulator 522).

The insulator 522 preferably has a function of inhibiting diffusion of oxygen, impurities, or the like, in which case oxygen contained in the oxide 530 is not diffused to the conductor 503 side. Furthermore, the conductor 503 can be inhibited from reacting with oxygen contained in the insulator 524, the oxide 530, or the like.

For the insulator 522, a single layer or stacked layers of an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST) is preferably used, for example. As miniaturization and high integration of transistors progress, a problem such as a leakage current might arise because of a thinner gate insulating film. When a high-k material is used for an insulator functioning as the gate insulating film, a gate potential during transistor operation can be reduced while the physical thickness is maintained.

It is particularly preferable to use an insulator containing an oxide of one or both of aluminum and hafnium, which is an insulating material having a function of inhibiting diffusion of impurities, oxygen, and the like (through which oxygen is less likely to pass). Aluminum oxide, hafnium oxide, an oxide containing aluminum and hafnium (hafnium aluminate), or the like is preferably used as the insulator containing an oxide of one or both of aluminum and hafnium. In the case where the insulator 522 is formed using such a material, the insulator 522 functions as a layer that inhibits release of oxygen from the oxide 530 and/or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. The insulator over which silicon oxide, silicon oxynitride, or silicon nitride is stacked may be used.

Note that in the transistor 500 in FIG. 14A and FIG. 14B, the insulator 522 and the insulator 524 are illustrated as the second gate insulating film having a stacked-layer structure of two layers; however, the second gate insulating film may be a single layer or may have a stacked-layer structure of three layers or four or more layers. In such cases, without limitation to a stacked-layer structure formed of the same material, a stacked-layer structure formed of different materials may be employed.

In the transistor 500, a metal oxide functioning as an oxide semiconductor is used as the oxide 530 including a channel formation region. For example, as the oxide 530, a metal oxide such as an In-M-Zn oxide (the element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an ALD (Atomic Layer Deposition) method. Note that the metal oxide functioning as an oxide semiconductor is described in detail in another embodiment.

The metal oxide functioning as the channel formation region in the oxide 530 has a bandgap of preferably 2 eV or greater, further preferably 2.5 eV or greater. With the use of a metal oxide having such a large bandgap, the off-state current of the transistor can be reduced.

When the oxide 530 includes the oxide 530a under the oxide 530b, it is possible to inhibit diffusion of impurities into the oxide 530b from the components formed below the oxide 530a.

Note that the oxide 530 preferably has a stacked-layer structure of a plurality of oxide layers that differ in the atomic ratio of metal atoms. Specifically, the atomic ratio of the element M to the constituent elements in the metal oxide used as the oxide 530a is preferably higher than the atomic ratio of the element M to the constituent elements in the metal oxide used as the oxide 530b. In addition, the atomic ratio of the element M to In in the metal oxide used as the oxide 530a is preferably higher than the atomic ratio of the element M to In in the metal oxide used as the oxide 530b. Furthermore, the atomic ratio of In to the element M in the metal oxide used as the oxide 530b is preferably higher than the atomic ratio of In to the element M in the metal oxide used as the oxide 530a.

The energy of the conduction band minimum of the oxide 530a is preferably higher than the energy of the conduction band minimum of the oxide 530b. In other words, the electron affinity of the oxide 530a is preferably smaller than the electron affinity of the oxide 530b.

Here, the energy level of the conduction band minimum gently changes at a junction portion of the oxide 530a and the oxide 530b. In other words, the energy level of the conduction band minimum at the junction portion of the oxide 530a and the oxide 530b continuously changes or is continuously joined. This can be obtained by decreasing the density of defect states in a mixed layer formed at the interface between the oxide 530a and the oxide 530b.

Specifically, when the oxide 530a and the oxide 530b contain a common element (as a main component) in addition to oxygen, a mixed layer with a low density of defect states can be formed. For example, in the case where the oxide 530b is an In—Ga—Zn oxide, an In—Ga—Zn oxide, a Ga—Zn oxide, gallium oxide, or the like is preferably used as the oxide 530a.

At this time, the oxide 530b serves as a main carrier path. When the oxide 530a has the above-described structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are not easily oxidized or materials that retain their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 14A, a stacked-layer structure of two or more layers may be employed. For example, it is preferable to stack a tantalum nitride film and a tungsten film. Alternatively, a titanium film and an aluminum film may be stacked. Alternatively, a two-layer structure where an aluminum film is stacked over a tungsten film, a two-layer structure where a copper film is stacked over a copper-magnesium-aluminum alloy film, a two-layer structure where a copper film is stacked over a titanium film, or a two-layer structure where a copper film is stacked over a tungsten film may be employed.

Other examples include a three-layer structure where a titanium film or a titanium nitride film is formed, an aluminum film or a copper film is stacked over the titanium film or the titanium nitride film, and a titanium film or a titanium nitride film is formed thereover; and a three-layer structure where a molybdenum film or a molybdenum nitride film is formed, an aluminum film or a copper film is stacked over the molybdenum film or the molybdenum nitride film, and a molybdenum film or a molybdenum nitride film is formed thereover. Note that a transparent conductive material containing indium oxide, tin oxide, or zinc oxide may be used.

In addition, as illustrated in FIG. 14A, a region 543a and a region 543b are formed as low-resistance regions at an interface between the oxide 530 and the conductor 542a (the conductor 542b) and in the vicinity of the interface in some cases. In that case, the region 543a functions as one of a source region and a drain region, and the region 543b functions as the other of the source region and the drain region. Furthermore, the channel formation region is formed in a region between the region 543a and the region 543b.

When the conductor 542a (the conductor 542b) is provided to be in contact with the oxide 530, the oxygen concentration in the region 543a (the region 543b) sometimes decreases. In addition, a metal compound layer that contains the metal contained in the conductor 542a (the conductor 542b) and the component of the oxide 530 is formed in the region 543a (the region 543b) in some cases. In such a case, the carrier density of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. At this time, the insulator 544 may be provided to cover a side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used for the insulator 544. Alternatively, silicon nitride oxide, silicon nitride, or the like can be used for the insulator 544.

It is particularly preferable to use an insulator containing an oxide of one or both of aluminum and hafnium, such as aluminum oxide, hafnium oxide, or an oxide containing aluminum and hafnium (hafnium aluminate), as the insulator 544. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose their conductivity even after absorbing oxygen. Design is determined as appropriate in consideration of required transistor characteristics.

When the insulator 544 is included, diffusion of impurities such as water and hydrogen contained in the insulator 580 into the oxide 530b can be inhibited. Furthermore, oxidation of the conductor 542 due to excess oxygen contained in the insulator 580 can be inhibited.

The insulator 545 functions as a first gate insulating film. Like the insulator 524, the insulator 545 is preferably formed using an insulator that contains excess oxygen and releases oxygen by heating.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride are preferable because they are thermally stable.

When an insulator containing excess oxygen is provided as the insulator 545, oxygen can be effectively supplied from the insulator 545 to the channel formation region of the oxide 530b. Furthermore, as in the insulator 524, the concentration of impurities such as water and hydrogen in the insulator 545 is preferably reduced. The thickness of the insulator 545 is preferably greater than or equal to 1 nm and less than or equal to 20 nm. Before and/or after formation of the insulator 545, the above-described microwave treatment may be performed.

Furthermore, to efficiently supply excess oxygen contained in the insulator 545 to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 may be used.

Note that the insulator 545 may have a stacked-layer structure like the second gate insulating film. As miniaturization and high integration of transistors progress, a problem such as a leakage current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have a high relative permittivity.

Although the conductor 560 that functions as the first gate electrode and has a two-layer structure is illustrated in FIG. 14A and FIG. 14B, a single-layer structure or a stacked-layer structure of three or more layers may be employed.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to use a conductive material that has a function of inhibiting diffusion of oxygen (e.g., at least one of an oxygen atom, an oxygen molecule, and the like). When the conductor 560a has a function of inhibiting diffusion of oxygen, a reduction in conductivity of the conductor 560b due to oxidation caused by oxygen contained in the insulator 545 can be inhibited. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is deposited by a sputtering method, the conductor 560a can have a reduced value of electrical resistance to be a conductor. Such a conductor can be referred to as an OC (Oxide Conductor) electrode.

In addition, a conductive material containing tungsten, copper, or aluminum as its main component is preferably used for the conductor 560b. Furthermore, the conductor 560b also functions as a wiring and thus a conductor having high conductivity is preferably used as the conductor 560b. For example, a conductive material containing tungsten, copper, or aluminum as its main component can be used. The conductor 560b may have a stacked-layer structure, for example, a stacked-layer structure of any of the above conductive materials and titanium or titanium nitride.

The insulator 580 is provided over the conductor 542a and the conductor 542b with the insulator 544 therebetween. The insulator 580 preferably includes an excess-oxygen region. For example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like is preferably contained as the insulator 580. In particular, silicon oxide and silicon oxynitride are preferable because they are thermally stable. In particular, silicon oxide and porous silicon oxide are preferable because an excess-oxygen region can be easily formed in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water and hydrogen in the insulator 580 is preferably reduced.

The opening of the insulator 580 is formed to overlap with the region between the conductor 542a and the conductor 542b. Accordingly, the conductor 560 is formed to be embedded in the opening of the insulator 580 and the region between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with a top surface of the insulator 580, a top surface of the conductor 560, and a top surface of the insulator 545. When the insulator 574 is deposited by a sputtering method, excess-oxygen regions can be provided in the insulator 545 and the insulator 580. Accordingly, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Accordingly, aluminum oxide deposited by a sputtering method serves as an oxygen supply source and can also have a function of a barrier film against impurities such as hydrogen.

In addition, an insulator 581 functioning as an interlayer film is preferably provided over the insulator 574. As in the insulator 524 or the like, the concentration of impurities such as water and hydrogen in the insulator 581 is preferably reduced.

Furthermore, a conductor 540a and a conductor 540b are placed in openings formed in the insulator 581, the insulator 574, the insulator 580, and the insulator 544. The conductor 540a and the conductor 540b are provided to face each other with the conductor 560 therebetween. The structure of the conductor 540a and the conductor 540b is similar to a structure of a conductor 546 and a conductor 548 that will be described later.

An insulator 582 is provided over the insulator 581. A substance having a barrier property against oxygen and/or hydrogen is preferably used for the insulator 582. Therefore, a material similar to that for the insulator 514 can be used for the insulator 582. For the insulator 582, a metal oxide such as aluminum oxide, hafnium oxide, or tantalum oxide is preferably used, for example.

In particular, aluminum oxide has an excellent blocking effect that prevents the passage of both oxygen and impurities such as hydrogen and moisture which are factors of fluctuation in electrical characteristics of the transistor. Accordingly, aluminum oxide can prevent entry of impurities such as hydrogen and moisture into the transistor 500 in the manufacturing process and after the manufacture of the transistor. In addition, release of oxygen from the oxide included in the transistor 500 can be inhibited. Therefore, aluminum oxide is suitably used for a protective film of the transistor 500.

An insulator 586 is provided over the insulator 582. For the insulator 586, a material similar to that for the insulator 320 can be used. Furthermore, when a material with a comparatively low permittivity is used for these insulators, parasitic capacitance generated between wirings can be reduced. A silicon oxide film, a silicon oxynitride film, or the like can be used for the insulator 586, for example.

Furthermore, the conductor 546, the conductor 548, and the like are embedded in the insulator 522, the insulator 524, the insulator 544, the insulator 580, the insulator 574, the insulator 581, the insulator 582, and the insulator 586.

The conductor 546 and the conductor 548 have functions of plugs or wirings that are connected to the capacitor 600, the transistor 500, or the transistor 550. The conductor 546 and the conductor 548 can be provided using materials similar to those for the conductor 328 and the conductor 330.

After the transistor 500 is formed, an opening may be formed to surround the transistor 500 and an insulator having a high barrier property against hydrogen or water may be formed to cover the opening. Surrounding the transistor 500 with the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as some of the manufacturing steps of the transistor 500. The insulator having a high barrier property against hydrogen or water may be formed using a material similar to that for the insulator 522 or the insulator 514, for example.

Next, the capacitor 600 is provided above the transistor 500. The capacitor 600 includes a conductor 610, a conductor 620, and an insulator 630.

In addition, a conductor 612 may be provided over the conductor 546 and the conductor 548. The conductor 612 has a function of a plug or a wiring that is connected to the transistor 500. The conductor 610 has a function of an electrode of the capacitor 600. Note that the conductor 612 and the conductor 610 can be formed at the same time.

For the conductor 612 and the conductor 610, a metal film containing an element selected from molybdenum, titanium, tantalum, tungsten, aluminum, copper, chromium, neodymium, and scandium; a metal nitride film containing the above element as its component (a tantalum nitride film, a titanium nitride film, a molybdenum nitride film, or a tungsten nitride film); or the like can be used. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are described in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that a conductive material such as a metal material, an alloy material, or a metal oxide material can be used for the conductor 620. It is preferable to use a high-melting-point material that has both heat resistance and conductivity, such as tungsten or molybdenum, and it is particularly preferable to use tungsten. In addition, in the case where the conductor 620 is formed concurrently with another component such as a conductor, Cu (copper), Al (aluminum), or the like, which is a low-resistance metal material, may be used.

An insulator 640 is provided over the conductor 620 and the insulator 630. For the insulator 640, a material similar to that for the insulator 320 can be used. In addition, the insulator 640 may function as a planarization film that covers an uneven shape therebelow.

With the use of this structure, a semiconductor device using a transistor including an oxide semiconductor can be miniaturized or highly integrated.

The configuration, structure, method, and the like described in this embodiment can be used in combination as appropriate with the configurations, structures, methods, and the like described in the other embodiments, the example, and the like.

### Embodiment 5

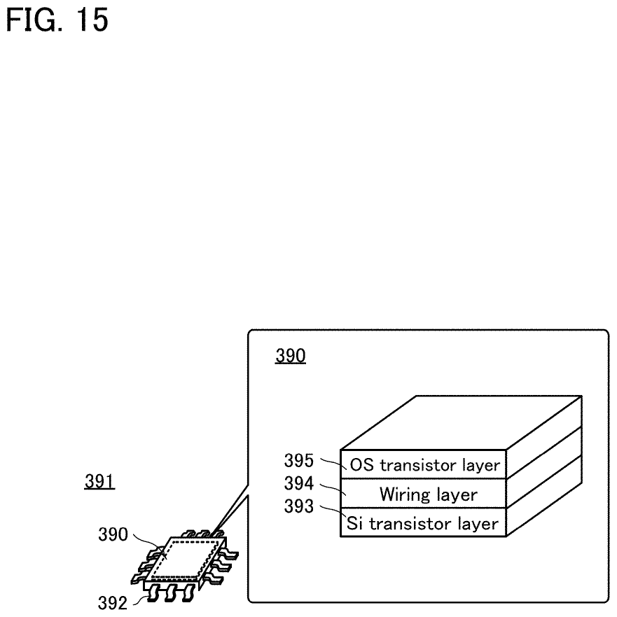

In this embodiment, the structure of an integrated circuit including components of the semiconductor device 10 and the arithmetic device MAC1 described in the above embodiment will be described with reference to FIG. 15.

FIG. 15 illustrates an example of a semiconductor chip 391 including an integrated circuit 390. The semiconductor chip 391 illustrated in FIG. 15 includes leads 392 and the integrated circuit 390. As for the integrated circuit 390, various circuits, including the semiconductor device 10 and the arithmetic device MAC1 described in the above embodiments, are provided in one die. The integrated circuit 390 has a stacked-layer structure, which is roughly divided into a layer including Si transistors (a Si transistor layer 393), a wiring layer 394, and a layer including OS transistors (an OS transistor layer 395). Since the OS transistor layer 395 can be provided to be stacked over the Si transistor layer 393, a reduction in the size of the semiconductor chip 391 is facilitated.

Although a QFP (Quad Flat Package) is used as the package of the semiconductor chip 391 in FIG. 15, the form of the package is not limited thereto. For other structure examples, a DIP (Dual In-line Package) and a PGA (Pin Grid Array), which are of an insertion mount type; an SOP (Small Outline Package), an SSOP (Shrink Small Outline Package), a TSOP (Thin-Small Outline Package), an LCC (Leaded Chip Carrier), a QFN (Quad Flat Non-leaded package), a BGA (Ball Grid Array), and an FBGA (Fine pitch Ball Grid Array), which are of a surface mount type; a DTP (Dual Tape carrier Package) and a QTP (Quad Tape-carrier Package), which are of a contact mount type; and the like can be used as appropriate.

The semiconductor device 10 and the arithmetic device MAC1 including Si transistors can be entirely formed in the Si transistor layer 393, the wiring layer 394, and the OS transistor layer 395. In other words, elements included in the semiconductor device can be formed through the same manufacturing process. Thus, the number of steps in the manufacturing process of the semiconductor chip illustrated in FIG. 15 does not need to be increased even when the number of elements is increased, and accordingly the semiconductor device can be incorporated at low cost.

According to one embodiment of the present invention described above, a novel semiconductor device and electronic device can be provided. According to another embodiment of the present invention, a semiconductor device and an electronic device having low power consumption can be provided. According to another embodiment of the present invention, a semiconductor device and an electronic device capable of suppressing heat generation can be provided.

This embodiment can be combined with the description of the other embodiments as appropriate.

### Embodiment 6

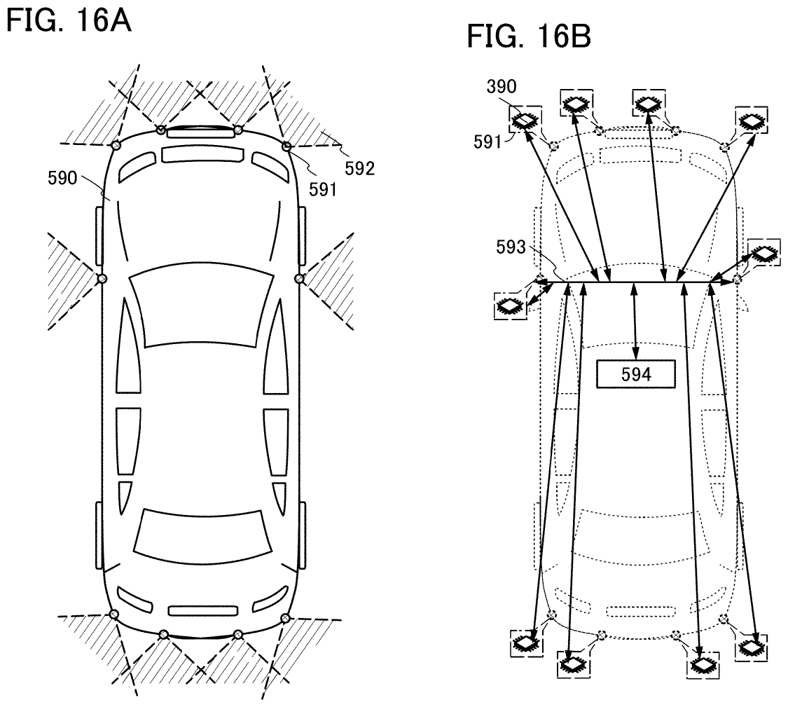

In this embodiment, an electronic device, a moving object, and an arithmetic system in which the integrated circuit 390 (or the semiconductor chip 391 including the integrated circuit 390) described in the above embodiment can be used will be described with reference to FIG. 16 to FIG. 19.

FIG. 16A illustrates an external view of an automobile as an example of a moving object. FIG. 16B is a simplified diagram illustrating data transmission in the automobile. An automobile 590 includes a plurality of cameras 591 and the like. The automobile 590 also includes various sensors such as an infrared radar, a millimeter wave radar, and a laser radar (not illustrated) and the like.

In the automobile 590, the above-described integrated circuit 390 can be used for the camera 591 and the like. The automobile 590 can perform autonomous driving by judging surrounding traffic information such as the presence of a guardrail or a pedestrian, because the camera 591 processes a plurality of images taken in a plurality of imaging directions 592 with the integrated circuit 390 described in the above embodiment and the plurality of images are collectively analyzed with a host controller 594 and the like through a bus 593 and the like. The integrated circuit 390 can be used for a system for navigation, risk prediction, or the like.

When arithmetic processing of a neural network or the like is performed on the obtained image data in the integrated circuit 390, for example, processing for the following can be performed: an increase in image resolution, a reduction in image noise, face recognition (for security reasons or the like), object recognition (for autonomous driving or the like), image compression, image compensation (a wide dynamic range), restoration of an image of a lensless image sensor, positioning, character recognition, and a reduction of glare and reflection.

Note that although an automobile is described above as an example of a moving vehicle, the moving vehicle is not limited to an automobile. Examples of moving objects also include a train, a monorail train, a ship, and a flying object (a helicopter, an unmanned aircraft (a drone), an airplane, and a rocket), and these moving objects can include a system utilizing artificial intelligence when equipped with a computer of one embodiment of the present invention.

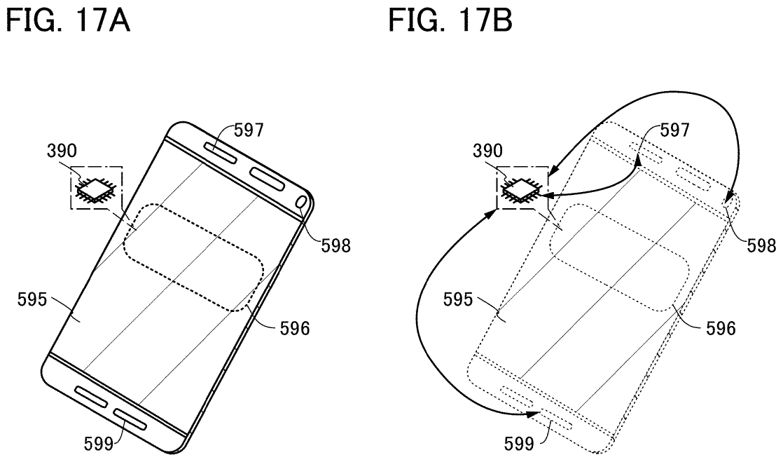

FIG. 17A is an external view illustrating an example of a portable electronic device. FIG. 17B is a simplified diagram illustrating data transmission in the portable electronic device. A portable electronic device 595 includes a printed wiring board 596, a speaker 597, a camera 598, a microphone 599, and the like.

In the portable electronic device 595, the printed wiring board 596 can be provided with the above-described integrated circuit 390. The portable electronic device 595 processes and analyzes a plurality of pieces of data obtained from the speaker 597, the camera 598, the microphone 599, and the like with the integrated circuit 390 described in the above embodiment, whereby the user's convenience can be improved.

When arithmetic processing of a neural network or the like is performed on the obtained image data in the integrated circuit 390, for example, processing for the following can be performed: an increase in image resolution, a reduction in image noise, face recognition (for security reasons or the like), object recognition (for autonomous driving or the like), image compression, image compensation (a wide dynamic range), restoration of an image of a lensless image sensor, positioning, character recognition, and a reduction of glare and reflection.

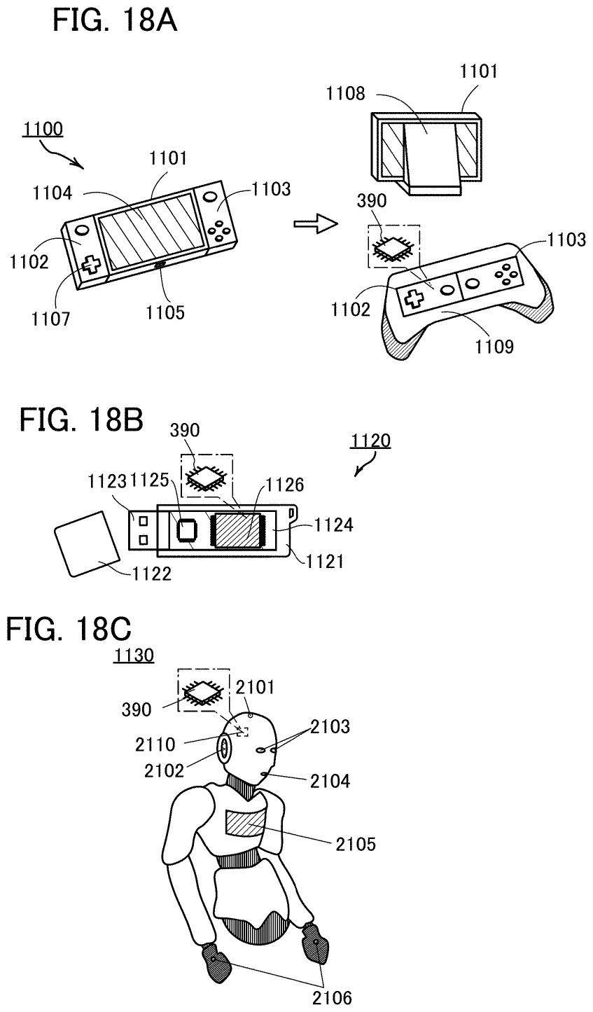

A portable game machine 1100 illustrated in FIG. 18A includes a housing 1101, a housing 1102, a housing 1103, a display portion 1104, a connection portion 1105, operation keys 1107, and the like. The housing 1101, the housing 1102, and the housing 1103 are detachable. When the connection portion 1105 provided in the housing 1101 is attached to a housing 1108, a video to be output to the display portion 1104 can be output to another video device. Alternatively, the housing 1102 and the housing 1103 are attached to a housing 1109, whereby the housing 1102 and the housing 1103 are unified and function as an operation portion. The integrated circuit 390 described in the above embodiment can be incorporated into a chip provided on a board in the housing 1102 and the housing 1103, for example.

FIG. 18B is a USB connection stick type electronic device 1120. The electronic device 1120 includes a housing 1121, a cap 1122, a USB connector 1123, and a board 1124. The board 1124 is held in the housing 1121. For example, a memory chip 1125 and a controller chip 1126 are attached to the board 1124. The integrated circuit 390 described in the above embodiment can be incorporated into the controller chip 1126 or the like of the board 1124.

FIG. 18C is a humanoid robot 1130. The robot 1130 includes sensors 2101 to 2106 and a control circuit 2110. For example, the integrated circuit 390 described in the above embodiment can be incorporated into the control circuit 2110.

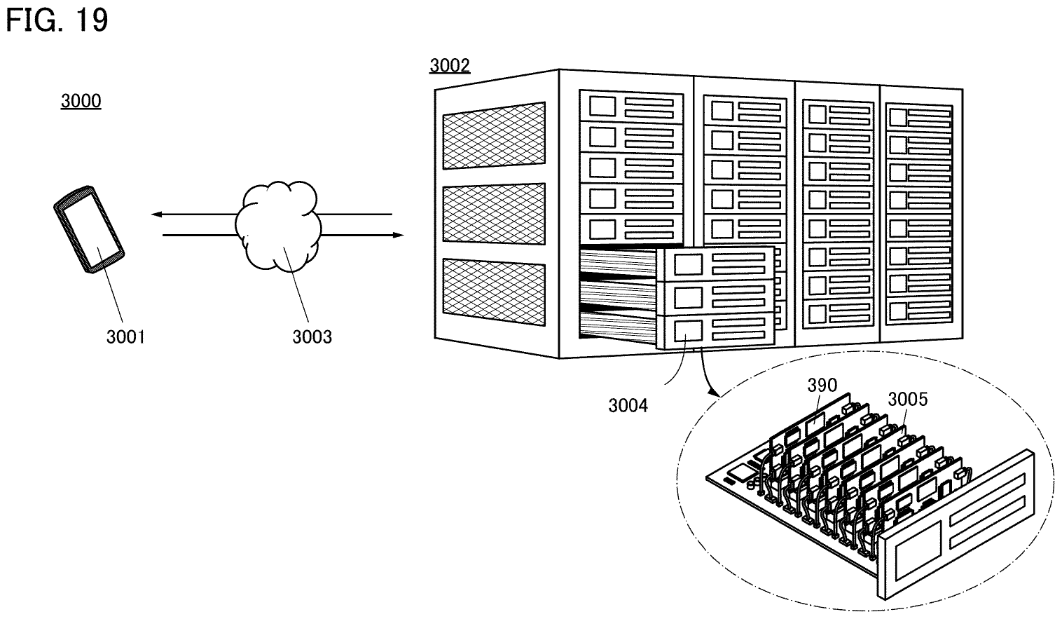

The integrated circuit 390 described in the above embodiment can be used for a server that communicates with the electronic devices instead of being incorporated into the electronic devices. In that case, the arithmetic system is configured with the electronic devices and a server. FIG. 19 illustrates a structure example of a system 3000.

The system 3000 includes an electronic device 3001 and a server 3002. Communication between the electronic device 3001 and the server 3002 can be performed through Internet connection 3003.

The server 3002 includes a plurality of racks 3004. The plurality of racks are provided with a plurality of boards 3005, and the integrated circuit 390 described in the above embodiment can be mounted on each of the boards 3005. Thus, a neural network is configured in the server 3002. The server 3002 can perform arithmetic processing of the neural network using data input from the electronic device 3001 through the Internet connection 3003. The result of the arithmetic processing executed by the server 3002 can be transmitted as needed to the electronic device 3001 through the Internet connection 3003. Accordingly, a burden of the arithmetic processing in the electronic device 3001 can be reduced.

This embodiment can be combined with the description of the other embodiments as appropriate.

### Example 1

In this example, the semiconductor devices 10 and 10B described in Embodiment 1 and a comparative example thereof will be described. Monte Carlo simulation of variation in output current responding to input data was performed to examine the arithmetic accuracy of the semiconductor devices 10 and 10B.

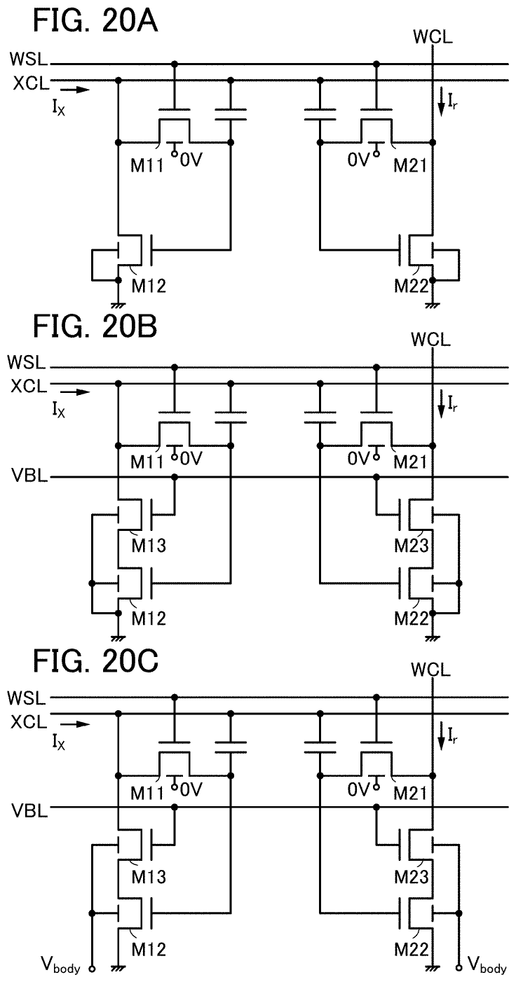

FIG. 20A illustrates a configuration of the semiconductor device 10 which does not include the transistors 23 and 33 as a comparative example. FIG. 20A illustrates transistors M11, M21, M12, and M22. Connections between circuits and wirings and the like are as shown in the drawing. The transistors M11 and M21 were OS transistors. The transistors M12 and M22 were Si transistors. The channel length (L) and the channel length (W) of each of the OS transistors were both 60 nm. The channel length (L) and the channel length (W) of each of the Si transistors were 0.65 μm and 0.4 μm, respectively. For the wiring WSL, a high level potential at the time of data writing was set to 2.5 V and a low level potential at the time of data reading was set to −0.8 V. For the wiring WCL, the drain voltage Vd at the time of data reading was set to 1.2 V. To back gates of the OS transistors, 0 V was applied. As I_{W} fed as weight data, 1 nA was supplied. The currents Iᵣ flowing in the wiring WCL when the current I_{X} fed as the input data was varied from 0 nA to 1.0 nA were observed. The number of trials of the Monte Carlo simulation was 50.

FIG. 20B illustrates the configuration of the semiconductor device 10. FIG. 20B illustrates transistors M11, M21, M12, M22, M13, and M23. Connections between circuits and wirings and the like are as shown in the drawing. The transistors M11 and M21 were OS transistors. The transistors M12, M22, M13, and M23 were Si transistors. The channel length (L) and the channel length (W) of each of the OS transistors were both 60 nm. The channel length (L) and the channel length (W) of each of the Si transistors were 0.65 μm and 0.4 μm, respectively. For the wiring WSL, a high level potential at the time of data writing was set to 2.5 V and a low level potential at the time of data reading was set to −0.8 V. For the wiring WCL, the drain voltage Vd at the time of data reading was set to 1.2 V. The voltage Vb applied to the wiring VBL was set to 0.7 V at 27° C. and 0.8 V at 85° C. To back gates of the OS transistors, 0 V was applied. As I_{W} fed as the weight data, 1 nA was supplied. The currents Iᵣ flowing in the wiring WCL when the current I_{X} fed as the input data was varied from 0 nA to 1.0 nA were observed. The number of trials of the Monte Carlo simulation was 50.

FIG. 20C illustrates the configuration of the semiconductor device 10B. FIG. 20C illustrates the transistors M11, M21, M12, M22, M13, and M23. Connections between circuits and wirings and the like are as shown in the drawing. The transistors M11 and M21 were OS transistors. The transistors M12, M22, M13, and M23 were Si transistors. The channel length (L) and the channel length (W) of each of the OS transistors were both 60 nm. The channel length (L) and the channel length (W) of each of the Si transistors were 0.65 μm and 0.4 μm, respectively. For the wiring WSL, a high level potential at the time of data writing was set to 2.5 V and a low level potential at the time of data reading was set to −0.8 V. For the wiring WCL, the drain voltage Vd at the time of data reading was set to 1.2 V. The voltage Vb applied to the wiring VBL was set to 0.6 V at 27° C. and 0.8 V at 85° C. V_{body} applied to back gates of the Si transistors was set to −0.5 V. To back gates of the OS transistors, 0 V was applied. As I_{W} fed as the weight data, 1 nA was supplied. The currents Iᵣ flowing in the wiring WCL when the current I_{X} fed as the input data was varied from 0 nA to 1.0 nA were observed. The number of trials of the Monte Carlo simulation was 50.

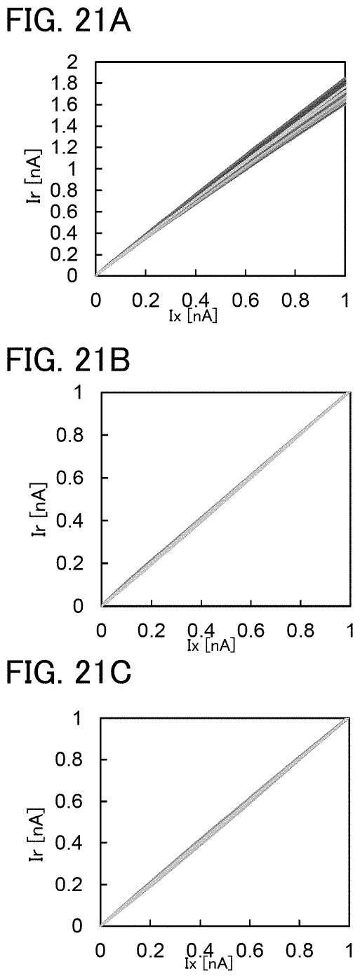

FIG. 21A is a diagram showing output results of the current Iᵣ with respect to the current I_{X} in FIG. 20A at 27° C. FIG. 21B is a diagram showing output results of the current Iᵣ with respect to the current I_{X} in FIG. 20B at 27° C. FIG. 21C is a diagram showing output results of the current Iᵣ with respect to the current I_{X} in FIG. 20C at 27° C.

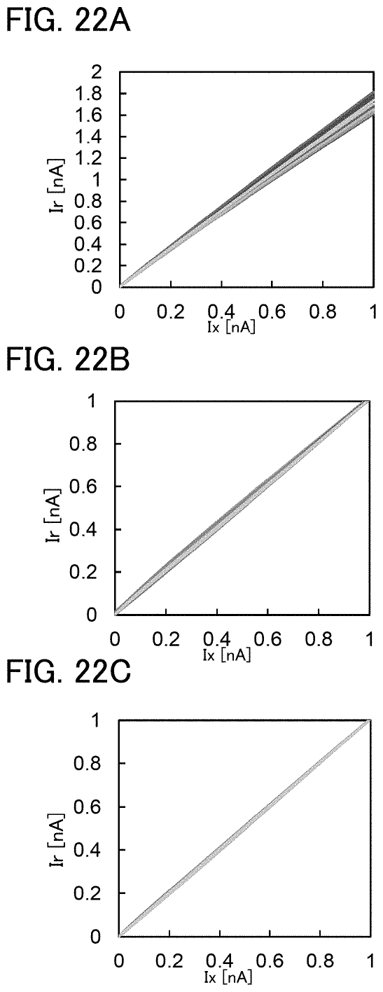

FIG. 22A is a diagram showing output results of the current Iᵣ with respect to the current I_{X} in FIG. 20A at 85° C. FIG. 22B is a diagram showing output results of the current Iᵣ with respect to the current I_{X} in FIG. 20B at 85° C. FIG. 22C is a diagram showing output results of the current Iᵣ with respect to the current I_{X} in FIG. 20C at 85° C.

Table 1 shows σ/μ and bit accuracy (Δ) of the case of FIG. 21A to FIG. 21C or FIG. 22A to FIG. 22C. σ represents a standard deviation, and μ represents an average. σ/μ represents variation in data of the case of each of the drawings. Furthermore, Δ in the table is obtained by converting σ/μ into the bit accuracy. It can be said that the smaller the value of σ/μ is, or the larger the value of Δ is, the higher the arithmetic accuracy is.

TABLE 1

| | (A) | | (B) | | (C) | |
|---|---|---|---|---|---|---|
| 27° C. | σ/μ = | 3.1% | σ/μ = | 0.31% | σ/μ = | 0.38 % |
| (FIG. 21) | Δ = | 4 bit | Δ = | 7 bit | Δ = | 7 bit |
| 85° C. | σ/μ = | 27% | σ/μ = | 0.59% | σ/μ = | 0.28 % |
| (FIG. 22) | Δ = | 4 bit | Δ = | 6 bit | Δ = | 7 bit |

(A) in Table 1 indicates the configuration in FIG. 20A, (B) in the table indicates the configuration (the semiconductor device 10) in FIG. 20B, and (C) in the table indicates the configuration (the semiconductor device 10B) in FIG. 20C.

The results in FIG. 21A to FIG. 21C, FIG. 22A to FIG. 22C, and Table 1 indicate that the arithmetic accuracy of the semiconductor devices 10 and 10B is higher than that of the comparative example under any conditions. In particular, the arithmetic accuracy of the semiconductor device 10B is found to be higher than that of the semiconductor device 10.

### Example 2

In this example, an arithmetic device, which is a device to which the semiconductor device of one embodiment of the present invention can be applied, was prototyped and an output signal responding to an input signal was measured. The arithmetic device can perform arithmetic having excellent arithmetic efficiency with current consumption per cell of several nanoamperes.

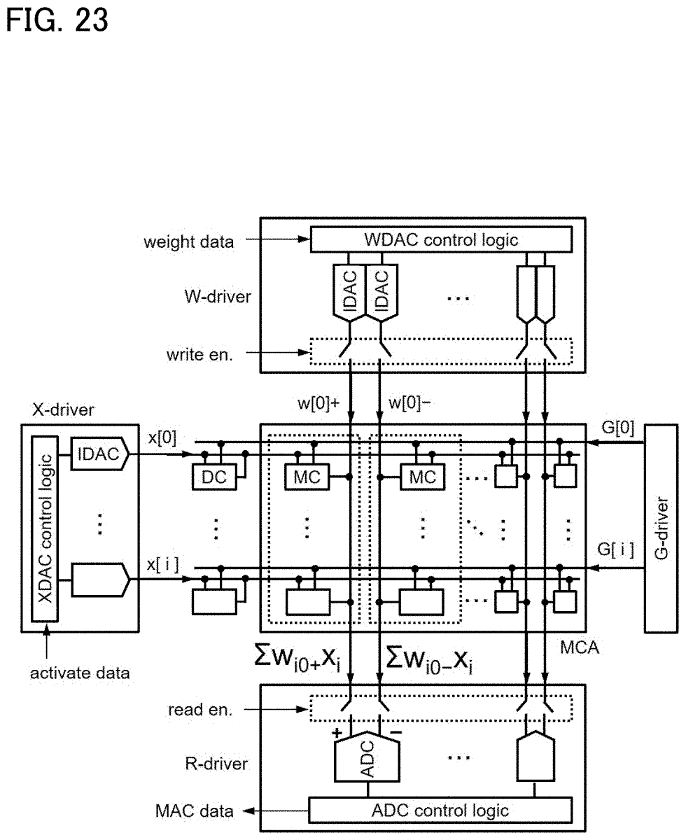

The prototype was fabricated using a process in which a 60-nm CAAC-IGZO FET (a transistor containing an In—Ga—Zn oxide having a CAAC structure in its channel formation region) and a 55-nm Si CMOS were combined. A block diagram of a cell array is as illustrated in FIG. 23; cells were arranged in 512 rows and 512 columns. In the structure illustrated in FIG. 23, two columns of cells MC are arranged as a pair; the absolute value of weight data W was stored in one column when the weight data is positive and the absolute value of the weight data W was stored in the other column when the weight data is negative. As the arithmetic result, differential current flowing in a pair of wirings was read as a digital value by the analog-digital converter circuit ADC.

FIG. 23 illustrates a W-driver corresponding to the circuit WCS in Embodiment 2, the W-driver corresponding to the circuit WCS in Embodiment 2, an X-driver corresponding to the circuit XCS in Embodiment 2, and a G-driver corresponding to the circuit WSD in Embodiment 2. The W-driver includes a circuit (WDAC control logic) for controlling writing of the weight data, current-output digital-analog converter circuits (IDACs), and switches controlled by a signal (write en.). The X-driver includes a circuit (XDAC control logic) for controlling input data (activete data) and IDACs.

FIG. 23 also illustrates an MCA corresponding to the cell array CA in Embodiment 2, cells DC corresponding to the reference cells 21, and the cells MC corresponding to the arithmetic cells 31. As illustrated in the drawing, input data (x[0] or x[i]), weight data (w[0]+ or w[0]−), or a control signal (G[0] or G[i]) is supplied to each wiring, and current (ΣWᵢ₀+Xᵢ) or ΣWᵢ₀−Xᵢ)) corresponding to positive or negative weight data is output to an R-driver. The R-driver includes switches controlled by a signal (read en.), the digital-analog converter circuits (ADCs) operating in accordance with a differential signal, and a circuit (ADC control logic) controlling the ADCs, and outputs data (MAC data) of product-sum operation.

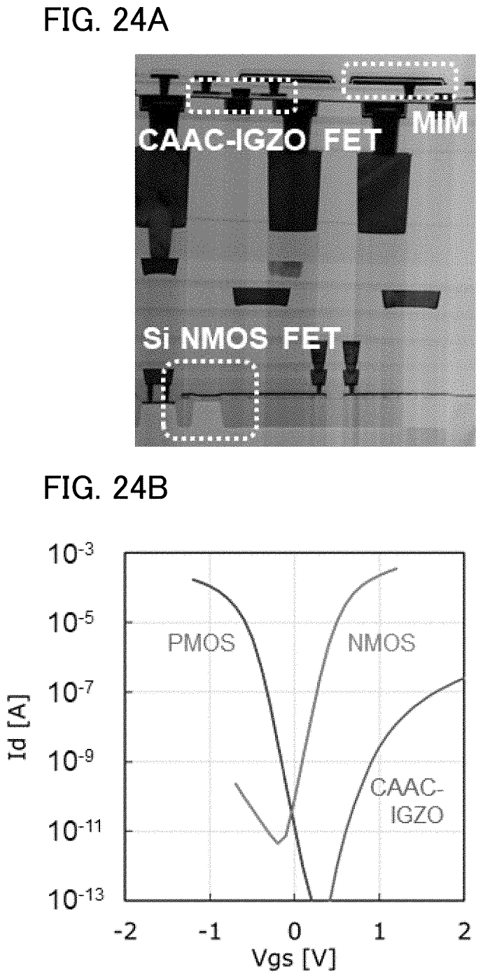

FIG. 24A is a perspective view showing structures of a CAAC-IGZO FET, a Si CMOS, and a capacitor (MIM) included in the arithmetic device. The CAAC-IGZO FET includes a top gate electrode (TGE), a gate insulating layer (TGI) on the top gate electrode side, a back gate electrode (BGE), a gate insulating layer (BGI) on the back gate electrode side, an electrode (S/D) functioning as a source or a drain, and the like. The transistor is a transistor having an S-channel structure.

FIG. 24B shows top gate voltage-drain current characteristics (also referred to as Id-Vg characteristics) of a typical CAAC-IGZO FET together with Id-Vg characteristics of Si transistors (PMOS and NMOS). As show in FIG. 24B, the CAAC-IGZO FET has characteristics of an extremely low off-state current (Ioff) and a large ratio of on-state current (Ion) to off-state current, as compared with the Si transistors (PMOS and NMOS).

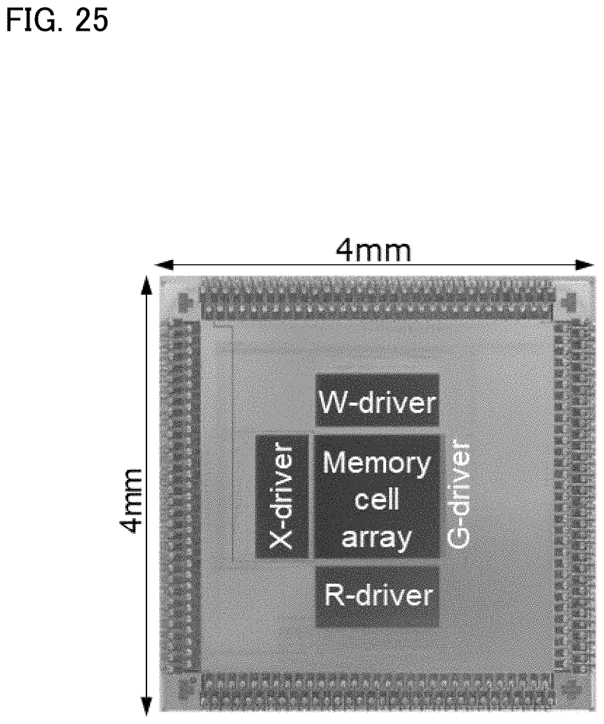

FIG. 25 is a chip photograph of the prototyped arithmetic device. In the chip photograph in FIG. 25, the W-driver, the X-driver, the G-driver, and the R-driver are arranged around the memory cell array. The chip size is 4 mm×4 mm.

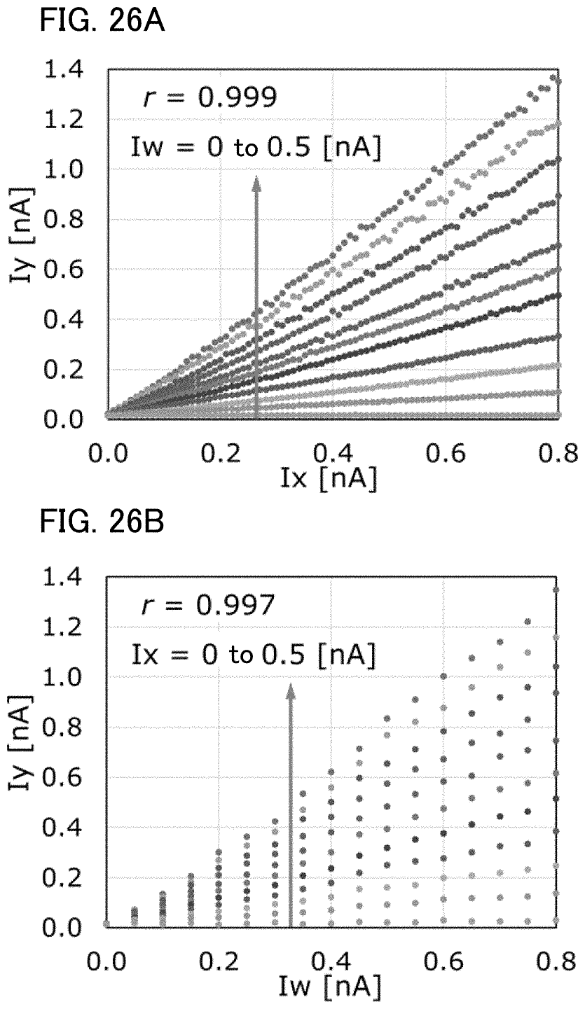

FIG. 26A is a graph showing changes in current Iy output from the cell MC with a change in the input data when current Iw corresponding to the weight data is changed from 0 to 0.5 nA in increments of 0.05 nA. In FIG. 26A, the horizontal axis represents current Ix corresponding to the input data, and the vertical axis represents the current Iy. The current output from the cell MC increased in proportion to the changes in the input data and the weight data. The value of a correlation coefficient r was 0.999, which was favorable.

FIG. 26B is a graph showing changes in the current Iy with a change in the weight data when the current Ix corresponding to the input data is changed from 0 to 0.5 nA in increments of 0.05 nA. In FIG. 26B, the horizontal axis represents the current Iw corresponding to the weight data, and the vertical axis represents the current Iy. The current output from the cell MC increased in proportion to the changes in the weight data and the input data. The value of the correlation coefficient r was 0.997, which was favorable.

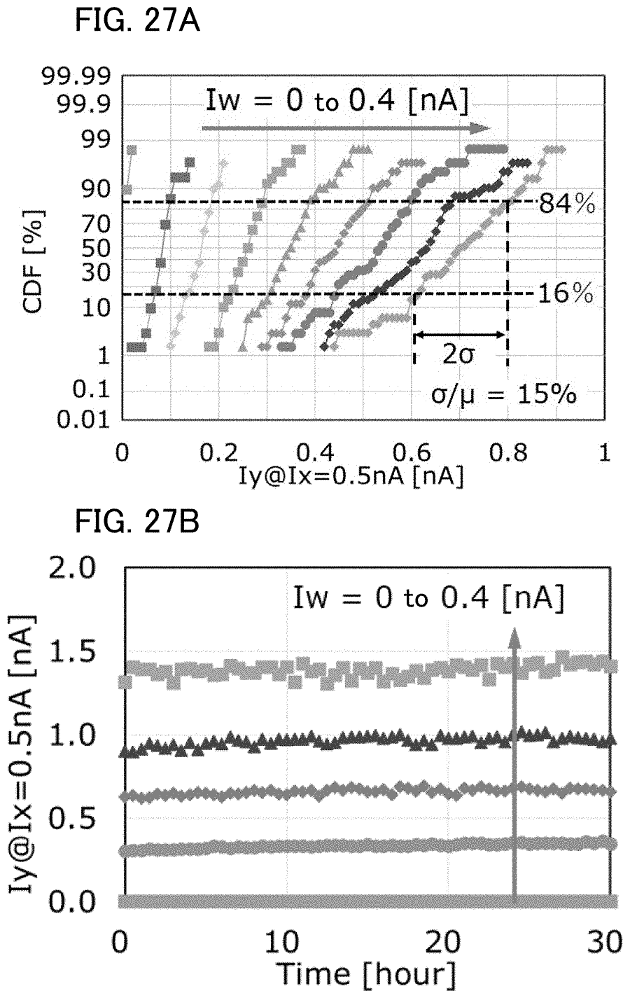

FIG. 27A is a graph for investigating an influence of variation among the cells MC. FIG. 27A is a graph showing a cumulative distribution function (CDF) when the current Iw corresponding to the weight data is changed from 0 to 0.4 nA in increments of 0.05 nA, with a horizontal axis representing the current Iy output from the cell MC when the current Ix corresponding to the input data is 0.5 nA. As shown in FIG. 27A, the results were favorable in a range where the currents corresponding to the input data and the weight data are low.

FIG. 27B is a graph for investigating characteristics of retaining a potential retained when the current Iw corresponding to the weight data flow in the cell MC. FIG. 27B is a graph showing the change in the current Iy when the current Iw corresponding to the weight data is changed from 0 to 0.4 nA in increments of 0.1 nA, with a horizontal axis representing retention time (Time) when the current Ix corresponding to the input data is 0.5 nA. As shown in FIG. 27B, the results were particularly favorable in a range where the current corresponding to the weight data is low.

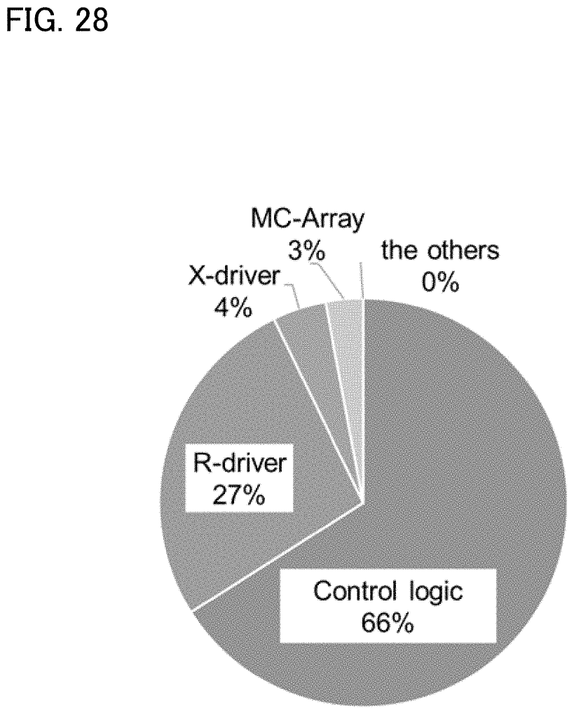

FIG. 28 is a pie chart showing arrangement of power consumption of each of the circuits in the prototyped arithmetic device. As shown in FIG. 28, the control circuit (Control logic) occupies 66%, the R-driver occupies 27%, and the X-driver occupies 4%; as a result, the proportion of the power consumption of the memory cell array (MC-Array) is as small as 3%.

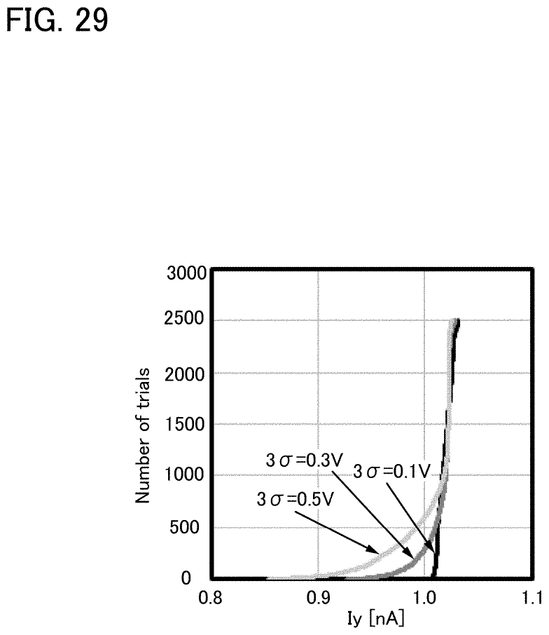

Next, an influence of variation in the threshold voltage of an OS transistor (e.g., the transistor 32 in FIG. 1) was examined. FIG. 29 is a graph showing simulation results of the cases where 36 in the distribution of the threshold voltage of the OS transistor was 0.1 V, 0.3 V, and 0.5 V. The smaller 3G is, the smaller the variation in the threshold voltage of the OS transistor is. FIG. 29 shows the results obtained by repeatedly performing multiplication in which the current Iy output when the current Ix corresponding to the input data is 1.0 nA and the current Iw corresponding to the weight data is 1.0 nA becomes 1.0 nA; the closer the current Iy is to 1.0 nA regardless of the number of times repeated, the better the result is.

As shown in FIG. 29, the current Iy, which is the output current, has a constant value when the in the threshold voltage of the OS transistor is reduced, leading to a favorable result.

Note that this example can be implemented in appropriate combination with the other embodiments described in this specification.

(Supplementary Notes on Description in this Specification and the Like)

The description of the above embodiments and each structure in the embodiments are noted below.

One embodiment of the present invention can be constituted by combining, as appropriate, the structure described in each embodiment with the structures described in the other embodiments and Example. In addition, in the case where a plurality of structure examples are described in one embodiment, the structure examples can be combined as appropriate.

Note that content (or part of the content) described in one embodiment can be applied to, combined with, or replaced with another content (or part of the content) described in the embodiment and/or content (or part of the content) described in another embodiment or other embodiments.

Note that in each embodiment, a content described in the embodiment is a content described with reference to a variety of drawings or a content described with text disclosed in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be formed.

In this specification and the like, components are classified on the basis of the functions, and shown as blocks independent of one another in block diagrams. However, in an actual circuit or the like, it is difficult to separate components on the basis of the functions, and there are such a case where one circuit is associated with a plurality of functions or a case where a plurality of circuits are associated with one function, for example. Therefore, blocks in the block diagrams are not limited by the components described in this specification, and the description can be changed appropriately depending on the situation.

In drawings, the size, the layer thickness, or the region is shown arbitrarily for description convenience. Therefore, they are not limited to the illustrated scale. Note that the drawings are schematically shown for clarity, and embodiments of the present invention are not limited to shapes, values, or the like shown in the drawings. For example, variation in signal, voltage, or current due to noise or variation in signal, voltage, or current due to difference in timing can be included.

Furthermore, the positional relationship between components illustrated in the drawings and the like is relative. Therefore, when the components are described with reference to drawings, terms for describing the positional relationship, such as “over” and “under”, are sometimes used for convenience. The positional relationship of the components is not limited to that described in this specification and can be explained with other terms as appropriate depending on the situation.

In this specification and the like, expressions “one of a source and a drain” (or a first electrode or a first terminal) and “the other of the source and the drain” (or a second electrode or a second terminal) are used in the description of the connection relationship of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation or the like.

In this specification and the like, the term “electrode”, “wiring”, or the like does not functionally limit these components. For example, an “electrode” is used as part of a “wiring” in some cases, and vice versa. Furthermore, the term “electrode”, “wiring”, or the like also includes the case where a plurality of “electrodes”, “wirings”, or the like are formed in an integrated manner, for example.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, voltage and potential can be replaced with each other as appropriate. The voltage refers to a potential difference from a reference potential, and when the reference potential is a ground voltage, for example, the voltage can be rephrased into the potential. The ground potential does not necessarily mean 0 V. Note that potentials are relative, and the potential supplied to a wiring or the like is changed depending on the reference potential, in some cases.

In this specification and the like, the term “high-level potential” or “low-level potential” does not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with a positive charge moves, and is expressed as positive current. In other words, the direction in which a carrier with a negative charge moves is opposite to the direction of a current, and is expressed as negative current. Thus, in the case where the polarity of current (or the direction of current) is not specified in this specification and the like, the description “current flows from element A to element B” can be rephrased as “current flows from element B to element A”, for example. The description “current is input to element A” can be rephrased as “current is output from element A”, for example.

In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

In this specification and the like, a switch is in a conduction state (on state) or in a non-conduction state (off state) to determine whether current flows or not. Alternatively, a switch has a function of selecting and changing a current path.

In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

Note that in this specification and the like, the terms “film”, “layer”, and the like can be interchanged with each other depending on the case or according to circumstances. For example, the term “conductive layer” can be changed into the term “conductive film” in some cases. As another example, the term “insulating film” can be changed into the term “insulating layer” in some cases.

### REFERENCE NUMERALS

10: semiconductor device, 20: reference cell portion, 21: reference cell, 22: transistor, 23: transistor, 24: transistor, 25: capacitor, 31: arithmetic cell, 32: transistor, 33: transistor, 34: transistor, 35: capacitor

1. A semiconductor device comprising:
a first transistor;
a second transistor;
a third transistor; and
a capacitor,
wherein the first transistor is configured to retain a first potential corresponding to first data supplied to a gate of the third transistor through the first transistor when being in an off state,
wherein the capacitor is configured to change the first potential retained in the gate of the third transistor into a second potential in accordance with a change in potential corresponding to second data supplied to one electrode of the capacitor,
wherein the second transistor is configured to set a potential of one of a source and a drain of the third transistor to a potential corresponding to a potential of a gate of the second transistor,
wherein the third transistor is configured to supply output current corresponding to a potential of the gate of the third transistor to the other of the source and the drain of the third transistor, and
wherein the output current is current flowing when the third transistor operates in a subthreshold region.

2. A semiconductor device comprising:
a first transistor;
a second transistor;
a third transistor; and
a capacitor,
wherein the first transistor is configured to retain a first potential corresponding to first data supplied to a gate of the third transistor through the first transistor when being in an off state,
wherein the capacitor is configured to change the first potential retained in the gate of the third transistor into a second potential in accordance with a change in potential corresponding to second data supplied to one electrode of the capacitor,
wherein the second transistor is configured to set a potential of one of a source and a drain of the third transistor to a potential corresponding to a potential of a gate of the second transistor,
wherein the third transistor is configured to supply output current corresponding to a potential of the gate of the third transistor to the other of the source and the drain of the third transistor,
wherein the output current is current flowing when the third transistor operates in a subthreshold region,
wherein the second transistor and the third transistor each have a back gate, and
wherein a potential supplied to the back gates of the second transistor and the third transistor is a potential of the other of the source and the drain of the third transistor.

3. A semiconductor device comprising:
a first transistor;
a second transistor;
a third transistor; and
a capacitor,
wherein the first transistor is configured to retain a first potential corresponding to first data supplied to a gate of the third transistor through the first transistor when being in an off state,
wherein the capacitor is configured to change the first potential retained in the gate of the third transistor into a second potential in accordance with a change in potential corresponding to second data supplied to one electrode of the capacitor,
wherein the second transistor is configured to set a potential of one of a source and a drain of the third transistor to a potential corresponding to a potential of a gate of the second transistor,
wherein the third transistor is configured to supply output current corresponding to a potential of the gate of the third transistor to the other of the source and the drain of the third transistor,
wherein the output current is current flowing when the third transistor operates in a subthreshold region,
wherein the second transistor and the third transistor each have a back gate, and
wherein a potential supplied to the back gates of the second transistor and the third transistor is lower than a potential of the other of the source and the drain of the third transistor.

4. The semiconductor device according to claim 1,
wherein the first transistor comprises a semiconductor layer comprising a metal oxide in a channel formation region.

5. The semiconductor device according to claim 4,
wherein the metal oxide comprises In, Ga, and Zn.

6. The semiconductor device according to claim 1,
wherein the second transistor and the third transistor each comprise a semiconductor layer comprising silicon in a channel formation region.

7. An electronic device comprising:
the semiconductor device according to claim 1; and
a housing,
wherein arithmetic of a neural network is performed by the semiconductor device.

8. The semiconductor device according to claim 2,
wherein the first transistor comprises a semiconductor layer comprising a metal oxide in a channel formation region.

9. The semiconductor device according to claim 8,
wherein the metal oxide comprises In, Ga, and Zn.

10. The semiconductor device according to claim 2,
wherein the second transistor and the third transistor each comprise a semiconductor layer comprising silicon in a channel formation region.

11. An electronic device comprising:
the semiconductor device according to claim 2; and
a housing,
wherein arithmetic of a neural network is performed by the semiconductor device.

12. The semiconductor device according to claim 3,
wherein the first transistor comprises a semiconductor layer comprising a metal oxide in a channel formation region.

13. The semiconductor device according to claim 12,
wherein the metal oxide comprises In, Ga, and Zn.

14. The semiconductor device according to claim 3,
wherein the second transistor and the third transistor each comprise a semiconductor layer comprising silicon in a channel formation region.

15. An electronic device comprising:
the semiconductor device according to claim 3; and
a housing,
wherein arithmetic of a neural network is performed by the semiconductor device.
